(19) United States
(12) Patent Application Publication
(10) Pub. No.: US 2007/0003743 A1
(43) Pub. Date: Jan. 4, 2007

(54) Color filter substrate for organic EL element

(76) Inventors: Masaaki Asano, Tokyo (JP); Yasuko Baba, Tokyo (JP); Hidemasa Oshige, Tokyo (JP); Tatsuya Miyoshi, Tokyo (JP)

Correspondence Address: SEYFARTH SHAW LLP, 131 S. DEARBORN ST., SUITE2400, CHICAGO, IL, 60603-5803, US

(21) Appl. No.: 11/202,850

(22) Filed: Aug. 12, 2005

(30) Foreign Application Priority Data
Aug. 27, 2004 (JP) 2004-248773
Sep. 15, 2004 (JP) 2004-267843
Sep. 24, 2004 (JP) 2004-278398
Sep. 30, 2004 (JP) 2004-288878

(51) Int. Cl. B32B 3/10; H01L 51/52; H05B 33/02

(52) U.S. Cl. 428/201; 428/323; 428/690; 428/917; 313/506; 313/112; 257/98; 257/E51.018; 428/328

(57) ABSTRACT

The main object of the present invention is to provide an inexpensive color filter substrate for an organic EL element and an organic EL display device which are capable of displaying good images having no defects such as dark spots. To attain the object, the invention provides a color filter substrate for an organic EL element having a substrate, a colored layer formed in a pattern form on/over the substrate, and a transparent electrode layer and a conductive layer laminated, in any order, on/over the colored layer, wherein the conductive layer is a coated film.

### BACKGROUND OF THE INVENTION

1. Field of the Invention

The present invention relates to a color filter substrate for an organic electroluminescent element, which is used in an organic electroluminescent display device capable of attaining color display.

2. Description of the Related Art

Organic electroluminescent (hereinafter, may refer to as organic EL) elements have high luminous efficiency. Thus, for example, the elements realize highly bright luminescence even if the voltage applied thereto is a little less than 10V. Moreover, from a simple structure thereof, light can be emitted. Therefore, the application thereof to image display devices has been expected and research thereon has been actively made. In particular, an organic EL element has been increasingly made practicable as a luminescent element in an image display device since the organic EL element has the following advantages; the element has high visibility by its self color-development; the element is excellent in impact resistance since the element, which is different from any liquid crystal display, is a completely solid display; the element is less affected by temperature change; and the element has a wide view angle.

In order to make organic EL elements practicable as luminescent elements in image display devices, it is important that the organic EL elements have highly precise display function and long-term stability. However, some of the organic EL elements have a drawback that luminescence properties, such as current-brightness property, are remarkably deteriorated when the elements are driven for a constant term.

A typical example of the cause of this deterioration in the luminescence properties is the growth of luminescence defect points called dark spots. It is generally considered that the dark spots result from the oxidization or aggregation of constituent materials of respective layers which constitute the organic EL element based on oxygen or water content in the organic EL element. The growth of the dark spots advances not only during the application of electric current to the element (the driving of the element) but also during the storage thereof. Ian extreme case, the dark spots spread out to the whole of the luminescent face. It is generally considered that (1) the growth is accelerated by oxygen or water content present around the organic EL element, (2) the growth is affected by oxygen or water content present as adsorbates in respective layers therein, and (3) the growth is also affected by water content adsorbed on parts used to produce the organic EL element or by the invasion of water content at the time of the production or the like.

The dark spots are also caused by gas generated resulting from the decomposition of dyes or the like contained in the colored layer, the color converting layer and any other layer that constitute the organic EL element when this element is produced.

As methods for preventing this invasion of water content, oxygen and the gas into the organic EL layer, suggested are methods of forming a transparent barrier layer such as an transparent inorganic film or resin film (see, for example, Japanese Patent Application Laid-Open (JP-A) Nos. 2002-100469, 2002-117976, 2002-134268, 2002-175880, and 2002-184578).

In general, however, sputtering, CVD or the like forms a transparent inorganic film. According to such a method, it is technically difficult to obtain a transparent inorganic film having no foreign substances, such as particles, or pinholes. For this reason, the transparent inorganic film has insufficient moisture proof property and gas barrier property for preventing the deterioration of the organic EL element. Thus, there is adopted a method of making the film thickness of the transparent inorganic film thick, thereby making the gas barrier property high. However, a problem that the costs become very high is caused.

Recently, an organic EL display device using a color filter has been known. In such an organic EL display device, indium tin oxide (ITO) or the like is generally used for its transparent electrode layer and a pigment or resin is used for its colored layer. Thus, the two are materials having different natures, and have bad material-compatibility so as to exhibit poor adhesive property to each other. Thus, a problem that the interface therebetween is easily peeled or cracked arises.

When the above-mentioned transparent inorganic film (transparent barrier layer) is formed in order to prevent dark spots, the transparent inorganic film has a poor adhesive property to a colored layer or the like since the film is formed by sputtering, CVD or the like, as described above. As a result, the transparent inorganic film is peered in the same manner as described above.

Furthermore, when a resin protective layer is formed to make the surface flat or smooth, the resin protective layer and the transparent electrode layer have bad material-compatibility in the same manner as in the case of the above-mentioned colored layer since resin is generally used for the resin protective layer. As a result, the resin protective layer and the transparent electrode layer exhibit insufficient adhesive property to each other. Thus, the interface therebetween is easily peeled or cracked.

In order to solve such problems, a thin film made of silicon oxide or the like is formed as an underlying layer of the transparent electrode layer. This thin film made of silicon oxide or sputtering or CVD forms the like; accordingly, the thin film is formed on the entire face of a transparent substrate. Therefore, it appears that the underlying layer has a certain measure of gas barrier property.

However, in ordinary processes for producing an organic EL element, a degassing treatment for removing gas components from its colored layer and other layers is conducted. When the underlying layer has a certain measure of gas barrier property at this time, a problem that the gas components are not easily removed is caused. This is because the gas barrier property of the underlying layer restrains the gas components from being discharged in the degassing treatment. Although the underlying layer has gas barrier property, the gas barrier property is insufficient. Thus, gas components may be discharged when the organic EL element is driven, resulting in a problem that dark spots are generated.

Thus, for example, JP-A No. 2002-134268 suggests an organic EL element in which a barrier layer having good adhesive property is formed between a transparent substrate on which a colored layer is formed and a transparent electrode layer. In this organic EL element, its barrier layer has gas barrier property and adhesive property; it is therefore unnecessary to arrange an underlying layer as described above.

However, the barrier layer is formed by sputtering, CVD or the like, and thus the thickness thereof needs to be made thick in order for this layer to obtain gas barrier property as described above. As a result, there arises a problem that the costs become very high.

### SUMMARY OF THE INVENTION

The present invention has been achieved in order to solve the above problems. It is a main object of this invention to provide an inexpensive color filter substrate for an organic EL element and an organic EL display device which are capable of displaying good images having no defects such as dark spots.

In order to attain the object, the present invention provides a color filter substrate for an organic electroluminescent element having a substrate, a colored layer formed in a pattern form on/over the substrate, and a transparent electrode layer and a conductive layer laminated, in any order, on/over the colored layer, wherein the conductive layer is a coated film.

It is allowable in the invention that the transparent electrode layer is formed on/over the colored layer and the conductive layer having barrier property is formed on/over the transparent electrode layer. According to the invention, the conductive layer is a coated film; therefore, even if defects such as pinholes are present in the transparent electrode layer, the pinholes and other defects can be blocked by applying a conductive layer forming coating solution on the transparent electrode layer when the conductive layer is formed. It is therefore possible to prevent the outflow of gas generated in the colored layer and so on from the pinholes and other defects in the transparent electrode layer. When the color filter substrate for an organic EL element of the invention is used in an organic EL display device, the generation of dark spots can be prevented. When the conductive layer is formed on/over the transparent electrode layer, gas can be prevented from flowing out from the colored layer and so on, as described above. It is therefore unnecessary to form a thick transparent barrier layer made of an insulating inorganic material by sputtering or CVD method. Consequently, costs for the production can be reduced.

It is preferred in the invention that the conductive layer contains fine particles having an average particle size of 1 to 10 nm. Fine particles with the average particle size thereof too small are not easily produced. On the other hand, if the average particle size of the fine particles is too large, pinholes or other detects in the transparent electrode layer may not be easily blocked. Moreover, the fall in the firing temperature the coating-solution based on the above-mentioned size effect cannot be expected.

In this case, the fine particles are preferably fine particles made of indium tin oxide (ITO) since ITO is preferably used as a conductive layer.

The fine particles may be fine particles made of at least one kind selected from the group consisting of Au, Ag, Cu, Pt, Sn, Zn, In, Pb and Al, and oxides thereof.

It is preferred in the invention that the average surface roughness (Ra) of the conductive layer is from 10 to 100 Å. When the average surface roughness (Ra) of the conductive layer is within this range, the generation of dark areas can be restrained when the color filter substrate for an organic EL element of the invention is used in an organic EL display device.

It is allowable in the invention that an inorganic layer having barrier property is formed between the colored layer and the transparent electrode layer. According to the invention, the formation of the inorganic layer makes it possible to make the surface of the colored layer flat or smooth so as to restrain the generation of dark areas. The formation of the inorganic layer also makes it possible to improve adhesive force between the transparent electrode layer and the colored layer. Furthermore, the inorganic layer having barrier property, the transparent electrode layer and the conductive layer having barrier property are successively laminated on the colored layer; it is therefore possible to restrain still further the outflow of gas generated from the colored layer and soon, and the invasion of oxygen or water vapor.

In this case, it is preferred that the inorganic layer has conductivity. When the inorganic layer has conductivity, the inorganic layer can be integrated with the transparent electrode layer and the conductive layer so as to cause the resultant to function as an electrode. Accordingly, the electric resistance thereof can be made small.

It is preferred in the invention that the inorganic layer contains fine particles having an average particle size of 1 to 10 nm. By the size effect peculiar to the fine particles, the firing temperature of an inorganic layer forming coating solution which contains the fine particles, at the time of the formation of the inorganic layer, can be made lower than ordinary firing temperatures. Consequently, the coating solution can be fired at not higher than the upper temperature limit of the colored layer.

In this case, the fine-particles are preferably fine particles made of indium tin oxide (ITO) since ITO is preferably used as an inorganic layer.

The fine particles may be fine particles made of at least one kind selected from the group consisting of Au, Ag, Cu, Pt, Sn, Zn, In, Pb and Al, and oxides thereof.

It is also preferred in the invention that at least one of the transparent electrode layer and the conductive layer is formed to cover the entire surface of the colored layer formed in the pattern form. When the entire face of the colored layer is covered with at least one of the transparent electrode layer and the conductive layer, that is, when the colored layer is not exposed, it is possible to prevent the outflow of gas generated from the colored layer more effectively.

It is also preferred in the invention that at least one of the transparent electrode layer, the conductive layer and/or the inorganic layer is formed to cover the entire surface of the colored layer formed in the pattern form. When the entire face of the colored layer is covered with at least one of the transparent electrode layer, the conductive layer and/or the inorganic layer, that is, when the colored layer is not exposed, it is possible to prevent the outflow of gas generated from the colored layer more effectively.

It is allowable in the invention that an overcoat layer is formed between the colored layer and the transparent electrode layer.

In this case, the overcoat layer may be formed over the entire face of the substrate on/over which the colored layer is formed. The formation of the overcoat layer over the entire face of the substrate, on/over which the colored layer is formed, makes it possible to make the surface of the colored layer flat or smooth and further make irregularities based on the patterned colored layer flat. This makes it possible to restrain the generation of dark areas when the color filter substrate for an organic EL element of the invention is used in an organic EL display device.

It is allowable in the invention that the overcoat layer is formed in a pattern form to cover at least the surface of the colored layer. In this case, it is preferred that at least one of the transparent electrode layer and/or the conductive layer is formed to cover the entire face of the overcoat layer formed in the pattern form, or cover the entire face of the colored layer and the overcoat layer formed in the pattern form. When the entire face of the overcoat layer or the entire face of the colored layer and the overcoat layer is covered with at least one of the transparent electrode layer and/or the conductive layer, that is, when the colored layer and the overcoat layer are not exposed, it is possible to prevent the outflow of gas generated from the colored layer and the overcoat layer more effectively.

It is allowable in the invention that an inorganic layer having barrier property is formed between the overcoat layer and the transparent electrode layer. The formation of the inorganic layer makes it possible to improve adhesive force between the transparent electrode layer and the overcoat layer. Moreover, it is possible to prevent still further the outflow of gas generated from the colored layer, the overcoat layer and so on and the invasion of oxygen, water vapor or the like since the inorganic layer having barrier property, the transparent electrode layer and conductive layer having barrier property are successively laminated. When the color filter substrate for an organic EL element of the invention is used in an organic EL display device, it is possible to restrain the generation of dark areas effectively.

It is allowable that an inorganic layer having barrier property is formed between the overcoat layer and the transparent electrode layer and the overcoat layer is formed in a pattern form to cover at least the surface of the colored layer. In this case, it is preferred that at least one of the transparent electrode layer, the conductive layer and/or the inorganic layer is formed to cover the entire face of the overcoat layer formed in the pattern form, or cover the entire face of the colored layer and the overcoat layer formed in the pattern form. When the entire face of the overcoat layer or the entire face of the colored layer and the overcoat layer is covered with at least one of the transparent electrode layer, the conductive layer and/or the inorganic layer, that is, when the colored layer and the overcoat layer are not exposed, it is possible to prevent the outflow of gas generated from the colored layer and the overcoat layer more effectively.

In this case, it is preferred that the inorganic film is a coated film, and has conductivity. When the inorganic film is a coated film, it is possible to prevent the generation of defects, such as pinholes penetrating through the inorganic layer to reach the surface of the conductive layer, even if the defects are present in the transparent electrode layer. This makes it possible to prevent the outflow of gas generated from the colored layer and so on, and the invasion of oxygen, water vapor or the like. Moreover, there is produced an advantage that the surface of the overcoat layer can be made smoother since the inorganic layer is the coated film. Furthermore, when the inorganic layer has conductivity, the inorganic layer can be integrated with the transparent electrode layer and the conductive layer to cause the resultant to function as an electrode. Consequently, the electric resistance can be made small.

It is preferred that the inorganic layer contains fine particles having an average particle size of 1 to 10 nm. By the size effect peculiar to the fine particles, the temperature for firing an inorganic layer forming coating solution which contains the fine particles, at the time of the formation of the inorganic layer, can be made lower than ordinary firing temperatures, Consequently, the coating solution can be fired at not higher than the upper temperature limit of the colored layer.

In this case, the fine particles are preferably fine particles made of indium tin oxide (ITO) since ITO is preferably used as an inorganic layer.

The fine particles may be fine particles made of at least one kind selected from the group consisting of Au, Ag, Cu, Pt, Sn, Zn, In, Pb and Al, and oxides thereof.

It is allowable in the invention that the conductive layer is formed in a pattern form on/over the colored layer and the transparent electrode layer is formed on/over the conductive layer. According to the invention, the formation of the conductive layer makes it possible to improve adhesive force between the transparent electrode layer and the colored layer so as to restrain the generation of peeling or cracking in the interfaces between the substrate on/over which the colored layer is formed and the transparent electrode layer. Moreover, irregularities or foreign substance on the colored layer can be cancelled or repaired to make the surface of the colored layer smooth since the conductive layer is the coated film. When the color filter substrate for an organic EL element of the invention is used in an organic EL display device, it is possible to restrain the generation of dark areas. Furthermore, the colored layer surface can be made smooth by the conductive layer and the transparent electrode layer, which is dense, can be formed thereon; it is therefore possible to restrain the invasion of water vapor or oxygen into the image display area where the colored layer is formed and the discharge of gas generated from the colored layer and so on. This makes it possible to restrain the generation of dark spots when the color filter substrate for an organic EL element of the invention is used in an organic EL display device. Moreover, it is unnecessary to form a thick barrier layer as in the prior art since the lamination of the conductive layer and the transparent electrode layer gives barrier property. Thus, costs for the production can be reduced. Furthermore, the conductive layer can be integrated with the transparent electrode layer to cause the resultant to function as an electrode since the conductive layer has conductivity. Consequently, the electric resistance can be made small.

It is preferred in the invention that the conductive layer contains fine particles having an average particle size of 1 to 10 nm. By the size effect peculiar to the fine particles, the temperature for firing an conductive layer forming coating solution which contains the fine particles, at the time of the formation of the conductive layer, can be made lower than ordinary firing temperatures. Consequently, the coating solution can be fired at not higher than the upper temperature limit of the colored layer.

In this case, the fine particles are preferably fine particles made of indium tin oxide (ITO) since ITO is preferably used as an electrode.

The fine particles may be fine particles made of at least one kind selected from the group consisting of Au, Ag, Cu, Pt, Sn, Zn, In, Pb and Al, and oxides thereof.

It is preferred in the invention that the average surface roughness (Ra) of the transparent electrode layer is from 10 to 100 Å. When the average surface roughness (Ra) of the transparent electrode layer is within this range, the generation of dark areas can be restrained when the color filter substrate for an organic EL element of the invention is used in an organic EL display device.

It is preferred in the invention that the conductive layer is formed to leave an area of a predetermined width from the edge of the colored layer formed in the pattern form. Such a structure makes it possible to discharge gas components selectively from the edge of the colored layer, which is a non-display area, to prevent the gas component from passing through the transparent electrode layer, which is an image-display area. Thus, when the color filter substrate for an organic EL element of the invention is used to produce an organic EL display device, it is possible to restrain the generation of dark spots.

It is also allowable that the conductive layer is formed to cover the entire face of the colored layer formed in the pattern form. When the entire face of the colored layer is covered with the conductive layer, that is, when the colored layer is not exposed, it is possible to prevent the outflow of gas generated from the colored layer more effectively.

It is also allowable in the invention that a barrier layer is formed between the colored layer and the conductive layer. This makes it possible to make high the barrier property of the color filter substrate for an organic EL element of the invention.

It is allowable in the invention that an overcoat layer is formed between the colored layer and the conductive layer.

In this case, it is preferred that the overcoat layer is formed over the entire face of the substrate on/over which the colored layer is formed and the conductive layer is formed to leave an area of a predetermined width from the edge of the colored layer formed in the pattern form. Such a structure makes it possible to discharge gas components selectively from the edge of the colored layer, which is a non-display area, to prevent the gas component from passing through the transparent electrode layer, which is an image-display area. Thus, when the color filter substrate for an organic EL element of the invention is used to produce an organic EL display device, it is possible to restrain the generation of dark spots. When the overcoat layer is formed over the entire face of the substrate on/over which the colored layer is formed, the colored layer surface can be made smooth and further irregularities based on the patterned colored layer can be made smooth. This makes it possible to restrain the generation of dark areas more effectively when the color filter substrate for an organic EL element of the invention is used in an organic EL display device.

It is also allowable that the overcoat layer is formed in a pattern form to cover at least the surface of the colored layer and the conductive layer is formed to leave an area of a predetermined width from the edge of the colored layer formed in the pattern form. As described above, such a structure makes it possible to discharge gas components selectively from the edge of the colored layer, which is a non-display area, to prevent the gas component from passing through the transparent electrode layer, which is an image-display area.

It is also allowable that the overcoat layer is formed in a pattern form to cover at least the surface of the colored layer, and the conductive layer is formed to cover the entire face of the overcoat layer formed in the pattern form, or cover the entire face of the colored layer and the overcoat layer formed in the pattern form. When the entire of the overcoat layer or the entire face of the colored layer and the overcoat layer is covered with the conductive layer, that is, when the colored layer and the overcoat layer are not exposed, it is possible to prevent the outflow of gas generated from the colored layer and the overcoat layer more effectively.

It is also allowable in the invention that a barrier layer is formed between the overcoat layer and the conductive layer. This makes it possible to make high the barrier property of the color filter substrate for an organic EL element of the invention.

It is also allowable in the invention that a light shielding part is formed on/over the substrate and between the colored layers. When the color filter substrate for an organic EL element of the invention is used to produce an organic EL display device, the contrast can be improved by the formation of the light shielding part, which is, for example, a black matrix.

In this case, it is preferred that the light shielding part has insulation property. Even if the light shielding part contacts, for example, the transparent electrode layer, it is possible to prevent electric conduction between the light shielding part and the transparent electrode layer when the light shielding part has insulation property.

It is also allowable in the invention that a color converting layer is formed on/over the colored layer and between the colored layer and the transparent electrode layer or the conductive layer.

The present invention also provides a color filter substrate for organic EL element having a substrate, a colored layer formed in a pattern form on/over the substrate, a transparent electrode layer formed on/over the colored layer, and a conductive layer formed on/over the transparent electrode layer, wherein pinholes present in the transparent electrode layer are blocked with the conductive layer.

According to the invention, the pinholes, which are present in the transparent electrode layer, are blocked with the conductive layer; it is therefore possible to prevent the outflow of gas generated from the colored layer and so on from the pinholes in the transparent electrode layer. For this reason, when the color filter substrate for an organic EL element of the invention is used in an organic EL display device, it is possible to restrain the generation of dark spots. The invention also has an advantage that it is unnecessary to form a thick transparent barrier layer as in the prior art, as described above.

It is allowable in the invention that an overcoat layer is formed between the colored layer and the conductive layer.

The present invention also provides an organic EL display device having the above-mentioned color filter substrate for an organic EL element, an organic EL layer formed on/over the color filter substrate for an organic EL element and containing at least a light emitting layer, and a counter electrode layer formed on/over the organic EL layer.

According to the invention, the generation of defects such as dark spots can be restrained to produce an organic EL display device capable of attaining good image display since the above-mentioned color filter substrate for an organic EL element is used. Moreover, it is unnecessary to form a thick transparent barrier layer as in the prior art. Thus, an inexpensive organic EL display device can be provided.

According to the invention, good barrier property can be obtained by laminating the transparent electrode layer and the conductive layer. Thus, when the color filter substrate for an organic EL element of the invention is used in an organic EL display device, the generation of dark spots can be restrained. Moreover, it is unnecessary to form a thick transparent barrier layer as in the prior art. Thus, an advantageous effect of making costs low is produced.

The formation of the transparent electrode layer on/over the conductive layer makes it possible to improve adhesive force between the transparent electrode layer and the colored layer, and restrain the generation of peeling or cracking in the interfaces between the substrate on/over which the colored layer is formed and the transparent electrode layer.

### BRIEF DESCRIPTION OF THE DRAWINGS

FIG. 1 is a schematic sectional view showing an example of the color filter substrate for an organic EL element of the present invention.

FIG. 2 is a schematic sectional view showing another example of the color filter substrate for an organic EL element of the present invention.

FIGS. 3A and 3B are views for explaining a conductive layer (second transparent electrode layer).

FIG. 4 is a schematic sectional view showing another example of the color filter substrate for an organic EL element of the present invention.

FIG. 5 is a schematic sectional view showing another example of the color filter substrate for an organic EL element of the present invention.

FIG. 6 is a schematic-sectional view showing another example of the color filter substrate for an organic EL element of the present invention.

FIG. 7 is a schematic sectional view showing another example of the color filter substrate for an organic EL element of the present invention.

FIG. 8 is a schematic sectional view showing another example of the color filter substrate for an organic EL element of the present invention.

FIG. 9 is a schematic sectional view showing another example of the color filter substrate for an organic EL element of the present invention.

FIG. 10 is a schematic sectional view showing another example of the color filter substrate for an organic EL element of the present invention.

FIG. 11 is a schematic sectional view showing another example of the color filter substrate for an organic EL element of the present invention.

FIG. 12 is a schematic sectional view showing another example of the color filter substrate for an organic EL element of the present invention.

FIG. 13 is a schematic sectional view showing another example of the color filter substrate for an organic EL element of the present invention.

FIG. 14 is a schematic sectional view showing another example of the color filter substrate for an organic EL element of the present invention.

FIG. 15 is a schematic sectional view showing another example of the color filter substrate for an organic EL element of the present invention.

FIGS. 16A and 16B are schematic sectional views showing another example of the color filter substrate for an organic EL element of the present invention.

FIGS. 17A to 17C are schematic sectional views showing another example of the color filter substrate for an organic EL element of the present invention.

FIG. 18 is a schematic sectional view showing another example of the color filter substrate for an organic EL element of the present invention.

FIG. 19 is a schematic sectional view showing another example of the color filter substrate for an organic EL element of the present invention.

FIG. 20 is a schematic sectional view showing another example of the color filter substrate for an organic EL element of the present invention.

FIG. 21 is a schematic sectional view showing another example of the color filter substrate for an organic EL element of the present invention.

FIG. 22 is a schematic sectional view showing another example of the color filter substrate for an organic EL element of the present invention.

FIG. 23 is a schematic sectional view showing another example of the color filter substrate for an organic EL element of the present invention.

FIG. 24 is a schematic sectional view showing another example of the color filter substrate for an organic EL element of the present invention.

FIG. 25 is a schematic sectional view showing an example of the organic EL display device of the present invention,

FIG. 26 is a schematic sectional view showing another example of the organic EL display device of the present invention.

FIG. 27 is a schematic sectional view showing another example of the organic EL display device of the present invent ton.

FIG. 28 is a schematic sectional view showing another example of the organic EL display device of the present invention.

### DESCRIPTION OF THE PREFERRED EMBODIMENTS

Hereinafter, the color filter substrate for an organic EL element and the organic EL display device of the present invention will be explained in detail.

A. Color Filter Substrate for an Organic EL Element

First, the color filter substrate for an organic EL element of the present invention is described. The color filter substrate for an organic EL element of the invention can be classified into two embodiments in accordance with the structure of its conductive layer. Each of the embodiments is described hereinafter.

### I. First Embodiment

The first embodiment of the color filter substrate for an organic EL element of the present invention is characterized in being a color filter substrate for an organic EL element having a substrate, a colored layer formed in a pattern form on/over the substrate, and a transparent electrode layer and a conductive layer laminated, in any order, on/over the colored layer, wherein the conductive layer is a coated film.

The color filter substrate for an organic EL element of the present embodiment can be further classified into two embodiments in accordance with the order of the lamination of the transparent electrode layer and the conductive layer. The first embodiment of the color filter substrate for an organic EL element of the present embodiment is a product in which in order of a substrate/a colored layer/a transparent electrode layer/a conductive layer they are laminated, and the second embodiment is a product in which in order of a substrate/a colored layer/a conductive layer/a transparent electrode layer they are laminated. Each of the embodiments is described hereinafter.

### 1. First Embodiment

The first embodiment of the color filter substrate for an organic EL element of the invention is a color filter substrate for an organic EL element having a substrate, a colored layer formed in a pattern form on/over the substrate, a transparent electrode layer formed on/over the colored layer, and a conductive layer formed on/over the transparent electrode layer and having barrier property, wherein the conductive layer is a coated film.

The color filter substrate for an organic EL element of the embodiment will be explained with a reference to the drawings.

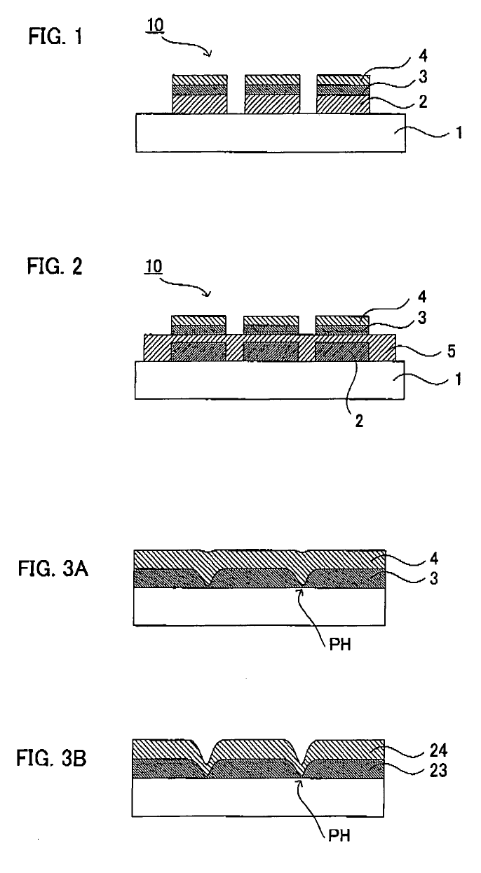

FIG. 1 is a schematic sectional view showing an example of the color filter substrate For an organic EL element of the present embodiment. As shown in FIG. 1, a color filter substrate for an organic EL element 10 according to this embodiment is a product in which a colored layer 2, a transparent electrode layer 3 and a conductive layer 4 are successively formed in a pattern form on a substrate 1.

FIG. 2 is a schematic sectional view showing another example of the color filter substrate for an organic EL element of the embodiment. As shown in FIG. 2, in the embodiment, an overcoat layer 5 may be formed between the colored layer 2 and the transparent electrode layer 3. The color filter substrate 10 for organic EL element shown in FIG. 2 is a product in which the colored layer 2 is formed in a pattern form on the substrate 1, the overcoat layer 5 is formed to cover this colored layer 2, and the transparent electrode layer 3 and the conductive layer 4 are successively formed on this overcoat layer 5.

In general, indium tin oxide (ITO), indium zinc oxide (IZO) or the like is used for a transparent electrode layer. Such a transparent electrode layer has a measure of barrier property against water vapor, oxygen, and gas generated from a colored layer, a color converting layer, an overcoat layer or the like. However, a transparent electrode layer is generally formed by sputtering or vacuum evaporation, and it is technically difficult to yield a transparent electrode layer having neither foreign substances such as particles nor pinholes by sputtering or vacuum evaporation. Therefore, production defects, microscopic structural defects, or other defects are present in any transparent electrode layer produced by sputtering or vacuum evaporation. For this reason, when a transparent electrode layer is used in an organic EL display device, it is necessary to block defects, such as foreign substances and pinholes, which are present in the transparent electrode layer. This is because gas generated from the colored layer, the color converting layer, the overcoat layer or the like flows out from the defects present in the transparent electrode layer, or water vapor or oxygen invades the transparent electrode layer from the defects so that dark spots may be generated.

Thus, in the present embodiment, the conductive layer 4, which is a coated film, is formed on/over the transparent electrode layer 3, whereby the color filter substrate can obtain barrier property against gas generated from the colored layer 2, the overcoat layer 5 and other layers, water vapor and oxygen. The conductive layer 4 in the embodiment is a coated film; therefore, even if the transparent electrode layer 3 has production defects, microscopic structural defects or other defects, the defects can be repaired by applying a conductive layer forming coating solution onto the transparent electrode layer 3. In other words, in the step of applying and drying the conductive layer forming coating solution, this solution infiltrates into pinholes present in the transparent electrode layer 3 so that the pinholes can be blocked.

In the embodiment, the conductive layer 4 is a coated film as described above, thereby making it possible to prevent the outflow of gas generated from the colored layer 2, the overcoat layer 5 and other members from the pinholes and so on in the transparent electrode layer 3. Additionally, the invasion of water vapor, oxygen and so on can be prevented. This makes it possible to attain good image display having no dark spots when the color filter substrate for an organic EL element of the embodiment is used in an organic EL display device.

In the embodiment, the formation of the conductive layer on the transparent electrode layer makes it possible that barrier property is obtained against gas generated from the colored layer, the overcoat layer and the other layers, water vapor and oxygen. It is therefore unnecessary to form a thick transparent barrier layer by sputtering, CVD or the like, as in the prior art. Thus, costs can be reduced.

Even if irregularities based on the colored layer are present, the barrier property of the transparent electrode layer and the conductive layer are not largely affected; therefore, it is unnecessary to form a resin protective layer for making the surface thereof smooth, and further pixel shrinkage or the like, based on expansion and contraction of the resin by thermal expansion thereof, is not generated.

Each of the members of this color filter substrate for an organic EL element is described hereinafter.

(1) Conductive Layer (Second Transparent Electrode Layer)

In the embodiment, two layers of the conductive layer and the transparent electrode layer, which will be detailed later, are integrated with each other so as to function as an electrode. Thus, the transparent electrode layer is a first transparent electrode layer, and the conductive layer is a second transparent electrode layer.

The second transparent electrode layer used in the embodiment is formed on/over the first transparent electrode layer, which will be detailed later, and is a coated film which has barrier property and is formed by coating.

The barrier property of the second transparent electrode layer used in the embodiment may be any barrier property that is capable of blocking defects, such as pinholes, in the first transparent electrode layer.

In the embodiment, it is sufficient that the two layers of the first and second transparent electrode layers are integrated with each other to function as an electrode. It is therefore unnecessary that the second transparent electrode layer has a sheet resistance value making it possible that this layer functions as an electrode by itself. Specifically, the sheet resistance value of the second transparent electrode layer is usually from about 100 to 10000 Ω/□, preferably from 100 to 1000 Ω/□.

The sheet resistance value is a value obtained by measuring the second transparent electrode layer by the four probe method with a Loresta-GP (MCP-T600) manufactured by Mitsubishi Chemical Corporation.

The second transparent electrode layer used in the present embodiment is not particularly limited if the layer has the above-mentioned natures and can be formed by coating. Specific examples of the material thereof include metal oxides such as indium tin oxide (ITO), indium zinc oxide (IZO), antimony tin oxide (ATO), aluminum zinc oxide (AZO), indium oxide, tin oxide, zinc oxide, cadmium oxide, gallium oxide, In₂O₃(ZnO)ₘ, InGaO₃(ZnO)ₘ, and CaNO₄. Moreover, conductive metals such as Au, Ag, Cu, Pt, Sn, Zn, Li, Be, B, Na, Mg, Al, Si, K, Ca, Sc, V, Cr, Mn, Fe, Co, Ni, Ga, Rb, Sr, Y, Zr, Nb, Pb, Mo, Cd, In, Sb, Cs, Ba, La, Hf, Ta, W, Ti, Pb, Bi, Ce, Pr, Nd, Pm, Sm, Eu, Gd, Tb, Dy, Ho, Er, Tm, Yb, Lu, and oxides thereof can be cited. Among then, ITO is preferable. Further, the second transparent electrode layer made of at least one kind selected from the group consisting of Au, Ag, Cu, Pt, Sn, Zn, In, Pb and Al, and oxides thereof is also preferable.

In this case, the material used in the second transparent electrode layer and that used in the first transparent electrode layer, which will be detailed later, may be the same or different, but are preferably the same. If these materials are the same, it is possible to form the two layers of the first and second transparent electrode layers over the entire face of a substrate on/over which a colored layer and other layers are formed and subsequently use, for example, a single etching solution to pattern the two layers simultaneously. This makes it possible to make the production process simple.

Even if the materials used in the first and second transparent electrode layers are different, the two layers can be etched with a single etching solution according to circumstances when the film thickness of the second transparent electrode layer is relatively thin. This situation is varied in accordance with the used materials; for example, when an ITO film of 150 nm thickness is formed as the first transparent electrode layer and a Ag film of 5 nm thickness is formed as the second transparent electrode layer, the two of the ITO film and the Ag film can be simultaneously patterned with an etching solution for the ITO film.

In the present embodiment, the second transparent electrode layer preferably contains fine particles having an average particle size of 50 nm or less. The average particle size of the fine particles is smaller than the size of defects, such as pinholes, in the first transparent electrode layer, and thus the defects can be effectively blocked. By the size effect peculiar to the fine particles, the temperature for firing a second transparent electrode layer forming coating solution which contains the fine particles, at the time of the formation of the second transparent electrode layer, can be made lower than ordinary firing temperatures. Consequently, the coating solution can be fired at not higher than the upper temperature limit of the colored layer.

Examples of the fine particles include particles of any one of the above-mentioned metal oxides, conductive metals, and oxides of conductive metals. In the present embodiment, the fine particles are preferably particles made of Indium tin oxide (ITO) since ITO is preferably used for the second transparent electrode layer. Further, the fine particles may be fine particles made of at least one kind selected from the group consisting of Au, Ag, Cu, Pt, Sn, Zn, In, Pb and Al, and oxides thereof is also preferable.

The average particle size of the fine particles may be any particle size that makes it possible to block defects, such as pinholes, in the first transparent electrode layer, and is specifically within a range from 0.5 to 50=n, preferably from 1 to 10 nm. If the average particle size is too small, the particles are not easily produced. On the other hand, if the average particle size is too large, defects, such as pinholes, in the first transparent electrode layer, may not be easily blocked. Moreover, the fall in the firing temperature, based on the size effect peculiar to the fine particles, cannot be expected.

The average particle size is generally a size used to indicate the particle size of particles. In the invention, the particle size is a value measured by the laser method. The laser method is a method of dispersing particles into a solvent, radiating a laser ray onto the particle-dispersed solvent, making the resultant scattered light fine, and carrying out an operation to measure the average particle size and the particle size distribution thereof, and others. The average particle size is a value measured by use of a particle size analyzer, Microtrack UFA Model-9230, manufactured by Leeds & Northup Co. as a particle size measuring device based on the laser method.

The second transparent electrode layer containing such fine particles is formed by applying a second transparent electrode layer forming coating solution which contains the fine particles and sintering the coating solution, as will be detailed later. Thus, it appears that the second transparent electrode layer consists of the fine particles. Accordingly, the content by percentage of the fine particles in the second transparent electrode layer would be 100%.

From a scanning electron microscope (SEM) photograph (magnifications: 50000 or more) of the second transparent electrode layer, it can be confirmed that this layer contains the fine particles. At this time, the interface between the first and second transparent electrode layers is first checked. If the shape of grains melted by the firing at the time of forming the second transparent electrode layer is observed in this layer, it is decided that the layer contains the fine particles.

When the color filter substrate for an organic EL element of the present embodiment is used in an organic EL display device, light is taken out from the substrate side thereof. It is therefore preferred that the second transparent electrode layer has light transmissivity. About the light transmissivity of the second transparent electrode layer, the light transmissivity is preferably 60% or more, more preferably 80% or more, and even more preferably 90% or more in the wavelength range of visible rays.

The light transmissivity is an average of values measured with a UV-3100 manufactured by Shimadzu Corporation in the range of wavelengths of 380 to 800 nm.

The film thickness of the second transparent electrode layer is not particularly limited if the thickness causes the above-mentioned barrier property, conductivity and light transmissivity to be satisfied. Specifically, the thickness can be set into the range of 5 to 2000 nm, and is preferably from 50 to 500 nm. If the film thickness of the second transparent electrode layer is too thick, the light transmissivity may lower or the layer may be peeled from the first transparent electrode layer. Furthermore, the second transparent electrode layer is formed on the topmost face of the color filter substrate for an organic EL element of the embodiment; therefore, the resistance of its terminal-connection areas may become high if the film thickness of the second transparent electrode layer is too thick. On the other hand, if the film thickness of the second transparent electrode layer is too thin, pinholes and so on present in the first transparent electrode layer are not easily blocked.

When any one of the above-mentioned conductive metals and oxides thereof is used for the second transparent electrode layer, the light transmissivity is lost if the film thickness of this layer is too thick. It is therefore preferred that the thickness is relatively thin within the above-mentioned range. Specifically, the thickness is preferably in the range of 5 to 50 nm.

The second transparent electrode layer used in the present embodiment is a coated film. The “coated film” means a film formed by any wet process, and is, for example, a film formed by coating a coating solution.

In general, a transparent electrode layer is formed by sputtering or vacuum evaporation. Whether a second transparent electrode layer is a layer formed by coating or by sputtering or vacuum evaporation can be checked from, for example, a scanning electron microscopy (SEM) photograph thereof. If the layer is a layer formed by coating, a second transparent electrode layer forming coating solution, for forming a second transparent electrode layer 4, enters pinholes PH in a first transparent electrode layer 3, as shown in FIG. 3A, because of the level property of the second transparent electrode layer forming coating solution; therefore, it appears that the vicinity of the pinholes PH is made substantially flat. On the other hand, if the layer is a layer formed by sputtering or the like, pinholes PH in a transparent electrode layer 23 cannot be sufficiently blocked with a sputtering film 24, as shown in FIG. 3B, so that the surface cannot be made flat. When pinholes in the first transparent electrode layer are substantially completely blocked in this way so that the surface is made flat, it can be said that the second transparent electrode layer is a layer formed by coating.

In the embodiment, the method for forming the second transparent electrode layer is a coating method, and examples thereof include a method using a sol-gel process, and a method of using a second transparent electrode layer forming coating solution which contains fine particles. When the sol-gel process is used, a second transparent electrode layer forming coating solution is applied onto the first transparent electrode layer and then heated to conduct polycondensation reaction, whereby the second transparent electrode layer can be formed. In the method using fine particles, a second transparent electrode layer forming coating solution is applied onto the first transparent electrode layer and then sintered, whereby the second transparent electrode layer can be formed. The method for patterning the second transparent electrode layer is usually photolithography.

It is particularly preferred in the embodiment that the second transparent electrode layer is formed by the method using a second transparent electrode layer forming coating solution which contains fine particles. As described above, pinholes can be effectively blocked with the fine particles, and further at the time of forming the second transparent electrode layer the coating solution for forming this layer can be fired at not higher than the upper temperature limit of the colored layer by the size effect peculiar to the fine particles.

The following describes a method for forming a second transparent electrode layer, using such a second transparent electrode layer forming coating solution which contains fine particles.

This method, used in the present embodiment, can be classified into two aspects in accordance with the constituent material(s) of the second transparent electrode layer. The first aspect is for the case that the second transparent electrode layer is made of a metal oxide, and the second aspect is for the case that the second transparent electrode layer is a conductive metal layer made of at least one of a conductive metal and a conductive metal oxide.

The following describes the aspects separately.

(i) First Aspect

The method for forming a second transparent electrode layer of this aspect is a aspect of preparing a conductive layer forming dispersion liquid which contains fine particles of a metal which is to be contained in a metal oxide, or fine particles of an alloy made of metals which are to be contained in the metal oxide; coating the conductive layer forming dispersion liquid onto a first transparent electrode layer, and firing the resultant at 150 to 250° C. in the atmosphere of oxygen gas or ozone gas having an atmospheric pressure or in a plasma atmosphere of a gas in which oxygen gas or ozone gas is added to an inert gas, thereby performing oxidization and sintering simultaneously to form the above-mentioned conductive layer made of a metal oxide.

According to the present aspect, the firing at the predetermined temperature in the oxidizing atmosphere makes it possible to advance oxidization and sintering simultaneously to form the conductive layer. At this time, the dispersion on the first transparent electrode layer can be fired at not higher than the upper temperature limit of the colored layer since the fine particles are sintered in a dense form at a temperature far lower than the firing temperatures for ordinary conductive layers.

As for the metal oxide for the present aspect, there is no limit as long as it is a metal oxide capable of forming second transparent electrode layer having the barrier, a conductivity and a light transmissivity. Specific examples are metal oxides such as indium oxide, tin oxide, zinc oxide, cadmium oxide, gallium oxide, In₂O₃(ZnO)ₘ, InGaO₃(ZnO)ₘ, and CaWO₄, indium tin oxide (ITO), antimony tin oxide (ATO), indium zinc oxide (IZO), and aluminum zinc oxide (AZO). Among them, ITO, ATO, IZO, zinc oxide, tin oxide and CaWO₄ are preferable. ITO, in particular, is preferable. Examples of the fine particles in this manner include fine particles of any metal contained in the above-mentioned metal oxides, and fine particles of any alloy made of metals contained in the metal oxides.

The conductive layer forming dispersion liquid used in this manner is a dispersion in which the above-mentioned fine particles are dispersed in a solvent. The solvent to be used may be appropriately selected in accordance with the used fine particles. Examples thereof include alcohols such as methanol, ethanol, propanol, Isopropyl alcohol, and butanol; glycols such as ethylene glycol; ketons such as acetone, methyl ethyl ketone and diethyl ketone; esters such as ethyl acetate, butyl acetate, and benzyl acetate; ether alcohols such as methoxyethanol, and ethoxyethanol; ethers such as dioxane and tetrahydrofuran; acid amides such as N,N-dimethylformamide; and aromatic hydrocarbons such as toluene and xylene. The solvent may be water.

The amount of the used solvent may be appropriately selected in accordance with the used fine particles in such a manner that the dispersion can easily be coated and further a desired film thickness can be obtained. For example, it is advisable to incorporate the fine particles into the solvent in an amount of 1 to 50% by weight of the solvent, preferably in an amount of 10 to 40% by weight thereof. If the content of the fine particles is too small, defects such as pinholes in the first transparent electrode layer are not easily blocked. On the other hand, if the content of the fine particles is too large, the fluidity lowers so that defects such as pinholes in the first transparent electrode layer are not easily blocked. Furthermore, the flatness or smoothness of the surface of the second transparent electrode layer may be damaged.

Examples of the method for coating the conductive layer forming dispersion liquid include spin coating, spray coating, inkjet printing, dip coating, roll coating and screen printing.

After the coating of the conductive layer forming dispersion liquid, the resultant is fired at a temperature far lower than the temperature necessary for sintering a simple substance of the fine particles (generally, 500 to 700° C.), that is, at 150 to 250° C. in an oxidizing atmosphere so as to perform oxidization and sintering simultaneously, thereby yielding an conductive layer.

The firing temperature is set into the range of 150 to 250° C. If the firing temperature is too low, sufficient sintering may not be attained. If the firing temperature is too high, problems are caused in the production process.

The oxidizing atmosphere may be an oxygen gas or ozone gas atmosphere having an atmospheric pressure, or a plasma atmosphere such as an atmospheric plasma of a gas in which oxygen gas or ozone gas is added to an inert gas or a rare gas such as helium.

After the coating of the conductive layer forming dispersion liquid and before the firing thereof, the coated conductive layer forming dispersion liquid may be dried at a predetermined temperature.

The oxidization and the sintering are simultaneously performed in the oxidizing atmosphere; at this time, preferably, ultraviolet rays are radiated. This gives more advantageous effects for shortening the production time and making the firing temperature lower. It is allowable to use what is called plasma sintering, using atmospheric pressure plasma or the like.

(ii) Second Aspect

The method for forming a second transparent electrode layer according to the present aspect is a aspect of coating a conductive metal layer forming dispersion liquid which containing fine particles made of a conductive metal onto a first transparent electrode layer and then sintering the resultant at 180 to 250° C. in the atmosphere, thereby forming a conductive metal layer made of at least one of the conductive metal and an oxide of the conductive metal.

According to the present aspect, the dispersion on the first transparent electrode layer can be fired at not higher than the upper temperature limit of the colored layer since the fine particles are sintered in a dense form at a temperature far lower than the firing temperatures for ordinary conductive layers.

In the present aspect, the fine particles of the conductive metal are used to form the second transparent electrode layer. Accordingly, if the film thickness of the second transparent electrode layer is too thick, the light transmissivity is damaged as described above; it is therefore necessary to form the layer so as to make the film thickness relatively thin. Specific ranges of the film thickness are as described above.

As for the fine particles of the conductive metal, at least one kind of the fine particles of Ag, Sn and Zn is preferable. Besides, at least one kind of the fine particles selected from a group of Li, Be, B, Na, Mg, Al, Si, K, Ca, Sc, V, Cr. Mn, Fe, Co, Ni, Ga, Rb, Sr, Y, Zr, Nb, Cu, Pb, Mo, Cd, In, Sb, Cs, Ba, La, Hf, Ta, W, Ti, Pb, Bi, Ce, Pr, Nd, Pm, Sm, Eu, Gd, Tb, Dy, Ho, Er, Tm, Yb and Lu can be used. Among them, the fine particles selected from Ag, Sn, Zn, In, Cu and Pb are preferable to lower the sintering temperature.

The conductive metal layer forming dispersion liquid is a dispersion in which the above-mentioned conductive metal fine particles are dispersed in a solvent. The solvent, the amount of the solvent used, the method for coating the conductive metal layer forming dispersion liquid are equivalent to those about the conductive layer forming dispersion liquid described about the first aspect.

After the coating of the conductive metal layer forming dispersion liquid, the resultant is fired at a temperature far lower than the temperature necessary for sintering a simple substance of the fine particles of the conductive metal (generally, 400 to 600° C.), that is, at 180 to 250° C. in the atmosphere so as to form a film. In this way, a conductive metal layer is yielded.

In this manner, the conductive metal may be somewhat oxidized in the production process of the conductive metal layer. Accordingly, the conductive metal layer may contain fine particles of an oxide of the conductive metal; therefore, the conductive metal layer is rendered a layer made of at least one of the conductive metal and the oxide of the conductive metal.

The firing temperature is set into the range of 180 to 250° C. If the firing temperature is too low, sufficient sintering may not be attained. If the firing temperature is too high, problems are caused in the production process.

(2) Transparent Electrode Layer (First Transparent Electrode Layer)

The following describes the first transparent electrode layer used in the present embodiment. In the embodiment, two layers of the transparent electrode layer and the conductive layer are integrated with each other to function as an electrode, as described above. Thus, the transparent electrode layer is called the first transparent electrode layer.

The first transparent electrode layer is a layer formed on/over the colored layer, which will be detailed later.

The first transparent electrode layer may be a layer that is ordinarily used as a transparent electrode layer of an organic EL element, and is preferably made of ITO.

When the color filter substrate for an organic EL element of the embodiment is used in an organic EL display device, light is taken out from the substrate side thereof. It is therefore preferred that the first transparent electrode layer has a light transmissivity similar to that of the second transparent electrode layer.

The film thickness of the first transparent electrode layer is not particularly limited. Specifically, the thickness can be set into the range of 50 to 500 nm, and is preferably from 100 to 200 nm. If the film thickness of the first transparent electrode layer is too thick, the light transmissivity may lower or the layer may be peeled from the substrate. On the other hand, if the thickness is too thin, desired electric properties may not be obtained.

As described above, it is sufficient that the two layers of the first and second transparent electrode layers are integrated with each other to function as an electrode; in light of this matter, specifically, the sheet resistance value of the first transparent electrode layer is from about 10 to 50 Ω/□, preferably from 10 to 30 Ω/□.

The method for measuring the sheet resistance value is the same as described in the item of the above-mentioned conductive layer (the second transparent electrode layer).

The first transparent electrode layer used in the embodiment can be formed by a method for forming an ordinary transparent electrode layer. Examples of the method include sputtering and vacuum evaporation.

(3) Inorganic Layer

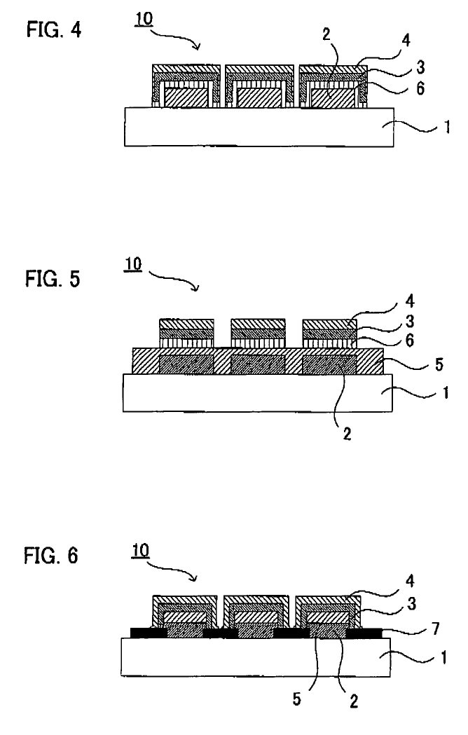

As shown in FIG. 4, in the embodiment, an inorganic layer 6 having barrier property may be formed between the colored layer 2 and the first transparent electrode layer 3. As shown in, e.g., FIG. 5, an inorganic layer 6 having barrier property may be formed between the overcoat layer 5 and the first transparent electrode layer 3.

In the embodiment, the formation of the inorganic layer makes it possible to cancel irregularities of the colored layer or foreign substances present on the colored layer. If irregularities are present in the colored layer, the shape of the irregularities is reflected on the first transparent electrode layer formed on/over the colored layer. Thus, when the color filter substrate for an organic EL element of the embodiment is used in an organic EL display device, defects are easily generated in its thin organic EL layer by damage by electrostatic discharge or the like. Such defective sites become fault spots (dark areas) to deteriorate the display quality thereof. It is therefore preferred to make the colored layer surface smooth by the formation of the inorganic layer.

Since the first transparent electrode layer is formed by sputtering or vacuum evaporation as described above, adhesive property thereof to the colored layer or the overcoat layer may not be sufficient. In the embodiment, the formation of the inorganic layer makes it possible to improve adhesive force between the first transparent electrode layer and the colored layer or overcoat layer so as to restrain the first transparent electrode layer from being peeled from the colored layer or the overcoat layer.

When the inorganic layer is formed, the inorganic layer, which has barrier property, the first transparent electrode layer and the second transparent electrode layer, which has barrier property, are successively laminated on the colored layer. This makes it possible to heighten the barrier property against gas generated from the colored layer, the overcoat layer and so on, water vapor and oxygen.

When the color filter substrate for an organic EL element of the embodiment is used in an organic EL display device, light is taken out from the substrate side thereof; it is therefore preferred that the inorganic layer has light transmissivity. Specifically, it is preferred that the inorganic layer has a light transmissivity similar to that of the second transparent electrode layer.

The inorganic layer used in the embodiment has the above-mentioned natures, and is not particularly limited if the layer is a layer capable of making the colored layer surface smooth. Two preferable aspects thereof can be given. One of the preferred aspects is a aspect in which the inorganic layer is a barrier layer used in an ordinary organic EL element (third aspect), and the other of the preferred aspects is a aspect in which the inorganic layer is a coated film (fourth aspect).

Each of the aspects is described hereinafter.

(i) Third Aspect

The inorganic layer according to the present aspect is a barrier layer used in an ordinary EL element. In the aspect, the formation of the ordinary barrier layer makes it possible to heighten the barrier property of the color filter substrate for an organic EL element.

The material used in the barrier layer according to the aspect may be a material which is ordinarily used in an organic EL element. Examples thereof include inorganic oxides such as silicon oxide, silicon oxynitride, aluminum oxide, titanium oxide, tantalum oxide, zinc oxide, magnesium oxide, tin oxide, and indium oxide alloy; inorganic nitrides such as silicon nitride, aluminum nitride, titanium nitride, and silicon carbonitride; and metals such as aluminum, silver, tin, chromium, nickel, and titanium.

Of the above-mentioned materials, silicon oxide and silicon oxynitride are preferred since these materials are good in adhesive property to the colored layer and the first transparent electrode layer. A thin film made of such a silicon oxide can be made from an organic silicon compound as a raw material. Specific examples of the organic silicon compound include 1,1,3,3-tetramethyldisiloxane, hexamethyldisiloxane, vinyltrimethylsilane, hexamethyldisilane, methylsilane, dimethylsilane, trimethylsilane, diethylsilane, propylsilane, phenylsilane, vinyltriethoxysilane, tetramethoxysilane, phenyltriethoxysilane, methyltriethoxysilane, and octamethylcyclotetrasiloxane. Of these organic silicon compounds, tetramethoxysilane (TMOS) and hexamethyldisiloxane (HMDSO) are preferably used since these are excellent in handleability and properties of vapor-deposited films therefrom.

When the overcoat layer, which will be detailed later, is formed in the present embodiment, it is preferred that the barrier layer has no conductivity for the following reason: when a barrier layer is formed over the entire face of the substrate on/over which the overcoat layer and soon are formed by sputtering or the like as described above, conduction is attained between the first transparent electrode layer and the barrier layer if the barrier layer has conductivity; consequently, it is feared that adjacent signals in the first transparent electrode layer cannot be dependently operated.

The barrier layer may have a mono-layered structure, or a multi-layered structure, which has plural sub-layers, in order to improve the barrier property. The sub-layers may be composed of the same kinds of layers or different kinds of layers.

The barrier layer may be formed over the entire face of the substrate on/over which the colored layer, the overcoat layer and so on are formed, or may be formed in a pattern form.

The barrier layer can be formed by sputtering, CVD, vacuum evaporation, dipping or the like.

The film thickness of the barrier layer is not particularly limited if the thickness gives barrier property against gas generated from the colored layer and soon, water vapor and oxygen and causes the above-mentioned light transmissivity to be satisfied. The thickness is appropriately selected in accordance with the above-mentioned material, and is usually from 5 to 5000 nm, preferably from 5 to 500 nm. When aluminum oxide or silicon oxide is used, the thickness is more preferably from 10 to 300 nm. If the film thickness of the barrier layer is too thin, the barrier property lowers. On the other hand, if the film thickness is too thick, the barrier layer may be cracked when it is formed. Moreover, the light transmissivity may lower.

(ii) Fourth Aspect

The inorganic layer in the present aspect is a coated film. According to the aspect, the generation of defects such as pinholes penetrating through the inorganic layer to reach the surface of the second transparent electrode layer can be prevented even if defects such as pinholes are present in the first transparent electrode layer. This is because the inorganic layer and the second transparent electrode layer are coated films. It is therefore possible to prevent the outflow of gas generated from the colored layer and so on and further prevent the invasion of oxygen, water vapor and so on.

The inorganic layer in the aspect preferably has conductivity. When the inorganic layer has conductivity, the inorganic layer is integrated with the first and second transparent electrode layers to cause the resultant to function as an electrode; therefore, the electric resistance can be made small.

It is sufficient that the conductivity of the inorganic layer has a sheet resistance similar to that of the second transparent electrode layer.

The material used in the inorganic layer is not particularly limited if the material can be painted and has conductivity. For example, the material may be the same as used in the second transparent electrode layer. Specific examples of the material thereof include metal oxides such as indium oxide, tin oxide, zinc oxide, cadmium oxide, gallium oxide, In₂O₃(ZnO)ₘ, InGaO₃(ZnO), CaWO₄, indium tin oxide (ITO), antimony tin oxide (ATO), indium zinc oxide (IZO), and aluminum zinc oxide (AZO). Moreover, conductive metals such as Au, Ag, Cu, Pt, Sn, Zn, Li, Be, B, Na, Mg, Al, Si, K, Ca, Sc, V, Cr, Mn, Fe, Co, Ni, Ga, Rb, Sr, Y, Zr, Nb, Pb, Mo, Cd, In, Sb, Cs, Ba, La, Hf, Ta, W, Ti, Pb, Bi, Ce, Pr, Nd, Pm, Sm, Eu, Gd, Tb, Dy, Ho, Er, Tm, Yb, Lu, and oxides thereof can be cited. Among them, ITO is preferable. Further, the inorganic layer made of at least one kind selected from the group consisting of Au, Ag, Cu, Pt, Sn, Zn, In, Pb and Al, and oxides hereof is also preferable.

In this case, the material used in the inorganic layer and that used in the first transparent electrode layer and the second transparent electrode layer may be the same or different, but are preferably the same. If these materials are the same, it is possible to form the three layers of the inorganic layer and the first and second transparent electrode layers over the entire face of a substrate on/over which a colored layer is formed and subsequently use, for example, a single etching solution to pattern the three layers simultaneously.

In the present aspect, the inorganic layer preferably contains fine particles having an average particle size of 50 mm or less. By the size effect peculiar to the fine particles, the temperature for firing an inorganic layer forming coating solution which contains the fine particles, at the time of the formation of the inorganic layer, can be made lower than ordinary firing temperatures. Consequently, the coating solution can be fired at not higher than the upper temperature limit of the colored layer.

The fine particles are equal to those described in the item of the second transparent electrode layer. Thus, the description thereof is not repeated herein.

The film thickness of the inorganic layer is equal to that of the second transparent electrode layer.

The inorganic layer in the present aspect is a coated film formed by coating. Whether or not an inorganic layer is a layer formed by coating can be checked by the method described in the item of the above-mentioned conductive layer (the second transparent electrode layer).

In the aspect, the method for forming the inorganic layer is a coating method, and examples thereof include a method using a sol-gel process, and a method of using a inorganic layer forming coating solution which contains fine particles. The method for patterning the inorganic layer is usually photolithography.

It is particularly preferred in the aspect that the inorganic layer is formed by the method using a inorganic layer forming coating solution which contains fine particles. As described above, pinholes can be effectively blocked with the fine particles, and further at the time of forming the inorganic layer the coating solution for forming this layer can be fired at not higher than the upper temperature limit of the colored layer by the size effect peculiar to the fine particles. Furthermore, the inorganic layer formed by using such an inorganic layer forming coating solution, which contains fine particles, has an advantage that the layer is good in adhesive property to the colored layer and the first transparent electrode layer.

The method for forming the inorganic layer is equivalent to the method for forming the second transparent electrode layer. Thus, the description thereof is not repeated herein.

(iii) Others

The inorganic layer used in the embodiment may be a laminate in which the above-mentioned barrier layer and coated layer are laminated. In this case, from the colored layer side or the overcoat layer side, the barrier layer and the coated layer are successively formed. This makes it possible that even if pinholes are present in the barrier layer, the pinholes are blocked with the coated film.

The inorganic layer may be a laminate in which the above-mentioned barrier layer and coated layer having no conductivity are laminated. In this case, from the colored layer side or the overcoat layer side, the barrier layer and the coated layer having no conductivity are successively formed. In the same manner as described above, this makes it possible that even if pinholes are present in the barrier layer, the pinholes are blocked with the coated film having no conductivity. This coated film having no conductivity may be a particle-dispersed film or a sol-gel film containing an inorganic oxide, such as silicon oxide, silicon oxynitride, aluminum oxide, titanium oxide, tantalum oxide, zinc oxide, magnesium oxide, tin oxide or indium oxide alloy, or an inorganic nitride, such as silicon nitride, aluminum nitride, titanium nitride or silicon carbonitride, or a silica-coated film containing polysilazane or the like.

(4) Characteristics of the Transparent Electrode Layer (the First Transparent Electrode Layer), the Conductive Layer (the Second Transparent Electrode Layer), and the Inorganic Layer

In the present embodiment, the formation of the second transparent electrode layer on/over the first transparent electrode layer as the coated film makes it possible to give barrier property against gas generated from the colored layer, the overcoat layer and so on, water vapor and oxygen. In connection with the barrier property obtained when the first and second transparent electrode layers are formed, the oxygen gas transmittance is preferably 1 cc/m²/day/atm or less, more preferably 0.5 cc/m²/day/atm or less. The water vapor transmittance is preferably 1 g/m²/day or less, more preferably 0.5 g/m²/day or less.

When the inorganic layer is formed between the colored layer or overcoat layer and the first transparent electrode layer in the embodiment, the barrier property against oxygen, water vapor and gas from the colored layer and so on can be made high. In connection with the barrier property obtained when the inorganic layer, the first transparent electrode layer and the second transparent electrode layer are formed in this way, the oxygen gas transmittance is preferably 1 cc/m²/day/atm or less, more preferably 0.5 cc/m²/day/atm or less, and ever more preferably 0.1 cc/m²/day/atm or less. The water vapor transmittance is preferably 1 g/m²/day or less, more preferably 0.5 g/m²/day or less, and even more preferably 0.1 g/m²/day or less.

When the oxygen gas transmittance and the water vapor transmittance are within the above-mentioned ranges, the barrier property of the color filter substrate for an organic EL element of the embodiment can be made high; thus, this color filter substrate can be preferably used in an organic EL element having members which are easily affected by oxygen, water vapor, or gas from the colored layer and so on.

The oxygen gas transmittance is a value measured by use of an oxygen gas transmittance meter (trade name. OX-TRAN 2/20, manufactured by MOCON Inc.) at a measuring temperature of 23° C. and a relative humidity of 90%. The water vapor transmittance is a value measured by use of a water vapor transmittance meter (trade name: PERMATRAN-W 3/31, manufactured by MOCON Inc.) at a measuring temperature of 37° C. and a relative humidity of 100%.

As described above, when the color filter substrate for an organic EL element of the embodiment is used in an organic EL display device, an organic EL layer is formed on/over the second transparent electrode layer; it is therefore preferred that the surface of the second transparent electrode layer is smooth in order to restrain the generation of dark areas. In particular, when the inorganic layer or the overcoat layer is formed, the colored layer surface can be made smooth; therefore, it appears that the second transparent electrode layer surface can also be made smooth. Specifically, the average surface roughness (Ra) of the second transparent electrode layer is preferably from 10 to 500 Å, more preferably form 10 to 100 Å. When the average surface roughness (Ra) is within the range, the generation of dark areas can be restrained to yield a good display image when the color filter substrate for an organic EL element of the embodiment is used in an organic EL display device.

The average surface roughness (Ra) of the second transparent electrode layer is a value obtained by measuring an observing area of 5 μm² therein with a scanning probe microscope (SPM: D-3000, manufactured by Digital Instruments) under the following measuring conditions:

(Measuring Condition)

Tapping mode,

Set point: about 1.6,

Scan line: 256, and

Frequency: 0.8 Hz.

(5) Overcoat Layer

It is allowable in the present embodiment that an overcoat layer is formed between the colored layer and the transparent electrode layer. The overcoat layer is a layer formed on/over the colored layer, which will be detailed later, and is a layer for protecting the colored layer and making the colored layer surface smooth. Moreover, the overcoat layer is formed to cancel irregularities based on the patterned colored layer and flatten the surface of the substrate in which the colored layer is formed. If the flatness of the colored layer is poor or irregularities based on the colored layer are present, the poor flatness of the colored layer or the shape of the irregularities is reflected on the second transparent electrode layer, which is formed on/over the colored layer. Thus, when this is used to produce an organic EL display device, defects based on damage by electrostatic discharge or the like are easily generated in a thin organic EL layer formed on/over the second transparent electrode layer. Such defects become fault spots (dark areas) to deteriorate the display quality thereof. It is therefore preferred to form the overcoat layer to make the colored layer surface flat and further make the irregularities based on the colored layer flat.

The formation of the overcoat layer makes it possible to make the first and second transparent electrode layers flat, so that these layers become dense layers to heighten the barrier property thereof.

The overcoat layer used in the embodiment may be formed over the substrate on/over which the colored layer is formed, or may be formed in a pattern form to cover at least the surface of the colored layer.

The wording “the overcoat layer is formed over the substrate on/over which the colored layer is formed” means that, as shown in, e.g., FIG. 2, the overcoat layer 5 is formed over the entire face of the substrate 1 to cover the whole of the colored layer 2. As shown in FIG. 2, edges of the substrate 1 may be not covered with the overcoat layer 5.

When the overcoat layer is formed over the entire face of the substrate in this way, there is produced an advantageous effect that irregularities based on the patterned colored layer can be cancelled to make the entire face of the substrate flat.

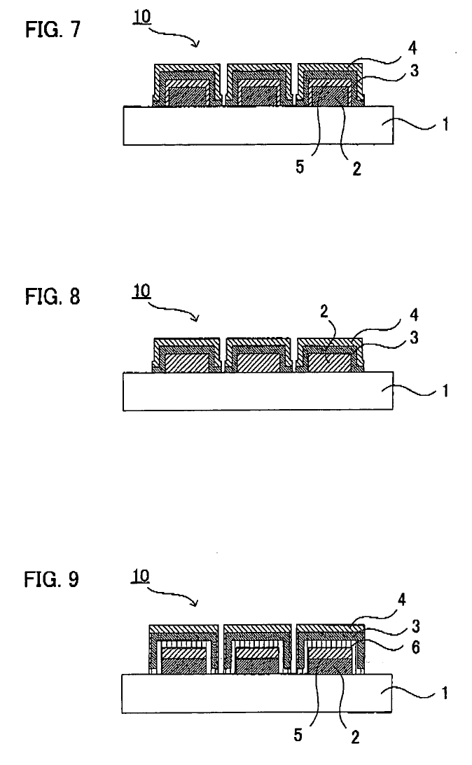

The wording “the overcoat layer is formed in a pattern form to cover at least the surface of the colored layer” means a case in which the overcoat layer is formed in a pattern form to cover a part of the colored layer surface and a case in which the overcoat layer is formed in a pattern form to cover the whole of the colored layer surface. For example, in FIG. 6, the overcoat layer 5 is formed in a pattern form to cover the whole of the surface of the colored layer 2. As shown in, e.g., FIG. 7, the overcoat layer 5 may be formed in a pattern form to cover not only the surface of the colored layer 2 but also side faces thereof.

When the overcoat layer is formed in a pattern form in this way, the area of the overcoat layer which is exposed is smaller than when the overcoat layer is formed on/over the entire face of the substrate; therefore, it appears that the generation of gas from the overcoat layer can be relatively restrained. As shown in, e.g., FIG. 6, when the overcoat layer 5 is formed in a pattern form to cover the surface of the colored layer 2, the first and second transparent electrode layers 3 and 4 can be formed to cover the colored layer 2 and the entire face of the overcoat layer 5. According to this, the colored layer 2 and the overcoat layer 5 are not exposed, so that the outflow of gas generated from the colored layer 2 and the overcoat layer 5 can be effectively restrained, as will be detailed later. As shown in, e.g., FIG. 7, when the overcoat layer 5 is formed in a pattern form to cover the surface and side faces of the colored layer 2, the first and second transparent electrode layers 3 and 4 can be formed not to make the overcoat layer exposed in the same manner as in FIG. 6; accordingly, the advantageous effect of restraining the outflow of the gas can be heightened.

The overcoat layer used in the embodiment preferably has light transmissivity. Specifically, the light transmittance thereof is preferably 70% or more, more preferably 90% or more in the wavelength range of visible rays. This makes it possible that when the color filter substrate is used to produce an organic EL display device, the brightness thereof is made high. The method for measuring the light transmittance is equal to that described in the item of the above-mentioned conductive layer (the second transparent electrode layer).

The material used in the overcoat layer is not particularly limited if the material makes it possible to flatten the colored layer surface and further has light transmissivity. Examples thereof include acrylic resin, polyimide, epoxy resin, and cyclic olefin resin. There may be used an acrylic acid type, methacrylic acid type, polyvinyl cinnamate type, or cyclic rubber type photocurable resist material, which has a reactive vinyl group.

The overcoat layer in the embodiment can be formed by coating the above-mentioned material by spin coating, roll coating, bar coating, cast coating, inkjet printing or the like. The overcoat layer can be formed in a pattern by exposing a coated film obtained by coating the above-mentioned material to light through a predetermined photomask and then removing unnecessary portions therefrom with a developing solution.

The film thickness of the overcoat layer is a thickness sufficient for making it possible to flatten the colored layer surface, is preferably a thickness which makes it possible to flatten irregularities based on the colored layer, and is even more preferably a thickness which makes it possible to flatten irregularities based on the colored layer and the color converting layer. Specifically, the thickness can be set into the range of 1 to 10 μm, and is preferably from 2 to 4 μm. When the color converting layer is formed, the film thickness thereof is relatively thick; therefore, the film thickness of the overcoat layer is preferably from 3 to 15 μm, more preferably from 5 to 10 μm.

The overcoat layer may be formed by printing or coating a low melting point glass paste consisting of a low melting point glass frit, a binder resin, and a solvent.

(6) Arrangement of the Transparent Electrode Layer (the First Transparent Electrode Layer), the Conductive Layer (the Second Transparent Electrode Layer), the Inorganic Layer, and the Overcoat Layer

As shown in, e.g., FIG. 1, if the first and second transparent electrode layers 3 and 4 are formed on/over the colored layer 2 in the embodiment, the outflow of most of gas generated from the colored layer 2 can be prevented; it is particularly preferred that at least one of the first and second transparent electrode layers is formed to cover the entire face of the patterned colored layer. The covering makes it possible to prevent more effectively the outflow of gas generated from the colored layer.

It is sufficient that the first and second transparent electrode layers are formed in such a manner that at least one thereof covers the entire face of the patterned colored layer. As shown in, e.g., FIG. 8, it is preferred that two of the first and second transparent electrode layers 3 and 4 are formed to cover the entire face of the patterned colored layer 2. This makes is possible to prevent even more effectively the outflow of gas generated from the colored layer.

The wording “being formed to cover the entire face of the colored layer” means that all of the surface and side faces of the colored layer are covered so that the colored layer is not exposed, and is, for example, a case in which the first and second transparent electrode layers 3 and 4 are formed in such a manner that none of the surfaces of the colored layer 2 are exposed as shown in FIG. 8.

When no overcoat layer is formed and the inorganic layer is a barrier layer in the embodiment, it is preferred that at least one of the first and second transparent electrode layers and the barrier layer is formed to cover the entire face of the patterned colored layer. The covering makes it possible to prevent more effectively the outflow of gas generated from the colored layer.

It is necessary to pattern the first and second transparent electrode layers, but it is unnecessary to pattern the barrier layer. Therefore, when the barrier layer is formed over the substrate, at least the barrier layer can cover the entire of the colored layer.

In the above-mentioned case, it is sufficient that the first and second transparent electrode layers and the barrier layer are formed in such a manner that at least one thereof covers the entire face of the patterned colored layer; preferably, as shown in, e.g., FIG. 4, all of the barrier layer 6 and the first and second transparent electrode layers 3 and 4 are formed to cover the entire face of the patterned colored layer 2. This makes it possible to prevent even more effectively the outflow of gas generated from the colored layer.

When no overcoat layer is formed and the inorganic layer is a coated film in the embodiment, it is preferred that at least one of the first and second transparent electrode layers and the inorganic layer is formed to cover the entire face of the patterned colored layer. The covering makes it possible to prevent more effectively the outflow of gas generated from the colored layer.

In such a case, it is sufficient that the first and second transparent electrode layers and the inorganic layer are formed in such a manner that at least one thereof covers the entire face of the patterned colored layer; preferably, as shown in, e.g., FIG. 4, all of the inorganic layer 6 and the first and second transparent electrode layers 3 and 4 are formed to cover the entire face of the colored layer 2. This makes it possible to prevent even more effectively the outflow of gas generated from the colored layer.

When the overcoat layer is formed in the embodiment, the outflow of most of gas generated from the colored layer 2 and the overcoat layer 5 can be prevented when the first and second transparent electrode layers 3 and 4 are formed on/over the overcoat layer 5, as shown in, e.g., FIG. 2. However, the gas may flow out from the area of the overcoat layer 5 that is not covered with the first and second transparent electrode layers 3 and 4. Usually, the area where the colored layer is formed becomes an image display area. Accordingly, dark spots are not generated as long as gas flows out into the area where the colored layer is formed. Furthermore, the amount of gas from the colored layer is generally larger than that of gas from the overcoat layer. It is therefore preferred that the first and second transparent electrode layers are formed in at least the area where the colored layer is formed.

In order to prevent the outflow of gas generated from the colored layer and the overcoat layer, it is preferred that the overcoat layer is formed in a pattern form to cover at least the surface of the colored layer and further at least one of the first and second transparent electrode layers is formed to cover the entire face of the patterned overcoat layer, or cover the entire face of the patterned colored layer and overcoat layer, as described above. The covering makes it possible to prevent more effectively the outflow of gas generated from the colored layer and the overcoat layer.

It is sufficient that the first and second transparent electrode layers are formed in such a manner that at least one thereof covers the entire face of the patterned overcoat layer, or cover the entire face of the patterned colored layer and overcoat layer; preferably, as shown in, e.g., FIG. 7, both of the first and second transparent electrode layers 3 and 4 are formed to cover the entire face of the patterned overcoat layer 5. It is also preferred that, as shown in, e.g., FIG. 6, both of the first and second transparent electrode layers 3 and 4 are formed to cover the entire face of the patterned colored layer 2 and overcoat layer 5. This makes it possible to prevent even more effectively the outflow of gas generated from the colored layer and the overcoat layer.

The wording “being formed to cover the entire face of the overcoat layer” means that all of the surface and side faces of the overcoat layer are covered so that the overcoat layer is not exposed, and is, for example, a case in which the first and second transparent electrode layers 3 and 4 are formed not to make any face of the overcoat layer 5 exposed, as shown in FIG. 7. For example, when the overcoat layer 5 is formed to cover the surface and side faces of the colored layer 2, the colored layer 2 is not exposed; it is therefore sufficient that the first and second transparent electrode layers 3 and 4 are formed not to make the overcoat layer 5 exposed.

The wording “being formed to cover the entire face of the colored layer and the overcoat layer” means that all of the surface and side faces of the colored layer and the surface and side faces of the overcoat layer are covered so that the colored layer and the overcoat layer are not exposed, and is, for example, a case in which the first and second transparent electrode layers 3 and 4 are formed not to make any face of the colored layer 2 nor the overcoat layer 5 as shown in FIG. 6. For example, when the overcoat layer 5 is formed to cover only the surface of the colored layer 2, the side faces of the colored layer 2 are exposed; accordingly, the first and second transparent electrode layers 3 and 4 are formed not to make the colored layer 2 or the overcoat layer 5 exposed.

When an inorganic layer having barrier layer is formed between the overcoat layer and the first transparent electrode layer in the embodiment, it is preferred that the overcoat layer is formed in a pattern form to cover at least the surface of the colored layer and at least one of the first and second transparent electrode layers and the inorganic layer is formed to cover the entire face of the patterned overcoat layer, or cover the entire face of the patterned colored layer and overcoat layer. The covering makes it possible to prevent more effectively the outflow of gas generated from the colored layer and the overcoat layer.

It is sufficient that at least one of the first and second transparent electrode layers and the inorganic layer is formed to cover the entire face of the patterned overcoat layer, or cover the entire face of the patterned colored layer and overcoat layer; preferably, all of the first and second transparent electrode layers and the inorganic layer are formed to cover the entire face of the patterned overcoat layer. It is also preferred that, as shown in, e.g., FIG. 9, all of the inorganic layer 6, and the first and second transparent electrode layers 3 and 4 are formed to cover the entire face of the patterned colored layer 2 and overcoat layer 5. This makes it possible to prevent even more effectively the outflow of gas generated from the colored layer and the overcoat layer.

When the inorganic layer is a barrier layer, it is unnecessary to pattern the layer; therefore, when the barrier layer is formed over the entire face of the substrate, it is possible that the entire face of the overcoat layer or the entire face of the colored layer and the overcoat layer is covered with at least the barrier layer.

(7) Colored Layer

The following describes the colored layer used in the present embodiment. The colored layer is a layer formed in a pattern form on/over the substrate.

When the color filter substrate for an organic EL element of the embodiment is used to produce an organic EL display device, the colored layer used in the embodiment is a layer for changing the color tone of white light emitted from the light emitting layer of the organic EL display device, or a layer for adjusting further the color tone of light transmitting through the color converting layer which will be detailed later. In general, the colored layer is formed as a blue, red or green colored layer. When the color converting layer is formed, blue, red and green colored layers are formed at positions corresponding to respective colors of the color converting layer. The formation of such colored layers makes it possible that when the color filter substrate for an organic EL element of the embodiment is used in an organic EL display device, colors having high purities are developed so that color reproducibility is made high.

The material for forming each of the colored layers may be a pigment and a binder that can be ordinarily used in a color filter.

Specifically, examples of the pigment used in the red color layer include perylene pigments, lake pigments, azo pigments, quinacridone pigments, anthraquinone pigments, anthracene pigments, and isoindolinone pigments. These pigments may be used alone or in the form of a mixture of two or more thereof.

Examples of the pigment used in the green colored layer include halogen-multi-substituted phthalocyanine pigments, halogen-multi-substituted copper phthalocyanine pigments, triphenylmethane basic dyes, isoindoline pigments, and isoindolinone pigments. These pigments may be used alone or in the form of a mixture of two or more thereof.

Examples of the pigment used in the blue colored layer include copper phthalocyanine pigments, indanthrene pigments, indophenol pigments, cyanine pigments, and dioxazine pigments. These pigments may be used alone or in the form of a mixture of two or more thereof.

The pigment(s) is/are contained in the red, green or blue colored layer usually in an amount of 5 to 50% by weight of the layer.

The binder resin used in the colored layers is preferably a transparent resin having a visible ray transmittance of 50% or more. Examples thereof include polymethyl methacrylate, polyacrylate, polycarbonate, polyvinyl alcohol, polyvinyl pyrrolidone, hydroxyethylcellulose, and carboxymethylcellulose.

The method for forming the colored layers may be a method for forming an ordinary colored layer, for example, photolithography or mask vapor deposition.

(8) Light Shielding Parts

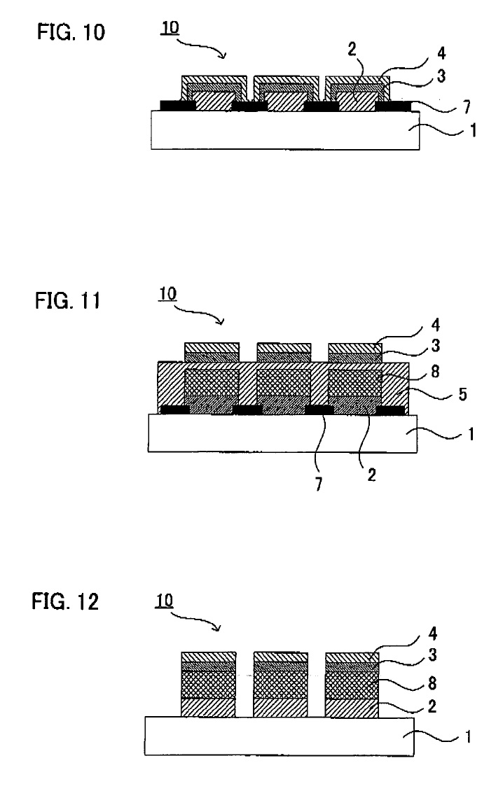

As shown in, e.g., FIGS. 10 and 11, in the present embodiment, light shielding parts 7 may be formed on the substrate 1 and between the colored layers 2. The formation of the light shielding parts, such as parts for a black matrix, can improve the contrast when the color filter substrate for an organic EL element of the embodiment is used to produce an organic EL display device.

The light shielding parts used in the embodiment may or may not be insulative. When the light shielding parts are insulative, the material for forming the light shielding parts may be, for example, a resin containing a black coloring agent. When the light shielding parts are not insulative, the material for forming the light shielding parts may be, for example, chromium. The light shielding parts may be made of a product in which two layers of a Croₓ (wherein X is any number) and a Cr film are laminated, or a product in which three layers of a CrOₓ (wherein X is any number), a CrN_{y} (wherein y is any number) and a Cr film are laminated to make the reflectivity smaller.

When at least one of the first and second transparent electrode layers is formed to cover the entire face of the patterned colored layer, or when at least one of the first and second transparent electrode layers and the inorganic layer is formed to cover the entire face of the patterned colored layer in the embodiment, it is preferred that the light shielding parts are insulative. When at least one of the first and second transparent electrode layers is formed to cover the entire face of the patterned overcoat layer or cover the entire face of the patterned overcoat layer and colored layer, or when at least one of the first and second transparent electrode layers and the inorganic layer is formed to cover the entire face of the patterned overcoat layer or cover the entire face of the patterned overcoat layer and colored layer, it is also preferred that the light shielding parts are insulative. In, e.g., FIG. 5C, the first and second transparent electrode layers 3 and 4 are formed to cover the entire face of the colored layer 2; accordingly, the first and second transparent electrode layers 3 and 4 contact the light shielding parts 7. In, e.g., FIG. 6, the first and second transparent electrode layers 3 and 4 are formed to cover the entire face of the colored layer 2 and the overcoat layer 5; accordingly, the first and second transparent electrode layers 3 and 4 contact the light shielding parts 7. When the light shielding parts 7 are conductive in such a case, conduction is attained between the light shielding parts 7 and the first and second transparent electrode layers 3 and 4; it is therefore feared that when signals are added to the first transparent electrode layer in an organic EL display device in which the color filter substrate for an organic EL element of the embodiment is used, adjacent ones out of the signals in the first transparent electrode layer cannot be independently operated.

The light shielding parts including a resin containing a black coloring agent can be formed by applying a resin composition containing the black coloring agent onto a substrate and then patterning the resultant layer by photolithography.

The light shielding parts including a metal such as chromium can be formed by forming a thin film made of a metal, metal oxide or metal nitride by sputtering, vacuum evaporation or the like, and then patterning the resultant layer by photolithography. The light shielding parts may be formed by electroless plating or printing.

The film thickness of the light shielding parts is from about 0.2 to 0.4 μm when the parts are formed by sputtering or vacuum evaporation. The thickness is from about 0.5 to 2 μm when the parts are formed by coating or printing.

When the light shielding parts are made from, for example, a resin containing a black coloring agent in the embodiment, gas may be generated from this resin. In such a case, therefore, an inorganic barrier layer may be formed on/over the light shielding parts. This inorganic barrier layer may be a film which is used as the inorganic barrier layer of an ordinary organic EL element, such as a silicon oxide film or a silicon nitride film.

The resin which is used in the light shielding parts and contains the black coloring agent may be any resin that has light shielding property. Accordingly, the light shielding parts may be subjected to sufficient thermal treatment, which is different from the case about the colored layer. It is therefore possible to remove gas components therefrom when the light shielding parts are formed. Thus, it appears that a possibility that gas is generated from the light shielding parts at the time of heating for producing the color filter substrate for an organic EL element is low.

When the light shielding parts are not insulative, an insulating layer nay be formed on the light shielding parts. This makes it possible to prevent conduction between the first or second transparent electrode layer and the light shielding parts.

(9) Color Converting Layer

As shown in, e.g., FIG. 12, in the embodiment, a color converting layer 8 may be formed on the colored layer 2 and between the colored layer 2 and the first transparent electrode layer 3. As shown in, e.g., FIG. 11, a color converting layer 8 may be formed on the colored layer 2 and between the colored layer 2 and the overcoat layer 5.

About the color converting layer in the same manner as about the above-mentioned colored layer, the dye or the like contained therein may decompose to generate gas, thereby causing dark spots. However, in the embodiment, the first and second transparent electrode layers are formed on/over the color converting layer; this matter gives barrier property against not only gas generated from the colored layer and the overcoat layer but also gas generated from the color converting layer.

Thus, when the color converting layer is formed, it is preferred that at least one of the first and second transparent electrode layers is formed to cover the entire of the color converting layer, which is formed in a pattern form, in the same manner as in the case of the colored layer. The covering makes it possible to prevent more effectively the outflow of gas generated from the color converting layer.

It is sufficient that the first and second transparent electrode layers are formed in such a manner that at least one thereof covers the entire face of the patterned color converting layer; preferably, both of the first and second transparent electrode layers are formed to cover the entire face of the color converting layer. This makes it possible to prevent even more effectively the outflow of gas generated from the colored layer.

When the inorganic layer is formed, it is preferred that at least one of the inorganic layer and the first and second transparent electrode layers is formed to cover the entire face of the patterned color converting layer. It is more preferred that all of the inorganic layer and the first and second transparent electrode layers are formed to cover the entire face of the patterned color converting layer.

When the color converting layer is formed and the above-mentioned overcoat layer is formed in the embodiment, it is preferred in order to prevent the outflow of gas generated from the colored layer, the color converting layer and the overcoat layer that the overcoat layer is formed in a pattern form to cover at least the surface of the color converting layer and at least one of the first and second transparent electrode layers is formed to cover the entire face of the patterned overcoat layer or the entire face of the patterned colored layer, color converting layer and overcoat layer in the same manner as in the case of the colored layer and the overcoat layer. This makes it possible to prevent more effectively the outflow of the gas generated from the colored layer, the color converting layer and the overcoat layer.

In order to prevent even more effectively the outflow of the gas generated from the colored layer, the color converting layer and the overcoat layer, it is preferred that both of the first and second transparent electrode layers are formed to cover the entire face of the patterned overcoat layer, or the entire face of the patterned colored layer, color converting layer and overcoat layer.

When the inorganic layer is formed, it is preferred in order to prevent the outflow of gas generated from the colored layer, the color converting layer and the overcoat layer that the overcoat layer is formed in a pattern form to cover at least the surface of the color converting layer and at least one of the inorganic layer and the first and second transparent electrode layers is formed to cover the entire face of the patterned overcoat layer or cover the entire face of the patterned colored layer, color converting layer and overcoat layer. It is more preferred that all of the inorganic layer and the first and second transparent electrode layers are formed to cover the entire face of the patterned overcoat layer or cover the entire face of the patterned colored layer, color converting layer and overcoat layer.

When the film thickness of the color converting layer is largely varied in the layer, it is preferred that the overcoat layer is formed over the entire face of the substrate on/over which the color converting layer is formed. This makes it possible to restrain the generation of dark areas.

The color converting layer used in the embodiment is not particularly limited if the following is satisfied: when the color filter substrate for an organic EL element of the embodiment is used to produce an organic EL display device, this layer is a layer which contains a fluorescent material absorbing light emitted from the light emitting layer of the organic EL element and emitting fluorescence in the wavelength range of visible rays, and which makes light from the light emitting layer blue, red or green. The color converting layer may be a layer which emits each of fluorescences in three colors of blue, red and green colors. When the light emitting layer which emits blue light is used, a transparent resin layer may be formed instead of the color converting layer for blue conversion.

The color converting layer is usually a layer which absorbs light from the light emitting layer and contains an organic fluorescent dye emitting fluorescence and a matrix resin.

The fluorescent dye used in the color converting layer is a dye which absorbs near ultraviolet rays or visible rays, in particular, blue or bluish green rays emitted from the light emitting layer so as to emit a visible ray having a different wavelength as fluorescence. Usually, a blue light emitting layer is used as the light emitting layer; it is therefore preferred to use one or more fluorescent dyes which emit at least red fluorescence. It is preferred to combine it with one or more fluorescent dyes which emit green fluorescence.

In other words, when the light emitting layer emitting blue light or bluish green light is used as a light source, very dark light is emitted if red light is desired to be obtained by passing the light from the light emitting layer merely through a red colored layer. This is because the amount of light rays having red-range wavelengths is originally small. Accordingly, when blue or bluish green light from the light emitting layer is converted to red light by the fluorescent dye, the red light can be emitted with a sufficient intensity.

Green light may be obtained by converting light from the light emitting layer by use of a different fluorescent dye, and emitted in the same manner as about the red light. Alternatively, it is allowable to emit light from the light emitting layer merely through a green colored layer when light emitted from the light emitting layer sufficiently contains green light rays. Blue light may be obtained by converting light from the light emitting layer by use of a fluorescent dye, and emitted. Preferably, the light from the light emitting layer is emitted merely through a blue colored layer.

Examples of the fluorescent dye which absorbs light of from blue-range wavelengths to bluish green-range wavelengths emitted from the light emitting layer and emits red fluorescence include rhodamine coloring agents such as rhodamine B, rhodamine 6G, rhodamine 3B, rhodamine 101, rhodamine 110, sulforhodamine, basic violet 11, and basic red 2; cyanine coloring dyes; pyridine coloring dye s such as 1-ethyl-2-[4-(p-dimethylaminophenyl)-1,3-budadienyl]-pyridinium perchlorate (pyridine 1); and oxazine coloring dye s. Various dyes (such as direct dyes, acidic dyes, basic dyes, and disperse dyes) that have fluorescent property can be used.

Examples of the fluorescent dye which absorbs light of from blue-range wavelengths to bluish green-range wavelengths emitted from the light emitting layer and emits green fluorescence include coumalin coloring dyes such as 3-(2′-benzothiazolyl)-7-diethylaminocoumalin (coumalin 6), 3-(2′-benzoimidazolyl)-7-N,N-diethylaminocoumalin (coumalin 7), 3-(2′-N-methylbenzoimidazolyl)-7-N,N-diethylaminocoumalin (coumalin 30), 2,3,5,6-1H,4H-tetrahydro-8-trifluoromethyl quinolizine (9,9a,1-gh) coumalin (coumalin 153); basic yellow 51, which is a coumalin dye; and naphthalimide coloring dye s such as solvent yellow 11 and solvent yellow 116. Various dyes (such as direct dyes, acidic dyes, basic dyes, and disperse dyes) that have fluorescent property can be used.

A fluorescent pigment may be used which is obtained by kneading any fluorescent dye into polymethacrylate ester, polyvinyl chloride, vinyl chloride-vinyl acetate copolymer resin, alkyd resin, aromatic sulfonamide resin, urea resin, melamine resin or benzoguanamine resin, or a mixture thereof in advance. These fluorescent dyes and fluorescent pigments, which will be generically named “fluorescent dyes” hereinafter, may be used alone, or used in combination of two or more thereof in order to adjust the color tone of fluorescence.

The fluorescent dye(s) is/are contained in the color converting layer in an amount of 0.01 to 5% by weight, preferably 0.1 to 2% by weight of the color converting layer. If the content of the fluorescent dye is too small, sufficient wavelength-conversion cannot be attained. If the content of the fluorescent dye is too large, the efficiency of color conversion may be lowered by effects such as concentration quenching.

The matrix resin used in the color converting layer may be an insoluble or non-melted resin obtained by subjecting a photosetting resin or photo and thermal setting resin (resist) to photo and/or thermal treatment to generate radical species or ionic species and thus polymerizing or crosslinking the curable resin. In order to pattern the color converting layer, it is desired that the photosetting resin or photo and thermal setting resin is soluble in an organic solvent or alkaline solution in the state that the resin is not exposed to light.

Examples of such an photosetting resin or photo and thermal setting resin include (1) a composition consisting of an acrylic polyfunctional monomer or oligomer containing plural acryloyl or methacryloyl groups, and an photo or thermal polymerization initiator, (2) a composition consisting of a polyvinyl cinnamate ester and a sensitizer, (3) a composition consisting of a linear or cyclic olefin and bisazide, and (4) a composition consisting of a monomer having an epoxy group and an acid generator. Particularly preferred is the composition (1), which consists of the acrylic polyfunctional monomer or oligomer and an photo or thermal polymerization initiator since the composition can be highly precisely patterned and is high in resistances such as solvent resistance and heat resistance. As described above, the matrix resin is formed by causing light and/or heat to act onto the photosetting resin or photo and thermal setting resin.

It is preferred that the photo polymerization initiator, the sensitizer and the acid generator which can be used in the color converting layer are each a product for initiating polymerization based on light having a wavelength which the fluorescent dye contained therein does not absorb. When the resin itself in the photosetting resin or photo and thermal setting resin can be polymerized by light or heat in the color converting layer, it is allowable that neither optical polymerization initiator nor thermal polymerization initiator is added thereto.

The method for forming the color converting layer may be a method used in an ordinary method for forming a color filter, for example, photolithography or vapor deposition.

(10) Substrate

The following describes the substrate used in the present embodiment. The substrate is preferably transparent for the following reason: when the color filter substrate for an organic EL element of the embodiment is used to produce an organic EL display device, light is taken out from the substrate side thereof. Preferably, the substrate has solvent resistance, heat resistance and excellent dimensional stability. According to this, the substrate is stable also when the colored layer, the first and second transparent electrode layers, and so on are formed on/over the substrate.

The transparent substrate may be, for example, a glass plate, or a film or sheet made of an organic material.

When a glass plate is used as the transparent substrate in the embodiment, the glass plate is not particularly limited it the plate is a glass plate having a high transmissivity to visible rays. Thus, the glass plate may be, for example, an unprocessed glass plate or a processed glass plate. This glass plate may be made of either alkali glass or non-alkali glass. When impurities become a problem in the embodiment, it is preferred to use a non-alkali glass such as Pyrex (registered trademark) glass. The kind of the processed glass plate is appropriately selected in accordance with the usage of the color filter substrate for an organic EL element of the embodiment. The processed glass plate may be, for example, a transparent glass plate subjected to coating processing or stepping processing.

The thickness of the glass plate is preferably from 20 μm to 2 mm. In particular, when the glass plate is used as a flexible substrate, the thickness is preferably from 20 μm to 200 μm. When it is used as a rigid substrate, the thickness is preferably from 200 μm to 2 mm.

Examples of the organic material used for the transparent substrate include polyarylate resin, polycarbonate resin, crystallized polyethylene terephthalate resin, polyethylene terephthalate resin, polyethylene naphthalate resin, UV curable methacrylic resin, polyethersulfone resin, polyetheretherketone resins polyetherimide resin, polyphenylenesulfide resin, and polyimide resin.

For the transparent substrate, it is allowable to use one or more selected from the above-mentioned organic materials together with one or more selected from, for example, cyclic polyolefin based resins, polystyrene based resins, acrylonitrile-styrene copolymer (AS resin), acrylonitrile-butadiene-styrene resin (ABS resin), poly(meth)acrylic resins, polycarbonate based resins, polyester based resins such as polyethylene terephthalate and polyethylene naphthalate, polyamide based resins such as various nylons, polyurethane based resins, fluorine-contained resins, acetal based resins, cellulose based resins, and polyetheresulfone based resins.

When the above-mentioned organic material (s) is/are used to produce a transparent substrate, the thickness of the substrate is preferably from 10 to 500 μm, more preferably from 50 to 400 μm, and even more preferably from 100 to 300 μm. If the thickness of the substrate is too thick, the impact resistance is poor or the substrate is not easily wounded upon winding so that the barrier property may deteriorate. If the thickness of the substrate is too thin, the machine fitness is poor so that the barrier property may deteriorate.

In the embodiment, it is preferred to use the substrate after the plate is washed. Preferred examples of the method for the washing include ultraviolet ray radiating treatment using oxygen or ozone, plasma treatment, and argon sputtering treatment. This makes it possible to make the substrate into a state that water content or oxygen is not adsorbed thereon, decrease dark spots, and make the lifespan of the organic EL element long.

(11) Process for Producing the Color Filter Substrate for an Organic EL Element

The following describes an example of the process for producing the color filter substrate for an organic EL element of the present embodiment.

First, a composite film made of chromium oxide and nitride is formed on a substrate by, for example, sputtering. Photolithography is then used to pattern the film, thereby forming a black matrix. For example, spin coating is used to apply a photosensitive coating for colored layer onto the substrate on which the black matrix is formed, and photolithography is used to pattern the resultant layer, thereby forming a colored layer. Next, an ITO film is formed on the colored layer by, for example, sputtering. A conductive layer forming dispersion liquid which contains fine particles made of indium alloy containing Sn is applied onto this ITO film by spin coating, and then the resultant is fired to form a conductive film. Furthermore, photolithography is used to pattern the ITO film and the conductive film simultaneously, thereby forming a first transparent electrode layer and a second transparent electrode layer. In this way, a color filter substrate for an organic EL element according to the embodiment can be produced.

It is allowable that, before the formation of the ITO film, an overcoat layer forming coating solution is applied onto the colored layer, thereby forming an overcoat layer to cover the entire of the colored layer.

### 2. Second Embodiment

The following describes the second embodiment of the color filter substrate for an organic EL element of the present embodiment.

The second embodiment is a color filter substrate for an organic EL element having a substrate, a colored layer formed in a pattern form on/over the substrate, a conductive layer formed in a pattern form on/over the colored layer, and a transparent electrode layer formed on/over the conductive layer, wherein the conductive layer is a coated film and has conductivity.

Referring to the drawings, the color filter substrate for an organic EL element of the present embodiment is described hereinafter.

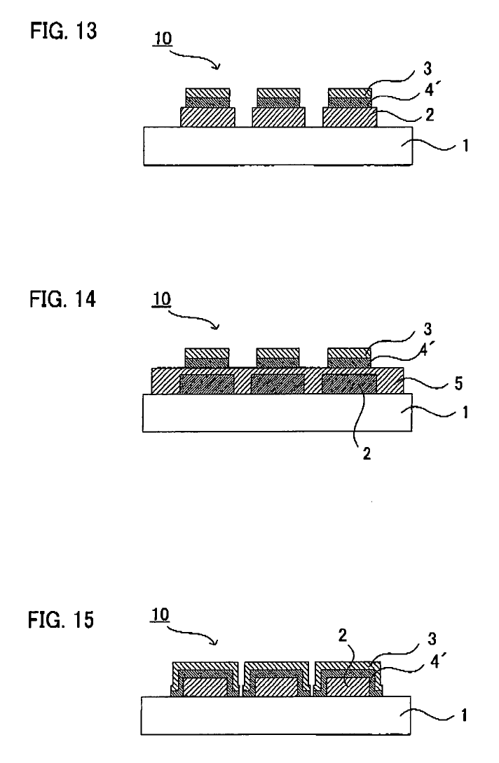

FIG. 13 is a schematic sectional view showing an example of the color filter substrate for an organic EL element of the embodiment. As shown in FIG. 13, a color filter substrate 10 for organic EL element according to this example is a color filter substrate in which a colored layer 2, a conductive layer 4′ and a transparent electrode layer 3 are successively formed in a pattern form on a substrate 1.

FIG. 14 is a schematic sectional view showing another example of the color filter substrate for an organic EL element of the embodiment. As shown in FIG. 14, in the embodiment, an overcoat layer 5 may be formed between the colored layer 2 and the conductive layer 4′. The color filter substrate 10 for organic EL element shown in FIG. 14 is a color filter substrate in which the colored layer 2 is formed in a pattern form on the substrate 1, the overcoat layer 5 is formed to cover the colored layer 2, and the conductive layer 4′ and the transparent electrode layer 3 are successively formed into a pattern form on the overcoat layer 5.

According to the embodiment, the formation of the conductive layer makes it possible to improve adhesive force between the transparent electrode layer and the colored layer and substrate or the overcoat layer; it is therefore possible to restrain the generation of peeling or cracking in the interface between the substrate on which the colored layer is formed and the transparent electrode layer or the interface between the overcoat layer and the transparent electrode layer.

The wording “the transparent electrode layer formed on/over the conductive layer” means the case that the transparent electrode layer is formed only on/over the conductive layer. As described above, the conductive layer causes an improvement in the adhesive property between the colored layer and the transparent electrode layer or overcoat layer. Accordingly, the conductive layer is indispensably formed beneath/below the transparent electrode layer.

Since the conductive layer is a coated film in the embodiment, irregularities or foreign substances on the colored layer are cancelled by applying a conductive layer forming coating solution onto the colored layer when the conductive layer is formed. Consequently, the surface of the colored layer can be made smooth. If irregularities are present in the colored layer, the shape of the irregularities is reflected also onto the transparent electrode layer formed on/over the colored layer. Thus, when the embodiment is used in an organic EL display device, defects based on damage by electrostatic discharge or the like are easily generated in its thin organic EL layer. Such defects become fault spots (dark areas) to deteriorate the quality of display. As described above, in the embodiment, the colored layer surface can be made smooth by the conductive layer; therefore, when the color filter substrate for an organic EL element of the embodiment is used in an organic EL display device, the generation of dark areas can be restrained.

Since the transparent electrode layer is formed on the conductive layer having good smoothness, the transparent electrode layer can be made dense. For the transparent electrode layer, indium tin oxide (ITO), indium zinc oxide (IZO) or the like is generally used, and such a transparent electrode layer has a measure of barrier property against water vapor, oxygen, and gas generated from the colored layer, the overcoat layer and so on. Thus, the lamination of the conductive layer and the transparent electrode layer makes it possible to yield barrier property against water vapor, oxygen, and the gas generated from the colored layer, overcoat layer and so on.

When the color filter substrate for an organic EL element of the embodiment is used to produce an organic EL display device, the area where the colored layer is formed becomes an image display area, and in the embodiment the conductive layer and the transparent electrode layer are formed on/over the colored layer. It is therefore possible to prevent the invasion of water vapor or oxygen into the image display area and restrain the discharge of gas from the colored layer and so on so that the generation of dark spots can be restrained. Furthermore, it is unnecessary to form a thick barrier layer by sputtering, CVD or the like as in the prior art. Thus, the embodiment has an advantage that costs can be reduced.

Moreover, the conductive layer in the embodiment has conductivity; accordingly, the conductive layer can be integrated with the transparent electrode layer to cause the resultant to function as an electrode so that the electric resistance can be made small.

The following describes each of the constituent members of the above-mentioned color filter substrate for an organic EL element. The colored layer, the overcoat layer and the substrate are the same as described in the first embodiment. Properties of the conductive layer (the adhesive property improving layer), the transparent electrode layer and the secondary transparent electrode layer are identical to those of the transparent electrode layer (the first transparent electrode layer), the conductive layer (the second transparent electrode layer) and the inorganic layer in the first embodiment. Thus, description thereof is not repeated herein.

(1) Conductive Layer (Adhesive Property Improving Layer)

The conductive layer used in the embodiment is an adhesive property improving layer for improving adhesive force between the transparent electrode layer and the colored layer and substrate.

The adhesive property improving layer used in the embodiment is a coated film which is formed in a pattern form on/over the colored layer by a wet process and which has conductivity.

In the embodiment, the adhesive property improving layer preferably has barrier property. The barrier property of the adhesive property improving layer is sufficient if the lamination of the adhesive property improving layer and the transparent electrode layer which will be detailed later makes it possible to prevent the invasion of water vapor and oxygen and the outflow of gas generated from the colored layer, the overcoat layer and so on.

This adhesive property improving layer is not particularly limited if the layer is a layer formed in a pattern form on/over the colored layer. As shown in, e.g., FIG. 13, the adhesive property improving layer 4′ may be formed in a pattern form to cover the surface of the patterned colored layer 2. As shown in, e.g., FIG. 15, the adhesive property improving layer 4′ may be formed in a pattern form to cover the entire face of the patterned colored layer 2. In the embodiment, it is particularly preferred that, as shown in FIG. 13, the adhesive property improving layer 4′ is formed to leave an area of a predetermined width from the edge of the patterned colored layer 2.

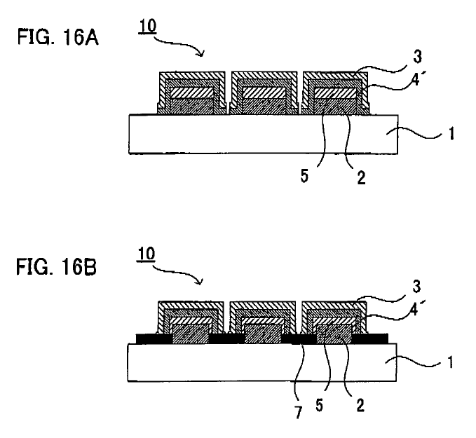

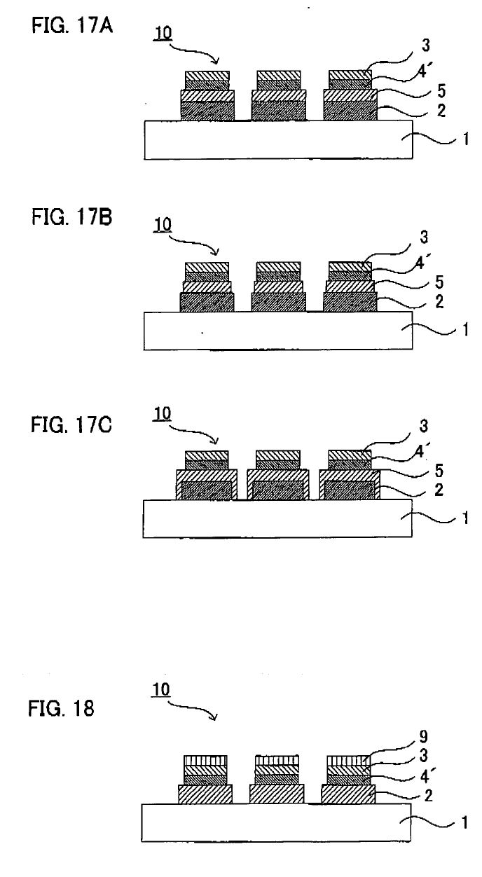

When the overcoat layer which will be detailed later is formed in the embodiment, the adhesive property improving layer is not particularly limited if the layer is a layer formed in a pattern form on/over the overcoat layer. As shown in, e.g., FIG. 14, it is allowable that the overcoat layer 5 is formed over the entire face of the substrate 1 on which the colored layer 2 is formed and the adhesive property improving layer 4′ is formed in a pattern form on the overcoat layer 5 and over the surface of the patterned colored layer 2. As shown in, e.g., FIG. 16A, it is allowable that the overcoat layer 5 is formed in a pattern form and the adhesive property improving layer 4′ is formed in a pattern form to cover the entire face of the patterned colored layer 2 and overcoat layer 5. As shown in, e.g., FIG. 16B, it is allowable that the overcoat layer 5 is formed in a pattern form and the adhesive property improving layer 4′ is formed in a pattern form to cover the entire face of the patterned overcoat layer 5. As shown in, e.g., each of FIGS. 17A to 17C, it is allowable that the overcoat layer 5 is formed in a pattern form and the adhesive property improving layer 4′ is formed in a pattern form on the overcoat layer 5 and over the surface of the patterned colored layer 2.

In the embodiment, it is preferred that the adhesive property improving layer 4′ is formed to leave an area of a predetermined width from the edge of the patterned colored layer 2 whether the overcoat layer 5 is formed over the entire face of the substrate 1 on which the colored layer 2 is formed as shown in, e.g., FIG. 14 or the overcoat layer 5 is formed in a pattern form on the colored layer 2 as shown in, e.g., FIGS. 17A to 17C.

When the color filter substrate for an organic EL element of the embodiment is used to produce an organic EL display device, the edge area of the colored layer becomes a non-display area since an insulating layer is usually formed thereon. Degas components in the colored layer originally pass through weak portions of the transparent electrode layer if loopholes are not present therein. As a result, the components damage the organic EL layer so that dark spots are generated. On the other hand, in the embodiment, the adhesive property improving layer and the transparent electrode layer are not formed in the edge area of the colored layer and thus the non-display area is rendered an area having a low barrier property. In this way, degas components are selectively discharged from this non-display area. It is therefore possible to restrain the degas components from passing through the weak portion of the transparent electrode layer and restrain the generation of dark spots.

The above-mentioned predetermined width is appropriately selected, considering the numerical aperture of the image display area, patterning precision, and other factors, and is specifically set into the range of about 1 to 30 μm. When the pattern of the colored layer and the adhesive property improving layer is in a band form, the width of the adhesive property improving layer is preferably from 40 to 98 when the width of the colored layer is regarded as 100.

As shown in, e.g., FIG. 15, when the adhesive property improving layer 4′ is formed in a pattern form to cover the entire face of the patterned colored layer 2, the outflow of gas generated from the colored layer and the invasion of water vapor and oxygen can be prevented since barrier property can be obtained by the adhesive property improving layer 4′ and the transparent electrode layer 3. As shown in, e.g., FIG. 16A, when the adhesive property improving layer 4′ is formed in a pattern form to cover the entire face of the patterned colored layer 2 and overcoat layer 5, or as shown in, e.g., FIG. 168, when the adhesive property improving layer 4′ is formed in a pattern form to cover the entire face of the patterned overcoat layer 5, the outflow of gas generated from she colored layer and the overcoat layer and the invasion of water vapor and oxygen can be prevented since barrier property can be obtained by the adhesive property improving layer 4′ and the transparent electrode layer 3. This makes it possible that when the color filter substrate for an organic EL element of the embodiment is used in an organic EL display device, the generation of dark spots is restrained in the same manner as described above.

The wording “being formed to cover the entire face of the colored layer” means that all of the surface and side faces of the colored layer are covered so that the colored layer is not exposed, and is, for example, a case in which the adhesive property improving layer 4′ is formed not to make any face of the colored layer 2 exposed, as shown in FIG. 15.

The wording “being formed to cover the entire face of the colored layer and the overcoat layer” means that all of the surface and side faces of the colored layer and the surface and side faces of the overcoat layer are covered so that the colored layer and the overcoat layer are not exposed, and is, for example, a case in which the adhesive property improving layer 4′ is formed not to make any face of the colored layer 2 and the overcoat layer 5 exposed, as shown in FIG. 16A. For example, when the overcoat layer 5 is formed to cover only the surface of the colored layer 2, the side faces of the colored layer 2 are exposed; accordingly, the adhesive property improving layer 4′ is formed not to make the colored layer 2 nor the overcoat layer 5 exposed.

The wording “being formed to cover the entire of the overcoat layer” means that all of the surface and side faces of the overoat layer are covered so that the overcoat layer is not exposed, and is, for example, a case in which the adhesive property improving layer 4′ is formed not to make any face of the overcoat layer 5 exposed, as shown in FIG. 168. For example, when the overcoat layer 5 is formed to cover the surface and side faces of the colored layer 2, the colored layer 2 is not exposed; accordingly, the adhesive property improving layer 4′ is formed not to make the overcoat layer 5 exposed.

When the color filter substrate for an organic EL element of the embodiment is used in an organic EL display device, light is taken out from the substrate side thereof; it is therefore preferred that the adhesive property improving layer has light transmissivity. About the light transmissivity of the adhesive property improving layer, the light transmittance is preferably 60% or more, more preferably 80% or more, and even more preferably 90% or more in the wavelength range of visible rays.

The method for measuring the light transmittance is equivalent to that described in the item of the conductive layer (the second transparent electrode layer) in the first embodiment.

As the conductivity of such adhesive property improving layer, it is sufficient that the two layers of the adhesive property improving layer and transparent electrode layer are integrated with each other to function as an electrode. It is therefore unnecessary to have a sheet resistance value making it possible that this layer functions as an electrode by itself. Specifically, the sheet resistance value of the adhesive property improving layer is usually from about 50 to 10000 Ω/□, preferably from 100 to 1000 Ω/□.

The method for measuring the sheet resistance value is equivalent to that described in the item of the conductive layer (the second transparent electrode layer) in the first embodiment.

The adhesive property improving layer used in the present embodiment is a coated film. The “coated film” means a film formed by any wet process, and is, for example, a film formed by coating a coating solution.

The matter that the adhesive property improving layer is a coated film can be confirmed from a scanning electron microscope (SEM) photograph thereof (magnifications: 50000 or more). At this time, if it is confirmed that irregularities in the colored layer surface are made smooth by the adhesive property improving layer, it can be said that this layer is a coated film.

The adhesive property improving layer used in the embodiment preferably contains fine particles having an average particle size of 50 nm or less. The fine particles are the same described in the item of the conductive layer (the second transparent electrode layer) in the first embodiment. Thus, description thereof is not repeated herein.

The forming material, the film thickness, the forming method and other matters of the adhesive property improving layer are equivalent to those of the conductive layer (the second transparent electrode layer) in the first embodiment. Thus, description thereof is not repeated herein.

(2) Transparent Electrode Layer

The following describes the transparent electrode layer used in the present embodiment. The transparent electrode layer is a layer formed on/over the adhesive property improving layer.

As described above, when the color filter substrate for an organic EL element of the embodiment is used in an organic EL display device, an organic EL layer is formed on/over the transparent electrode layer; it is therefore preferred that the surface of the transparent electrode layer is flat or smooth in order to restrain the generation of dark areas. Specifically, the average surface roughness (Ra) of the transparent electrode layer is preferably from 10 to 500 Å, more preferably from 10 to 100 Å. When the average surface roughness (Ra) of the transparent electrode layer is in the range, the generation of dark areas can be restrained when the color filter substrate for an organic EL element of the embodiment is used in an organic EL display device. As a result, good images can be displayed.

The method for measuring the average surface roughness (Ra) of the transparent electrode layer is equivalent to that described in the item of the conductive layer (the second transparent electrode layer) in the first embodiment.

Since the adhesive property between the colored layer and the transparent electrode layer is improved by the adhesive property improving layer in the embodiment, the adhesive property improving layer is indispensably formed between the colored layer and the transparent electrode layer. Thus, as shown in, e.g., FIG. 13, when the adhesive property improving layer 4′ is formed in a pattern form to cover the surface of the patterned colored layer 2, the transparent electrode layer 3 is formed over the surface of the colored layer 2 in the same manner as the adhesive property improving layer 4′.

Since the adhesive property between the overcoat layer and the transparent electrode layer is improved by the adhesive property improving layer in the embodiment, the adhesive property improving layer is indispensably formed between the overcoat layer and the transparent electrode layer. Thus, as shown in, e.g., FIG. 14 or FIGS. 17A to 17C, when the adhesive property improving layer 4′ is formed in a pattern form over the surface of the patterned colored layer 2, the transparent electrode layer 3 is formed over the surface of the colored layer 2 in the same manner as the adhesive property improving layer 4′.

On the other hand, as shown in, e.g., FIG. 15, when the adhesive property improving layer 4′ is formed in a pattern form to cover the entire face of the patterned colored layer 2, the transparent electrode layer 3 may be formed to cover the entire face of the colored layer 2 in the same manner as the adhesive property improving layer 4′. The transparent electrode layer 3 may be formed over the surface of the colored layer, which is not shown.

As shown in, e.g., FIG. 16A, when the adhesive property improving layer 4′ is formed in a pattern form to cover the entire face of the patterned colored layer 2 and overcoat layer 5, or as shown in, e.g., FIG. 16B, when the adhesive property improving layer 4′ is formed in a pattern form to cover the entire face of the patterned overcoat layer 5, the transparent electrode layer 3 may be formed to cover the entire face of the colored layer 2 and the overcoat layer 5, or cover the entire face of the overcoat layer 5 in the same manner as the adhesive property improving layer 4′. The transparent electrode layer 3 may be formed over the surface of the colored layer, which is not shown.

In the embodiment, it is particularly preferred that the adhesive property improving layer and the transparent electrode layer are formed to leave an area of a predetermined width from the edge of the patterned colored layer. As described above, such a structure makes it possible to discharge degas components selectively from the edge area of the colored layer, which is a non-display area, so as to prevent the discharge of the degas components into the image display area. Thus, the generation of dark spots can be restrained.

The forming material, the film thickness, the sheet resistance value, the forming method and other matters of the transparent electrode layer are equivalent to those of the transparent electrode layer (the first transparent electrode layer) in the first embodiment. Thus, description thereof is not repeated herein.

(3) Secondary Transparent Electrode Layer

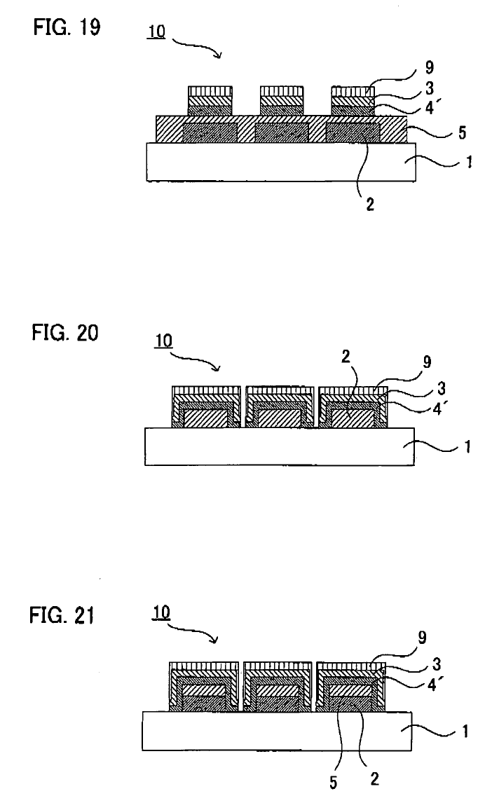

As shown in, e.g., FIGS. 18 and 19, in the embodiment, a secondary transparent electrode layer 9 may be formed on the transparent electrode layer 3. The secondary transparent electrode layer used in the embodiment can be classified into two aspects. One of the aspects is a aspect in which the secondary transparent electrode layer is a coated film having barrier property (fifth aspect), and the other is a aspect in which pinholes present in the above-mentioned transparent electrode layer are blocked with the secondary transparent electrode layer (sixth aspect).

Each of the aspects is described hereinafter.

(i) Fifth Aspect

The secondary transparent electrode layer in the present aspect is a coated film which has barrier property and is formed by a wet process. In the aspect, the formation of the secondary transparent electrode layer on/over the transparent electrode layer makes it possible to heighten still further the barrier property against gas generated from the colored layer and so on, water vapor and oxygen for the following reason: the secondary transparent electrode layer is a coated film; therefore, even if production defects, microscopic structural defects and other defects are present in the transparent electrode layer, the defects can be repaired by coating a coating solution for forming the secondary transparent electrode layer on/over the transparent electrode layer. In other words, in the step of coating the secondary transparent electrode layer forming coating solution and then drying the coating solution, the coating solution infiltrates into pinholes present in the transparent electrode layer, so that the pinholes can be blocked.

It is sufficient that the barrier property of the secondary transparent electrode layer in the embodiment makes it possible to block defects, such as pinholes, in the transparent electrode layer.

Further, as the conductivity of the secondary transparent electrode layer, it is sufficient that the two layers of the secondary transparent electrode layer and the transparent electrode layer are integrated with each other to function as an electrode. It is therefore unnecessary to have a sheet resistance value making it possible that this layer functions as an electrode by itself. Specifically, the sheet resistance value of the secondary transparent electrode layer is usually from about 50 to 10000 Ω/□, preferably from 100 to 1000 Ω/□.

The method for measuring the sheet resistance value is equivalent to that described in the item of the conductive layer (the second transparent electrode layer) in the first embodiment.

When the color filter substrate for an organic EL element of the present embodiment is used in an organic EL display device, light is taken out from the substrate side thereof. It is therefore preferred that the secondary transparent electrode layer has light transmissivity. About the light transmissivity of the secondary transparent electrode layer, the light transmittance is preferably 60% or more, more preferably 80% or more, and even more preferably 90% or more in the wavelength range of visible rays.

The method for measuring the light transmittance is equivalent to that described in the item of the conductive layer (the second transparent electrode layer) in the first embodiment.

Furthermore, when the color filter substrate for an organic EL element of the embodiment is used in an organic EL display device, an organic EL layer is formed on/over the secondary transparent electrode layer; it is therefore preferred that the surface of the secondary transparent electrode layer is flat or smooth in order to restrain the generation of dark areas. Specifically, it is preferable that the secondary transparent electrode layer has the average surface roughness (Ra) described in the column of the transparent electrode layer.

The forming material, the film thickness, the forming method and other matters of the secondary transparent electrode layer are equivalent to those of the conductive layer (the second transparent electrode layer) in the first embodiment. Thus, description thereof is not repeated herein.

The material used in the secondary transparent electrode layer and that used in the transparent electrode layer may be the same or different, but are preferably the same. If these materials are the same, it is possible to form the two layers of the transparent electrode layer and secondary transparent electrode layer over the entire face of a substrate on/over which a colored layer is formed and subsequently use, for example, a single etching solution to pattern the two layers simultaneously. If these materials used in the adhesive property improving layer, transparent electrode layer and the secondary transparent electrode layer are the same, it is possible to use a single etching solution to pattern the three layers simultaneously. This makes it possible to make the production process simple.

Even if the materials used in the secondary transparent electrode layer and transparent electrode layer are different, the two layers can be etched with a single etching solution according to circumstances when the film thickness of the secondary transparent electrode layer is relatively thin. This situation is varied in accordance with the used materials; for example, when an ITO film of 150 nm thickness is formed as the transparent electrode layer and an Ag film of 5 nm thickness is formed as the secondary transparent electrode layer, the two of the ITO film and the Ag film can be simultaneously patterned with an etching solution for the ITO film.

In the present embodiment, the secondary transparent electrode layer preferably contains fine particles having an average particle size of 50 nm or less. The fine particles are equivalent to those described in the item of the conductive layer (the second transparent electrode layer) in the first embodiment. Thus, description thereof is not repeated herein.

The secondary transparent electrode layer used in the present aspect is a coated film. The “coated film” means a film formed by any wet process, and is, for example, a film formed by coating a coating solution.

By the method described in the item of the conductive layer (the second transparent electrode layer) in the first embodiment, it can be confirmed that the secondary transparent electrode layer is a coated film.

The position where the secondary transparent electrode layer in the embodiment is formed is the same as in the case of the above-mentioned transparent electrode layer. As shown in, e.g., FIGS. 18 and 19, when the adhesive property improving layer 4′ is formed in a pattern form to cover the surface of the patterned colored layer 2, the secondary transparent electrode layer 9 is formed over the surface of the colored layer 2 in the same manner as the adhesive property improving layer 4′.

On the other hand, as shown in, e.g., FIG. 20, when the adhesive property improving layer 4′ is formed in a pattern form to cover the entire face of the patterned colored layer 2, the secondary transparent electrode layer 9 may be formed to cover the entire of the colored layer 2 in the same manner as the adhesive property improving layer 4′. The secondary transparent electrode layer may be formed over the surface of the colored layer, which is not shown. As shown in, e.g., FIG. 21, when the adhesive property improving layer 4′ is formed in a pattern form to cover the entire face of the patterned colored layer 2 and overcoat layer 5, or when the adhesive property improving layer is formed in a pattern form to cover the entire face of the patterned overcoat layer, the latter case being not shown, the secondary transparent electrode layer 9 may be formed to cover the entire face of the colored layer 2 and the overcoat layer 5 or the entire face of the overcoat layer in the same manner as the adhesive property improving layer 4′. The secondary transparent electrode layer may be formed over the surface of the colored layer, which is not shown.

In the embodiment, it is particularly preferred that the adhesive property improving layer, the transparent electrode layer and the secondary transparent electrode layer are formed to leave an area of a predetermined width from the edge of the patterned colored layer. As described above, such a structure makes it possible to discharge degas components selectively from the edge area of the colored layer, which is a non-display area, so as to prevent the degas components from passing through the transparent electrode layer, which is an image display area. Thus, the generation of dark spots can be restrained.

(ii) Sixth Aspect

The secondary transparent electrode layer in the present aspect is a layer for blocking pinholes present in the above-mentioned transparent electrode layer. Since the pinholes present in the transparent electrode layer are blocked with the secondary transparent electrode layer in the aspect, it is possible to improve the barrier property against gas generated from the colored layer, the color converting layer and so on, water vapor and oxygen.

The matter that the pinholes present in the transparent electrode layer are blocked with the secondary transparent electrode layer can be confirmed by the method described in the item of the conductive layer (the second transparent electrode layer) in the second aspect.

Other matters of the secondary transparent electrode layer are equivalent to those described about the fifth aspect. Thus, description thereof is not repeated herein.

(4) Light Shielding Parts

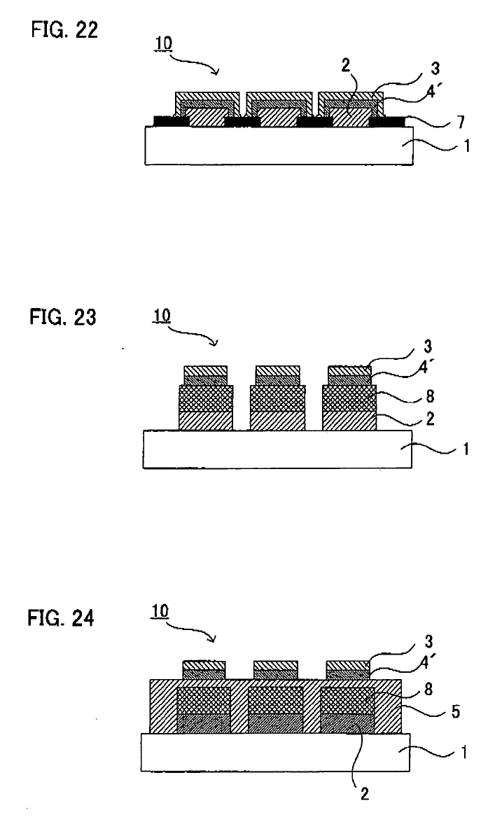

As shown in, e.g., FIG. 22 and FIG. 168, in the present embodiment, light shielding parts 7 may be formed on the substrate 1 and the colored layers 2.

The light shielding parts used in the embodiment may be insulative, or not insulative.

In the embodiment, it is preferred that the light shielding parts are insulative when the adhesive property improving layer is formed in a pattern form to cover the entire face of the patterned colored layer, when the adhesive property improving layer is formed to cover the entire face of the patterned overcoat layer, or when the adhesive property improving layer is formed to cover the entire face of the patterned overcoat layer and colored layer. In, e.g., FIG. 22, the adhesive property improving layer 4′ and the transparent electrode layer 3 are formed to cover the entire face of the colored layer 2; accordingly, the adhesive property improving layer 4′ and the transparent electrode layer 3 contact the light shielding parts 7. In, e.g., FIG. 16B, the adhesive property improving layer 4′ and the transparent electrode layer 3 are formed to cover the entire face of the overcoat layer 5; accordingly, the adhesive property improving layer 4′ and the transparent electrode layer 3 contact the light shielding parts 7. If in such a case the light shielding parts are not insulative, that is conductive, electric conduction is unfavorably permitted between the light shielding parts and the adhesive property improving layer and transparent electrode layer; accordingly, in an organic EL display device using the color filter substrate for an organic EL element of the embodiment, it is feared that when signals are given to the transparent electrode layer, adjacent ones out of the signals in the transparent electrode layer cannot be independently operated.

When the adhesive property improving layer is formed to leave an area of a predetermined width from the edge of the patterned colored layer and when the overcoat layer is formed over the entire face of the substrate on/over the colored layer is formed, the light shielding parts may not be insulative, that is be conductive for the following reasons: in such a case, the light shielding parts do not contact the adhesive property improving layer or the transparent electrode layer; and gas is not generated from the light shielding parts because of the use of a Cr film or the like in the conductive light shielding parts as described above, and thus barrier property is unnecessary for areas where the light shielding parts are formed.

The forming material, the forming method, the film thickness and other matters of the light shielding parts are equivalent to those described in the item of the light shielding parts in the first embodiment. Thus, description thereof is not repeated herein.

(5) Color Converting Layer

As shown in, e.g., FIG. 23, in the embodiment, a color converting layer 8 may be formed on the colored layer 2 and between the colored layer 2 and the adhesive property improving layer 4′. As shown in, e.g., 24, a color converting layer 8 may be formed on the colored layer 2 and between the colored layer 2 and the overcoat layer 5.

When the color converting layer is formed in the embodiment, it is preferred, in the same manner as in the case of the colored layer, that the adhesive property improving layer is formed to leave an area of a predetermined width from the edge of the patterned colored layer and color converting layer in order to discharge degas components selectively from the non-display area and prevent the outflow of the gas into the display image area.

When the secondary transparent electrode layer is formed, it is preferred that the adhesive property improving layer, the transparent electrode layer and the secondary transparent electrode layer are formed to leave an area of a predetermined width from the edge of the patterned colored layer and color converting layer.

The adhesive property improving layer may be formed to cover the entire face of the patterned colored layer and color converting layer, the entire face of the patterned colored layer, color converting layer and overcoat layer, or the entire face of the overcoat layer. In this case, the colored layer, the color converting layer and the overcoat layer are not exposed; it is therefore possible to prevent more effectively the outflow of gas generated from the colored layer, the color converting layer and the overcoat layer.

Furthermore, when the film thickness of the color converting layer is largely varied in the layer, it is preferred that the overcoat layer is formed over the substrate on/over which the color converting layer is formed. This makes it possible to restrain the generation of dark areas.

Other matters of the color converting layer are equivalent to those described in the item of the color converting layer in the first embodiment. Thus, description thereof is not repeated herein.

(6) Process for Producing the Color Filter Substrate for an Organic EL Element

The following describes an example of the process for producing the color filter substrate for an organic EL element of the present embodiment.

First, a composite film made of chromium oxide and nitride is formed on a substrate by, for example, sputtering. Photolithography is then used to pattern the film, thereby forming a black matrix. For example, spin coating is used to apply a photosensitive paint composition for colored layer forming onto the substrate on which the black matrix is formed, and photolithography is used to pattern the resultant layer, thereby forming a colored layer. Next, a conductive layer forming dispersion liquid which contains fine particles made of indium alloy containing Sn is applied onto the colored layer by spin coating, and then the resultant is fired to form a conductive film. Then, an ITO film is formed on the colored layer by, for example, sputtering. Furthermore, photolithography is used to pattern the ITO film and the conductive film simultaneously, thereby forming an adhesive property improving layer and a transparent electrode layer. In this way, a color filter substrate for an organic EL element according to the embodiment can be produced.

It is allowable that before the formation of the ITO film an overcoat layer forming coating solution is applied onto the colored layer, thereby forming an overcoat layer to cover the entire of the colored layer.

(7) Others

It is also allowable in the invention that a barrier layer is formed between the colored layer and the adhesive property improving layer. This makes it possible to make high the barrier property of the color filter substrate for an organic EL element of the embodiment. This makes it possible or the like that even if pinholes are present in the barrier layer, the pinholes are blocked with the coated film of the adhesive property improving layer. This barrier layer may be a barrier layer which is ordinarily used in an organic EL element. The film thickness of the barrier layer used in the embodiment is thinner than that of any ordinary barrier layer since good barrier property can be obtained by the adhesive property improving layer and the transparent electrode layer.

### II. Second Embodiment

The following describes the second embodiment of the color filter substrate for an organic EL element of the present invention.

The second embodiment of the color filter substrate for an organic EL element of the present invention is characterized in providing a color filter substrate for organic EL element having a substrate, a colored layer formed in a pattern form on/over the substrate, a transparent electrode layer formed on/over the colored layer, and a conductive layer formed on/over the transparent electrode layer, wherein pinholes present in the transparent electrode layer are blocked with the conductive layer.

It is allowable in the embodiment that an overcoat layer 5 is formed between the colored layer 2 and the transparent electrode layer 3 as shown in FIG. 2.

As shown in, e.g., FIG. 3A, in the embodiment, pinholes PH present in the transparent electrode layer 3 are blocked with the conductive layer 4; therefore, barrier property can be obtained against gas generated from the colored layer, the color converting layer, the overcoat layer and so on, water vapor and oxygen. This makes it possible that when the color filter substrate for an organic EL element of the embodiment is used in an organic EL display device, good images having no dark spots are displayed.

The matter that the pinholes present in the transparent electrode layer are blocked with the conductive layer can be checked from, for example, a scanning electron microscope (SEM) photograph thereof. When the pinholes PH present in the transparent electrode layer 3 are blocked with the conductive layer 4 as shown in, e.g., FIG. 3A, the vicinity of the pinholes PH would be made substantially smooth. On the other hand, when pinholes PH present in the transparent electrode layer 23 are no blocked with the conductive layer 24 as shown in, e.g., FIG. 38, the vicinity of the pinholes PH cannot be made smooth. As described herein, in the present invention, the state that the vicinity of the pinholes in the transparent electrode layer is made substantially smooth is referred to by the wording “the pinholes are blocked with the conductive layer”.

The respective constituent members and other matters of the color filter substrate for an organic EL element are equivalent to those described about the first embodiment. Thus, description thereof is not repeated herein.

B. Organic EL Display Device

The following describes the organic EL display device of the present invention.

The organic EL display device has the above-mentioned color filter substrate for an organic EL element, an organic EL layer formed on/over the color filter substrate for an organic EL element and containing at least a light emitting layer, and a counter electrode layer formed on/over the organic EL layer.

Since the above-mentioned color filter substrate for an organic EL element is used according to the invention, the organic EL display device makes it possible to restrain the generation of defects such as dark spots and display good images. Additionally, barrier property can be obtained by the transparent electrode layer and the conductive layer in the color filter substrate for an organic EL element; therefore, it is unnecessary to form a thick transparent barrier layer as in the prior art so that costs can be reduced.

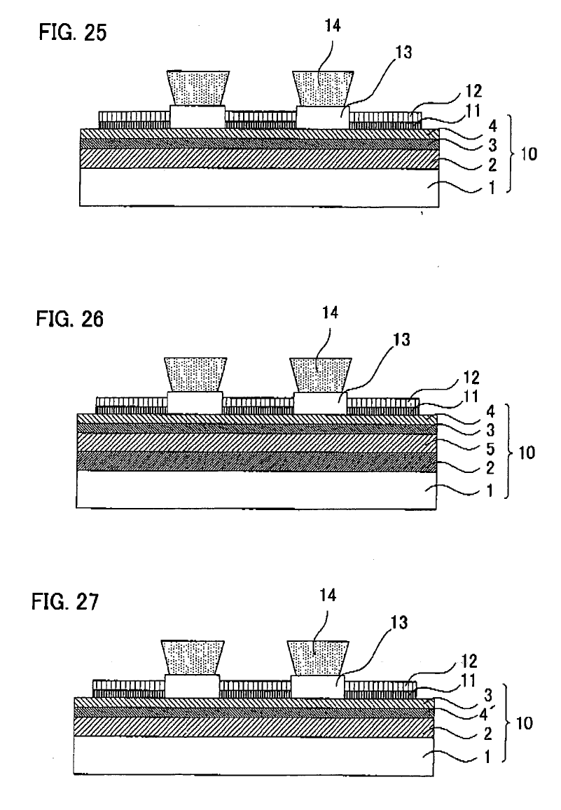

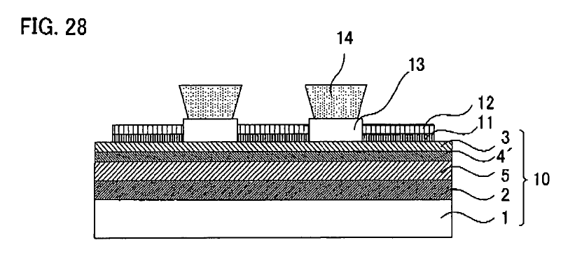

FIGS. 25 to 28 are each a view showing an example of the organic EL display device of the invention. As shown in FIG. 25, the organic EL display device according to the example has one of the above-mentioned color filter substrates 10 for organic EL element, an organic EL layer 11 formed in a pattern form on the conductive layer 4 of this color filter substrate 10 for organic EL element, and a counter electrode layer 12 formed on the organic EL layer 11. An insulting layer 13 is formed on the conductive layer 4 and between the organic EL layers 11. This insulating layer 13 is a layer formed not to bring the conductive layer 4 into contact with the counter electrode layer 12. Furthermore, partitions 14 are formed on the Insulating layer 13. Portions where the organic EL layer 11 is formed constitute an image display area.

In the organic EL display device shown in FIG. 27, the organic EL layer 11 is formed in a pattern form on the transparent electrode layer 3 of the color filter substrates 10 for organic EL element.

The following describes each of the constituent members of the organic EL display device.

1. Organic EL Layer

The organic EL layer used in the present invention comprises one layer or a plurality of organic layers including at least a light emitting layer. That is, the organic EL layer is a layer including at least a light emitting layer, with the layer configuration of one organic layer or more. In general, in the case the organic EL layer is formed with the wet process by coating, since the lamination of a large number of layers is difficult according to the relationship with the solvent, it is formed as one layer or two layers of organic layers in many cases. However, it is also possible to provide a larger number of layers by skillfully using the organic material so as to have a different solubility to solvent or employing the vacuum deposition method in a combination.

As the organic layers formed in the organic EL layer in addition to the light emitting layer, a charge injection layer such as a positive hole injection layer and an electron injection layer can be presented. Furthermore, as the other organic layers, a charge transporting layer such as a positive hole transporting layer for transporting the positive hole to the light emitting layer, and an electron transporting layer for transporting the electron to the light emitting layer can be presented. In general, these layers can be provided integrally with the charge injection layer by providing the charge transporting function to the charge injection layer. A different example of the organic layer formed in the organic EL layer is a layer for preventing the piercing of positive holes or electrons and further preventing the diffusion of excitons to confine the excitons in the light emitting layer, thereby making the efficiency of the recombination high. An example of the layer is a carrier block layer. Hereinafter, each configuration of such an organic EL layer will be explained.

(1) Light Emitting Layer

The light emitting layer used in the present invention is a layer having a function of supplying a field where electrons and positive holes are recombined, so as to emit light. As material forming the light emitting layer, in general, a pigment based light emitting material, a metal complex based light emitting material, or a polymer based light emitting material can be used.

As the pigment based light emitting material, for example, a cyclopentadiene derivative, a tetraphenyl butadiene derivative, a triphenyl amine derivative, an oxadiazol derivative, a pyrazoloquinoline derivative, a distyryl benzene derivative, a distyryl arylene derivative, a silol derivative, a thiophene ring compound, a pyridine ring compound, a perynon derivative, a perylene derivative, an oligothiophene derivative, a triphmanyl amine derivative, an coumalin derivative, an oxadiazol dimer, a pyrazoline dimer or the like can be presented.

Moreover, as the metal complex based light emitting material, for example, metal complexes having Al, Zn, Be, Ir, Pt or the like as the central metal, or a rare earth metal such as Tb, Eu, Dy or the like, and an oxadiazol, a thiadiazol, a phenyl pyridine, a phenyl benzoimidazol, a quinoline structure or the like as the ligand, such as an aluminum quinolino_ complex, a benzoquinolinol beryllium complex, a benzoxazol zinc complex, a benzothiazol zinc complex, an azomethyl zinc complex, a porphiline zinc complex, an europium complex, iridium complex, platinum complex or the like can be presented. Specifically, tris(8-quinolinol)aluminum complex (Alq₃) can be used.

Furthermore, as the polymer based light emitting material, for example, a polyparaphenylene vinylene derivative, a polythiophene derivative, a polyparaphenylene derivative, a polysilane derivative, a polyacetylene derivative, a polyvinyl carbazol, a polyfluorenone derivative, a polyfluorene derivative, a polyquinoxaline derivative, a polydialkylfluorene derivative, and a copolymer thereof or the like can be presented. Other examples thereof include products each obtained by making one or more of the pigment based light emitting material and the metal complex based light emitting materials into a polymer.

The light emitting material used in the invention is preferably selected from the metal complex based light emitting materials and the polymer based light emitting materials out of the above-mentioned examples, and is more preferably selected from the polymer based light emitting materials. Of the polymer based light emitting materials, a conductive polymer having a π conjugated structure is preferable. Examples thereof include poly-p-phenylenevinylene derivatives, polythiophene derivatives, poly-p-phenylene derivatives, polysilane derivatives, polyacetylene derivatives, polyfluorenone derivatives, polyfluorene derivatives, polyquinoxaline derivatives, polydialkylfluorene derivatives, and copolymers thereof, as described above,

The thickness of the light emitting layer is not particularly limited as long as it is a thickness capable of providing the field for recombination of the electron and the positive pole so as to provide the light emitting function. For example it can be about 1 nm to 200 nm.

A dopant which emits fluorescence or phosphorescence may be incorporated into the light emitting layer in order to improve the light emitting efficiency thereof, change the emission wavelength thereof, or attain others. Examples of the dopant include perylene derivatives, coumalin derivatives, rubrene derivatives, quinacridone derivative, squarylium derivatives, porphyrin derivatives, styrene dyes, tetracene derivatives, pyrazoline derivative, decacyclene, phenoxazone, quinoxaline derivatives, carbazole derivatives, and fluorene derivatives.

The method for forming the light emitting layer is not particularly limited if the method is capable of attaining highly precise patterning. Examples thereof include vapor deposition, printing, inkjet printing, spin coating, casting, dipping, bar coating, blade coating, roll coating, gravure coating, flexography, spray coating, and self-organization process (alternate adsorption or self-organization monomolecular film process). Of these, vapor deposition, spin coating, and inkjet printing are preferably used. When the light emitting layer is patterned, pixels exhibiting different light emitting colors may be separately formed by coating or vapor deposition using masking technique, or partitions may be formed between the light emitting layers. The material for forming the partitions may be a photosetting type resin such as photosensitive polyimide resin or acrylic resin, a thermosetting resin, an inorganic material, or the like. It is allowable to conduct treatment for changing the surface energy (wettability) of the material for forming the partitions.

(2) Charge Injection and Transporting Layer

In the present invention, the charge injection and transporting layer may be formed between the transparent electrode layer and the light emitting layer or between the light emitting layer and the counter electrode layer. The charge injection and transporting layer here has the function of stably transporting the charge from the transparent electrode layer or the counter electrode layer to the light emitting layer. By providing such a charge injection and transporting layer between the transparent electrode layer and the light emitting layer or between the light emitting layer and the counter electrode layer, the charge injection to the light emitting layer can be stabilized so as to improve the light emitting efficiency.

As such a charge injection and transporting layer, there are a positive hole injection and transporting layer for transporting the positive hole injected from the anode into the light emitting layer, and an electron injection and transporting layer for transporting the electron injected from the cathode into the light emitting layer. Hereinafter, the positive hole injection and transporting layer and the electron injection and transporting layer will be explained.

(i) Positive Hole Injection and Transporting Layer

The positive hole injection and transporting layer used in the present invention nay be one of the positive hole injection layer for injecting the positive hole into the light emitting layer or the positive hole transporting layer for transporting the positive hole, a lamination of the positive hole injection layer and the positive hole transporting layer, or a single layer having the both functions of the positive hole injecting function and the positive hole transporting function.

The material used for the positive hole injection and transporting layer is not particularly limited as long as it is a material capable of stably transporting the positive hole injected from the anode into the light emitting layer. In addition to the compounds presented for the light emitting material for the light emitting layer, phenyl amine based, star burst type amine based, phthalocyanine based, oxides such as a vanadium oxide, a molybdenum oxide, a ruthenium oxide, and an aluminum oxide, an amorphous carbon, a polyaniline, a polythiophene, a polyphenylene vinylene derivative or the like can be used. Specifically, a bis(N-(1-naphthyl-N-phenyl) benzidine (α-NPD), a 4,4,4-tris(3-methyl phenyl phenyl amino) triphenyl amine (MTDATA), a poly 3,4 ethylene dioxythiophene-polystyrene sulfonic acid (PEDOT-PSS), a polyvinyl carbazol (PVCz) or the like can be presented.

Moreover, the thickness of the positive hole injection and transporting layer is not particularly limited as long as it is a thickness capable of sufficiently performing the function of injecting the positive hole from the anode and transporting the positive hole to the light emitting layer. Specifically, it is in a range of 0.5 nm to 1,000 nm, in particular it is preferably in a range of 10 nm to 500 nm.

(ii) Electron Injection and Transporting Layer

The electron injection and transporting layer used in the present invention may be one of the electron injection layer for injecting the electron into the light emitting layer or the electron transporting layer for transporting the electron, a lamination of the electron injection layer and the electron transporting layer, or a single layer having the both functions of the electron injecting function and the electron transporting function.

The material used for the electron injection layer is not particularly limited as long as it is a material capable of stabilizing the electron injection into the light emitting layer. In addition to the compounds presented for the light emitting material for the light emitting layer, alkaline metals such as an aluminum lithium alloy, a lithium fluoride, a strontium, a magnesium oxide, a magnesium fluoride, a strontium fluoride, a calcium fluoride, a barium fluoride, an aluminum oxide, a strontium oxide, a calcium, a polymethyl methacrylate, a sodium polystyrene sulfonate, a lithium, a cesium, and a cesium fluoride, halides of the alkaline metals, organic complexes of the alkaline metals or the like can be used.

The thickness of the electron injection layer is not particularly limited as long as it is a thickness capable of sufficiently performing the electron injection function.

Moreover, the material used for the electron transporting layer is not particularly limited as long as it is a material capable of transporting the electron injected from the first transparent electrode layer and the second transparent electrode layer or the counter electrode layer into the light emitting layer, For example, a bathcuproine, a bathphenanthroline, a phenanthroline derivative, a triazol derivative, an oxadiazol derivative, a tris(8-quilinol)aluminum couplex (Alq₃) or the like can be presented.

Furthermore, as the electron injection and transporting layer comprising a single layer having the both functions of the electron injecting function and the electron transporting function, a metal doping layer with an alkaline metal or an alkaline earth metal doped to an electron transporting organic material may be formed so as to provide the electron injection and transporting layer. As the electron transporting organic material, for example, a bathcuproine, a bathphenanthroline, a phenanthroline derivative or the like can be presented. As the doping metal, Li, Cs, Ba, Sr or the like can be presented.

2. Counter Electrode Layer

The following describes the counter electrode layer used in the invention. The counter electrode layer is an electrode opposite to the transparent electrode layer, and is generally made of a metal. Specific examples of the metal include magnesium alloys (such as MgAg), aluminum alloys (such as AlLi, AlCa, and AlMg), aluminum, alkaline earth metals (such as Ca), and alkali metals (such as K, and Li).

The counter electrode layer can be formed by use of a method for forming an ordinary electrode layer. Examples thereof include sputtering and vacuum evaporation.

3. Insulating Layer

As shown in, e.g., FIG. 25, in the invention, an insulating layer 13 may be formed between pieces of the organic EL layer 11. This insulating layer is formed, as a non-display area, in a pattern form.

Examples of the material for forming the insulating layer used in the invention include photosetting resins such as ultraviolet curable resin, and thermosetting resins. The insulating layer can be formed by using a resin composition containing one or more of the above-mentioned resins. Moreover, for a patterning method of the insulating layer, those methods known in general such as the photolithography method or the printing method can be employed,

The present invention is not limited to the embodiments. The embodiments are merely examples, and any one having the substantially same configuration as the technological idea disclosed in the claims of the present invention and the same effects is included in the technological scope of the present invention.

### EXAMPLES

The present invention is specifically described by way of the following working examples and comparative examples.

### Example 1

(Formation of a Black Matrix)

As a transparent substrate, prepared was a 370 mm×470 mm×0.7 mm (thickness) sodium glass substrate (a Sn face polished product, manufactured by CENTRAL GLASS CO., LTD). This transparent substrate was washed by an ordinary method, and then a thin film (thickness: 0.2 μm) made of chromium nitride oxide complex was formed on the whole of one surface of the transparent substrate. A photosensitive resist was coated onto this thin film, and the resultant was subjected to mask-exposure and development. The thin film was then etched, thereby yielding a black matrix in which openings each having a 84 μm×284 μm rectangular shape were arranged at a pitch of 100 μm in a matrix form.

(Formation of a Colored Layer)

Prepared were photosensitive coating compositions for forming colored layers in three colors of red, green and blue. As a red coloring agent, a green coloring agent and a blue coloring agent, the following were used: a condensed azo dye (Chromophthal Red BRN, manufactured by Ciba-Geigy Japan Limited), a phthalocyanine based green pigment (Lionol Green 2Y-301, manufactured by TOYO INK MFG. CO., LTD.), and an anthraquinone based pigment (Chromophthal Blue A3R, manufactured by Ciba-Geigy Japan Limited), respectively. As a binder resin, a 10% aqueous solution of polyvinyl alcohol was used. One part of each of the coloring agents was incorporated into 10 parts of the aqueous solution of polyvinyl alcohol (the “part(s)” being part(s) by mass). The resultant was stirred to disperse the coloring agent sufficiently in the solutions One part of ammonium dichromate was added as a crosslinking agent to 100 parts of the resultant solution to yield a photosensitive coating composition for forming each of the colored layers.

The resultant colored-layer-forming photosensitive coating compositions were successively used to form colored layers in the respective colors. Specifically, the red-colored-layer-forming photosensitive coating composition was coated onto the transparent substrate, on which the black matrix was formed, by spin coating, and the resultant was pre-baked at 100° C. for 5 minutes. Thereafter, the resultant was exposed to light through a photomask, and then developed with a developer (0.05% KOH solution). Next, the resultant was post-baked at 200° C. for 60 minutes to form a pattern of bands (width: 85 μm, and thickness: 1.5 μm) of the red colored layer so as to make the opening consistent with the pattern of the black matrix and further direct the width direction thereof to the short side direction of the openings in the black matrix. Thereafter, the green-colored-layer-forming photosensitive coating composition and the blue-colored-layer-forming photosensitive coating composition were successively used to form green and blue colored layers. In this way, a unified colored layer in which the patterned colored layers in the three colors were repeatedly arranged in the width direction was formed.

(Formation of a Barrier Layer)

A SiON thin film having a thickness of 300 nm was formed as a barrier layer by sputtering, so as to cover the whole of the colored layer.

(Formation of a First Transparent Electrode Layer)

An ITO film having a thickness of 150 nm was formed on the formed barrier layer by sputtering.

(Formation of a Second Transparent Electrode Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed ITO film by spin coating, and then the resultant was fired at 250° C. in the atmosphere of oxygen gas (oxygen gas concentration: 100% by volume) having an atmospheric pressure for 10 minutes to form a conductive film having a thickness of 150 nm. This conductive film was a transparent and homogeneous film. It was ascertained that defects (pinholes) generated when the ITO film was formed were covered with the conductive layer so as to repair the defects.

(Patterning of the First and Second Transparent Electrode Layers)

A photosensitive resin was coated onto the ITO film and the conductive film, and the resultant was subjected to mask-exposure and development. The ITO film and the conductive film were then etched, thereby forming patterned first and second transparent electrode layers (pattern width: 100 μm, and space width: 20 μm)

(Formation of an Insulating Layer and Partitions)

An insulating layer forming coating solution, in which a norbornene based resin (ARTON, manufactured by JSR Corporation.) having an average molecular weight of about 100,000 was diluted with toluene, was coated onto the second transparent electrode layer by spin coating, so as to cover the first and second transparent electrode layers. The resultant was then baked at 100° C. for 30 minutes to form an insulating film (thickness: 1 μm). Next, a photosensitive resist was coated onto this insulating film, and the resultant was subjected to mask-exposure and development. The insulating film was then etched to form an insulating layer. This insulating layer had a pattern in the form of stripes (width: 20 μm) crossing the first transparent electrode layer at right angles, and positioned on the black matrix.

Next, a partition forming coating (Photoresist ZPN 1100, manufactured by ZEON CORPORATION) was coated onto the insulating layer by spin coating, so as to cover the entire face of the insulating layer. The resultant was pre-baked at 70° C. for 30 minute, exposed to light through a predetermined partition forming photomask, developed with a developer (ZTMA-100, manufactured by ZEON CORPORATION), and post-baked at 100° C. for 30 minutes. In this way, partitions were formed on the insulating layer. The partitions were in the following form: a height of 10 μm, a lower part (insulating layer side) width of 15 μm, and upper part width of 26 μm.

(Formation of an Organic EL Layer)

An organic EL layer consisting of a positive hole injection layer, a blue light emitting layer, and an electron injection layer was formed by vacuum evaporation using the partitions as a mask.

Specifically, 4,4′,4″-tris[N-(3-methylphenyl)-N-phenylamino]triphenylamine was first vapor-deposited into a thickness of 200 nm through a photomask having an opening corresponding to an image display area, so as to form a film. Thereafter, 4,4′-bis[N-(1-naphthyl)-N-phenylamino]biphenyl was vapor-deposited into a thickness of 20 nm to form a film, whereby the partitions functioned as a mask pattern so as to pass the positive hole injection layer materials only through spaces between the respective partitions. In this way, a positive hole injection layer was formed on the second transparent electrode layer. In the same way, 4,4′-bis(2,2-diphenylvinyl)biphenyl was vapor-deposited into a thickness of 50 nm to form a film as a blue light emitting layer. Thereafter, tris(8-quinolinol)aluminum was vapor-deposited into a thickness of 20 nm to form a film as an electron injection layer. The thus obtained organic EL layer was a layer in which patterned bands having a width of 280 μm were present between the respective partitions. A dummy organic EL layer having the same layer structure was formed on the upper surface of the partitions also.

(Formation of a Counter Electrode Layer)

Next, aluminum was vapor-deposited on the area where the partitions were formed, through a photomask having a predetermined opening larger than the image display area, by vacuum evaporation (vapor deposition rate of aluminum=1.3 to 1.4 nm/second). In this way, the partitions functioned as a mask to form a counter electrode layer (back electrode layer, thickness: 200 nm) made of aluminum on the organic EL layer. This counter electrode layer was a layer formed in a pattern of bands having a width of 280 μm on the organic EL layer. A dummy counter electrode layer was formed on the upper surface of the partitions also.

By the above-mentioned method, an organic EL element was yielded. The organic EL element was sealed up to yield an organic EL display device.

### Example 2

In the same way as in Example 1, a black matrix, a colored layer and a barrier layer were formed on a transparent substrate.

(Formation of a First Transparent Electrode Layer)

An ITO film having a thickness of 150 nm was formed on the formed barrier layer by sputtering. Furthermore, a photosensitive resist was coated onto the ITO film, and the resultant was subjected to mask-exposure, development and etching to form a first transparent electrode layer in the form of a pattern (width: 100 μm, and space width: 20 μm).

(Formation of a Second Transparent Electrode Layer)

Ag fine particles were dispersed into n-butyl acetate to give a concentration of 1%, thereby preparing a conductive metal layer forming dispersion liquid. This conductive metal layer forming dispersion liquid was coated onto the formed ITO film by spin coating and dried. Next, the resultant was fired at 250° C. in the atmosphere for 10 minutes to form an Ag film, as a conductive metal film with a thickness of 5 nm. This conductive metal film was a transparent and homogeneous film. It was ascertained that defects (pinholes) generated when the first transparent electrode layer was formed were covered with the conductive metal film so as to repair the defects.

Furthermore, a photosensitive resist was coated onto the conductive metal film, and then the resultant was subjected to mask-exposure, development and etching so as to form a second transparent electrode layer in the form of a pattern (width: 100 μm, and space width: 20 μm).

(Production of an Organic EL Element)

Next, an insulating layer, partitions, an organic EL layer and a counter electrode layer were formed in the same way as in Example 1, so as to yield an organic EL element. The organic EL element was sealed up to yield an organic EL display device.

### Example 3

In the same way as in Example 1, a black matrix and a colored layer were formed on a transparent substrate.

(Formation of an Inorganic Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed colored layer by spin coating, and then the resultant was fired at 250° C. in the atmosphere of oxygen gas (oxygen gas concentration: 100% by volume) having an atmospheric pressure for 10 minutes to form a conductive film with a thickness of 150 nm. This conductive film was a transparent and homogeneous film.

(Formation of a First Transparent Electrode Layer)

An ITO film having a thickness of 150 nm was formed on the formed inorganic layer by sputtering.

(Formation of a Second Transparent Electrode Layer)

The conductive layer forming dispersion liquid used when the inorganic layer was formed was coated onto the formed ITO film by spin coating, and then the resultant was fired at 250° C. in the atmosphere of oxygen gas (oxygen gas concentration: 100% by volume) having an atmospheric pressure for 10 minutes to form a conductive film with a thickness of 150 nm. This conductive film was a transparent and homogeneous film. It was ascertained that defects (pinholes) generated when the ITO film was formed were covered with the conductive film so as to repair the defects.

(Patterning of the Inorganic Layer, the First Transparent Electrode Layer and the Second Transparent Electrode Layer)

A photosensitive resist was coated onto the laminated film in which the conductive film, the ITO film and the other conductive layer film were laminated, and the resultant was subjected to mask-exposure and development. The ITO film and the conductive layers were etched to form a patterned inorganic layer, first transparent electrode layer and second transparent electrode layer (pattern width: 100 μm, and space width; 20 μm).

(Production of an Organic EL Element)

Next, an insulating layer, partitions, an organic EL layer and a counter electrode layer were formed in the same way as in Example 1, so as to yield an organic EL element. The organic EL element was sealed up to yield an organic EL display device.

### Example 4

In the same way as in Example 1, a black matrix and a colored layer were formed on a transparent substrate.

(Formation of a Color Converting Layer)

A blue color converting layer (dummy layer) forming coating solution (transparent photosensitive resin composition, trade name: “Color Mosaic CB-701”, manufactured by FUJIFILM ELECTRONIC MATERIALS CO., LTD.) was coated onto the formed black matrix and colored layer by spin coating, and the resultant was pre-baked at 100° C. for 5 minutes, patterned by photolithography, and then post-baked at 200° C. for 60 minutes. In this way, a blue color converting layer (dummy layer) in the form of bands (width; 85 μm, and thickness: 10 μm) was formed on the blue colored layer.

Next, an alkali-soluble negative photosensitive resist in which a green color converting fluorescent substance (coumalin 6, manufactured by SIGMA-ALDRICH Corp.) was dispersed was used as a green color converting layer forming coating solution to form a green color converting layer in the form of bands (width: 85 μm, and thickness: 10 μm) on the green colored layer in the same way as described above.

Next, an alkali-soluble negative photosensitive resist in which a red color converting fluorescent substance (rhodamine 6G, manufactured by SIGMA-ALDRICH Corp.) was dispersed was used as a red color converting layer forming coating solution to form a red color converting layer in the form of bands (width: 85 μm, and thickness: 10 μm) on the red colored layer in the same way as described above.

(Formation of a Hard Coat Layer)

Next, a hard coat layer forming coating solution in which an acrylic thermosetting resin (trade name: “V-259PA/PH5”, manufactured by Nippon Steel Chemical Co., Ltd.) was diluted with propylene glycol monomethyl ether acetate was coated onto the formed color converting layers by spin coating, and the resultant was pre-baked at 120° C. for 5 minutes. The whole surface thereof was exposed to ultraviolet rays to set the quantity of the radiated rays into 300 mJ. After the exposure, the resultant was post-baked at 200° C. for 60 minutes, thereby forming a transparent hard coat layer having a thickness of 5 μm to cover the whole of the color converting layers.

(Formation of an Organic EL Element)

Next, a barrier layer, a first transparent electrode layer, a second transparent electrode layer, an insulating layer, partitions, an organic EL layer and a counter electrode layer were formed on the formed hard coat layer in the same way as in Example 1, so as to yield an organic EL element. The organic EL element was sealed up to yield an organic EL display device.

### Comparative Example 1

An organic EL element was produced in the same way as in Example 1 except that the second transparent electrode layer in Example 1 8 was not formed. The organic EL element was sealed up to yield an organic EL display device.

### Comparative Example 2

An organic EL element was produced in the same way as in Example 1 except that the second transparent electrode layer in Example 4 was not formed. The organic EL element was sealed up to yield an organic EL display device.

[Evaluation]

A DC voltage of 8.5 V was applied to the first transparent electrode layer and the counter electrode layer of each of the organic EL display devices of Examples 1 to 4 and Comparative Examples 1 and 2 at a constant current density of 10 mA/cm² to drive the display device continuously, thereby emitting light from the blue light emitting layer at desired sites where the pattern pieces of the first transparent electrode layer and the counter electrode layer crossed. The luminous area of the organic EL display devices were an area 6 mm square. The organic EL display device was subjected to a storage test at a temperature of 85° C. and a relative humidity of 60%. After 500 hours from the start of the test, defects in the organic EL element were observed with an optical microscope (magnifications: 50) to evaluate the organic EL element.

As a result, dark spots were generated in the organic EL display device of Comparative Example 1. In the organic EL display device of Comparative Example 2, its pixels shrank. On the other hand, in the organic EL display devices of Examples 1 to 4, no dark spot was generated so that display characteristics having excellent durability were exhibited. In the organic EL display devices of Examples 1 to 3, their pixels did not shrink.

### Example 5

(Formation of a Black Matrix)

As a transparent substrate, prepared was a 370 mm×470 mm×0.7 mm (thickness) sodium glass substrate (a Sn face polished product, manufactured by CENTRAL GLASS CO., LTD). This transparent substrate was washed by an ordinary method, and then a thin film (thickness: 0.2 μm) made of chromium nitride oxide complex was formed on the whole of one surface of the transparent substrate. A photosensitive resist was coated onto this thin film, and the resultant was subjected to mask-exposure and development. The thin film was then etched, thereby yielding a black matrix in which openings each having a 84 μm×284 μm rectangular shape were arranged at a pitch of 100 μm in a matrix form.

(Formation of a Colored Layer)

Prepared were photosensitive coating compositions for forming colored layers in three colors of red, green and blue. As a red coloring agent, a green coloring agent and a blue coloring agent, the following were used: a condensed azo dye (Chromophthal Red BRN, manufactured by Ciba-Geigy Japan Limited), a phthalocyanine based green pigment (Lionol Green 2Y-301, manufactured by TOYO INK MFG. CO., LTD.), and an anthraquinone based pigment (Chromophthal Blue A3R, manufactured by Ciba-Geigy Japan Limited), respectively. As a binder resin, a 10% aqueous solution of polyvinyl alcohol was used. One part of each of the coloring agents was incorporated into 10 parts of the aqueous solution of polyvinyl alcohol (the “part's)” being part(s) by mass). The resultant was stirred to disperse the coloring agent sufficiently in the solution. One part of ammonium dichromate was added as a crosslinking agent to 100 parts of the resultant solution to yield a photosensitive coating composition for forming each of the colored layers.

The resultant colored-layer-forming photosensitive coating compositions were successively used to form colored layers in the respective colors. Specifically, the red-colored-layer-forming photosensitive coating composition was coated onto the transparent substrate, on which the black matrix was formed, by spin coating, and the resultant was pre-baked at 100° C. for 5 minutes. Thereafter, the resultant was exposed to light through a photomask, and then developed with a developer (0.05% KOH solution). Next, the resultant was post-baked at 200° C. for 60 minutes to form a pattern of bands (width: 85 μm, and thickness: 1.5 μm) of the red colored layer so as to make the opening consistent with the pattern of the black matrix and further direct the width direction thereof to the short side direction of the openings in the black matrix. Thereafter, the green-colored-layer-forming photosensitive coating composition and the blue-colored-layer-forming photosensitive coating composition were successively used to form green and blue colored layers. In this way, a unified colored layer in which the patterned colored layers in the three colors were repeatedly arranged in the width direction was formed.

(Formation of a Color Converting Layer)

A blue color converting layer (dummy layer) forming coating solution (transparent photosensitive resin composition, trade name: “Color Mosaic CB-701”, manufactured by FUJIFILM ELECTRONIC MATERIALS CO., LTD.) was coated onto the formed black matrix and colored layer by spin coating, and the resultant was pre-baked at 100° C. for 5 minutes, patterned by photolithography, and then post-baked at 200° C. for 60 minutes. In this way, a blue color converting layer (dummy layer) in the form of bands (width: 85 μm, and thickness: 10 μm) was formed on the blue colored layer.

Next, an alkali-soluble negative photosensitive resist in which a green color converting fluorescent substance (coumalin 6, manufactured by SIGMA-ALDRICH Corp.) was dispersed was used as a green color converting layer forming coating solution to form a green color converting layer in the form of bands (width: 85 μm, and thickness: 10 μm) on the green colored layer in the same way as described above.

Next, an alkali-soluble negative photosensitive resist in which a red color converting fluorescent substance (rhodamine 6G, manufactured by SIGMA-ALDRICH Corp.) was dispersed was used as a red color converting layer forming coating solution to form a red color converting layer in the form of bands (width: 85 μm, and thickness: 10 μm) on the red colored layer in the same way as described above.

(Formation of an Overcoat Layer)

Next, an overcoat layer forming coating solution in which an acrylic thermosetting resin (trade name: “V-259PA/PH5”, manufactured by Nippon Steel Chemical Co., Ltd.) was diluted with propylene glycol monomethyl ether acetate was coated onto the formed color converting layers by spin coating, and the resultant was pre-baked at 120° C. for 5 minutes. The whole surface thereof was exposed to ultraviolet rays to set the quantity of the radiated rays into 300 mJ. After the exposure, the resultant was post-baked at 200° C. for 60 minutes, thereby forming a transparent overcoat layer having a thickness of 5 μm to cover the whole of the color converting layers.

(Formation of a Barrier Layer)

A SiON thin film having a thickness of 300 nm was formed as a barrier layer by sputtering on the overcoat layer.

(Formation of a First Transparent Electrode Layer)

An ITO film having a thickness of 150 nm was formed on the formed barrier layer by sputtering.

(Formation of a Second Transparent Electrode Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed ITO film by spin coating, and then the resultant was fired at 250° C. in the atmosphere of oxygen gas (oxygen gas concentration: 100% by volume) having an atmospheric pressure for 10 minutes to form a conductive film having a thickness of 150 nm. This conductive film was a transparent and homogeneous film. It was ascertained that defects (pinholes) generated when the ITO film was formed were covered with the conductive layer so as to repair the defects.

(Patterning of the First and Second Transparent Electrode Layers)

A photosensitive resin was coated onto the ITO film and the conductive film, and the resultant was subjected to mask-exposure and development. The ITO film and the conductive film were then etched, thereby forming patterned first and second transparent electrode layers (pattern width: 100 μm, and space width: 20 μm)

(Formation of an Insulating Layer and Partitions)

An insulating layer forming coating solution, in which a norbornene based resin (ARTON, manufactured by JSR Corporation.) having an average molecular weight of about 100,000 was diluted with toluene, was coated onto the second transparent electrode layer by spin coating, so as to cover the first and second transparent electrode layers. The resultant was then baked at 100° C. for 30 minutes to form an insulating film (thickness: 1 μm). Next, a photosensitive resist was coated onto this insulating film, and the resultant was subjected to mask-exposure and development. The insulating film was then etched to form an insulating layer. This insulating layer had a pattern in the form of stripes (width: 20 μm) crossing the first transparent electrode layer at right angles, and positioned on the black matrix.

Next, a partition forming coat (Photoresist ZPN 1100, manufactured by ZEON CORPORATION) was coated onto the insulating layer by spin coating, so as to cover the entire face of the insulating layer. The resultant was pro-baked at 70° C. for 30 minute, exposed to light through a predetermined partition forming photomask, developed with a developer (ZTMA-100, manufactured by ZEON CORPORATION), and post-baked at 100° C. for 30 minutes. In this way, partitions were formed on the insulating layer. The partitions were in the following form: a height of 10 μm, a lower part (insulating layer side) width of 15 μm, and upper part width of 26 μm.

(Formation of an Organic EL Layer)

An organic EL layer consisting of a positive hole injection layer, a blue light emitting layer, and an electron injection layer was formed by vacuum evaporation using the partitions as a mask. Specifically, 4,4′,4″-tris[N-(3-methylphenyl)-N-phenylamino]triphenylamine was first vapor-deposited into a thickness of 200 nm through a photomask having an opening corresponding to an image display area, so as to form a film. Thereafter, vapor-deposited into a thickness of 20 nm to form a film, whereby the partitions functioned as a mask pattern so as to pass the positive hole injection layer materials only through spaces between the respective partitions. In this way, a positive hole injection layer was formed on the second transparent electrode layer. In the same way, 4,4′-bis(2,2-diphenylvinyl)biphenyl was vapor-deposited into a thickness of 50 nm to form a film as a blue light emitting layer. Thereafter, tris(8-quinolinol)aluminum was vapor-deposited into a thickness of 20 nm to form a film as an electron injection layer. The thus obtained organic EL layer was a layer in which patterned bands having a width of 280 μm were present between the respective partitions. A dummy organic EL layer having the same layer structure was formed on the upper surface of the partitions also.

(Formation of a Counter Electrode Layer)

Next, aluminum was vapor-deposited on the area where the partitions were formed, through a photomask having a predetermined opening larger than the image display area, by vacuum evaporation (vapor deposition rate of aluminum=1.3 to 1.4 nm/second). In this way, the partitions functioned as a mask to form a counter electrode layer (back electrode layer, thickness: 200 nm) made of aluminum on the organic EL layer. This counter electrode layer was a layer formed in a pattern of bands having a width of 280 μm on the organic EL layer. A dummy counter electrode layer was formed on the upper surface of the partitions also.

By the above-mentioned method, an organic EL element was yielded. The organic EL element was sealed up to yield an organic EL display device.

### Example 6

In the same way as in Example 5, a black matrix, a colored layer, a color converting layer, an overcoat layer and a barrier layer were formed on a transparent substrate.

(Formation of a First Transparent Electrode Layer)

An ITO film having a thickness of 150 nm was formed on the formed barrier layer by sputtering. Furthermore, a photosensitive resist was coated onto the ITO film, and the resultant was subjected to mask-exposure, development and etching to form a first transparent electrode layer in the form of a pattern (width: 100 μm, and space width: 20 μm).

(Formation of a Second Transparent Electrode Layer)

Ag fine particles were dispersed into n-butyl acetate to give a concentration of 1%, thereby preparing a conductive metal layer forming dispersion liquid. This conductive metal layer forming dispersion liquid was coated onto the formed ITO film by spin coating and dried. Next, the resultant was fired at 250° C. in the atmosphere for 10 minutes to form an Ag film, as a conductive metal film with a thickness of 5 nm. This conductive metal film was a transparent and homogeneous film. It was ascertained that defects (pinholes) generated when the first transparent electrode layer was formed were covered with the conductive metal film so as to repair the defects.

Furthermore, a photosensitive resist was coated onto the conductive metal film, and then the resultant was subjected to mask-exposure, development and etching so as to form a second transparent electrode layer in the form of a pattern (width: 100 μm, and space width: 20 μm).

(Production of an Organic EL Element)

Next, an insulating layer, partitions, an organic EL layer and a counter electrode layer were formed in the same way as in Example 5, so as to yield an organic EL element. The organic EL element was sealed up to yield an organic EL display device.

### Example 7

In the same way as in Example 5, a black matrix, a colored layer, a color converting layer and an overcoat layer were formed on a transparent substrate.

(Formation of an Inorganic Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated on to the formed overcoat layer by spin coating, and then the resultant was fired at 250° C. in the atmosphere of oxygen gas (oxygen gas concentration: 100% by volume) having an atmospheric pressure for 10 minutes to form a conductive film with a thickness of 150 nm, This conductive film was a transparent and homogeneous film.

(Formation of a First Transparent Electrode Layer)

An ITO film having a thickness of 150 nm was formed on the formed inorganic layer by sputtering.

(Formation of a Second Transparent Electrode Layer)

The conductive layer forming dispersion liquid used when the inorganic layer was formed was coated onto the formed ITO film by spin coating, and then the resultant was fired at 250° C. in the atmosphere of oxygen gas (oxygen gas concentration: 100% by volume) having an atmospheric pressure for 10 minutes to form a conductive film with a thickness of 150 nm. This conductive film was a transparent and homogeneous film. It was ascertained that defects (pinholes) generated when the ITO film was formed were covered with the conductive film so as to repair the defects.

(Patterning of the Inorganic Layer, the First Transparent Electrode Layer and the Second Transparent Electrode Layer)

A photosensitive resist was coated onto the laminated film in which the conductive film, the ITO film and the other conductive layer film were laminated, and the resultant was subjected to mask-exposure and development. The ITO film and the conductive layers were etched to form a patterned inorganic layer, first transparent electrode layer and second transparent electrode layer (pattern width: 100 μm, and space width: 20 μm).

(Production of an Organic EL Element)

Next, an insulating layer, partitions, an organic EL layer and a counter electrode layer were formed in the same way as in Example 5, so as to yield an organic EL element. The organic EL element was sealed up to yield an organic EL display device.

### Comparative Example 3

An organic EL element was produced in the same way as in Example 5 except that the second transparent electrode layer in Example 5 was not formed. The organic EL element was sealed up to yield an organic EL display device.

[Evaluation]

A DC voltage of 8.5 V was applied to the first transparent electrode layer and the counter electrode layer of each of the organic EL display devices of Examples 5 to 7 and Comparative Example 3 at a constant current density of 10 mA/cm² to drive the display device continuously, thereby emitting light from the blue light emitting layer at desired sites where the pattern pieces of the first transparent electrode layer and the counter electrode layer crossed. The luminous area of the organic EL display device was an area 6 mm square. The organic EL display devices were subjected to a storage test at a temperature of 85° C. and a relative humidity of 60%. After 500 hours from the start of the test, defects in the organic EL element were observed with an optical microscope (magnifications: 50) to evaluate the organic EL element.

As a result, dark spots were generated in the organic EL display device of Comparative Example 3. On the other hand, in the organic EL display devices of Examples 5 to 7, no dark spot was generated so that display characteristics having excellent durability were exhibited.

### Example 8

(Formation of a Black Matrix)

As a transparent substrate, prepared was a 370 mm×470 mm×0.7 mm (thickness) sodium glass substrate (a Sn face polished product, manufactured by CENTRAL GLASS CO., LTD). This transparent substrate was washed by an ordinary method, and then a thin film (thickness: 0.2 μm) made of chromium nitride oxide complex was formed on the whole of one surface of the transparent substrate. A photosensitive resist was coated onto this thin film, and the resultant was subjected to mask-exposure and development. The thin film was then etched, thereby yielding a black matrix in which openings each having a 84 μm×284 μm rectangular shape were arranged at a pitch of 100 μm in a matrix form.

(Formation of a Colored Layer)

Prepared were photosensitive coating compositions for forming colored layers in three colors of red, green and blue. As a red coloring agent, a green coloring agent and a blue coloring agent, the following were used: a condensed azo dye (Chromophthal Red BRN, manufactured by Ciba-Geigy Japan Limited), a phthalocyanine based green pigment (Lionol Green 2Y-301, manufactured by TOYO INK MFG. CO., LTD.), and an anthraquinone based pigment (Chromophthal Blue A3R, manufactured by Ciba-Geigy Japan Limited), respectively. As a binder resin, a 10% aqueous solution of polyvinyl alcohol was used. One part of each of the coloring agents was incorporated into 10 parts of the aqueous solution of polyvinyl alcohol (the “part(s)” being part(s) by mass). The resultant was stirred to disperse the coloring agent sufficiently in the solution. One part of ammonium dichromate was added as a crosslinking agent to 100 parts of the resultant solution to yield a photosensitive coating composition for forming each of the colored layers.

The resultant colored-layer-forming photosensitive coating compositions were successively used to form colored layers in the respective colors. Specifically, the red-colored-layer-forming photosensitive coating composition was coated onto the transparent substrate, on which the black matrix was formed, by spin coating, and the resultant was pre-baked at 100° C. for 5 minutes. Thereafter, the resultant was exposed to light through a photomask, and then developed with a developer (0.05% KOH solution). Next, the resultant was post-baked at 200° C. for 60 minutes to form a pattern of bands (width; 85 μm, and thickness: 1.5 μm) of the red colored layer so as to make the opening consistent with the pattern of the black matrix and further direct the width direction thereof to the short side direction of the openings in the black matrix. Thereafter, the green-colored-layer-forming photosensitive coating composition and the blue-colored-layer-forming photosensitive coating composition were successively used to form green and blue colored layers. In this way, a unified colored layer in which the patterned colored layers in the three colors were repeatedly arranged in the width direction was formed.

(Formation of an Adhesive Property Improving Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed colored layer by spin coating, and then the resultant was fired at 250° C. in the atmosphere of oxygen gas (oxygen gas concentration: 100% by volume) having an atmospheric pressure for 10 minutes to form a conductive film with a thickness of 150 nm. This conductive film was a transparent and homogeneous film.

(Formation of a Transparent Electrode Layer)

An ITO film having a thickness of 150 nm was formed on the formed adhesive property improving layer by sputtering.

(Patterning of the Adhesive Property Improving Layer and the Transparent Electrode Layer)

A photosensitive resist was coated onto the conductive film and the ITO film, and the resultant was subjected to mask-exposure and development. The ITO film and the conductive layers were etched to form a patterned adhesive property improving layer and transparent electrode layer (pattern width: 100 μm, and space width: 20 μm).

(Formation of an Insulating Layer and Partitions)

An insulating layer forming coating solution, in which a norbornene based resin (ARTON, manufactured by JSR Corporation.) having an average molecular weight of about 100,000 was diluted with toluene, was coated onto the transparent electrode layer by spin coating, so as to cover the adhesive property improving layer and the transparent electrode layer. The resultant was then baked at 100° C. for 30 minutes to form an insulating film (thickness: 1 μm). Next, a photosensitive resist was coated onto this insulating film, and the resultant was subjected to mask-exposure and development. The insulating film was then etched to form an insulating layer. This insulating layer had a pattern in the form of stripes (width: 20 μm) crossing the transparent electrode layer at right angles, and positioned on the black matrix.

Next, a partition forming coat (Photoresist ZPN 1100, manufactured by ZEON CORPORATION) was coated onto the insulating layer by spin coating, so as to cover the entire face of the insulating layer. The resultant was pre-baked at 70° C. for 30 minute, exposed to light through a predetermined partition forming photomask, developed with a developer (ZTMA-100, manufactured by ZEON CORPORATION), and post-baked at 100° C. for 30 minutes. In this way, partitions were formed on the insulating layer. The partitions were in the following form: a height of 10 μm, a lower part (insulating layer side part) width of 15 μm, and upper part width of 26 μm.

(Formation of an Organic EL Layer)

An organic EL layer consisting of a positive hole injection layer, a blue light emitting layer, and an electron injection layer was formed by vacuum evaporation using the partitions as a mask.

Specifically, 4,4′,4″-tris[N-(3-methylphenyl)-N-phenylamino]triphenylamine was first vapor-deposited into a thickness of 200 nm through a photomask having an opening corresponding to an image display area, so as to form a film. Thereafter, 4,4′-bis[N-(1-naphthyl)-N-phenylamino]biphenyl was vapor-deposited into a thickness of 20 nm to form a film, whereby the partitions functioned as a mask pattern so as to pass the positive hole injection layer materials only through spaces between the respective partitions. In this way, a positive hole injection layer was formed on the transparent electrode layer. In the same way, 4,4′-bis(2,2-diphenylvinyl)biphenyl was vapor-deposited into a thickness of 50 nm to form a film as a blue light emitting layer. Thereafter, tris(8-quinolinol)aluminum was vapor-deposited into a thickness of 20 nm to form a film as an electron injection layer. The thus obtained organic EL layer was a layer in which patterned bands having a width of 280 μm were present between the respective partitions. A dummy organic EL layer having the same layer structure was formed on the upper surface of the partitions also.

(Formation of a Counter Electrode Layer)

Next, aluminum was vapor-deposited on the area where the partitions were formed, through a photomask having a predetermined opening larger than the image display area, by vacuum evaporation (vapor deposition rate of aluminum=1.3 to 1.4 nm/second). In this way, the partitions functioned as a mask to form a counter electrode layer (back electrode layer, thickness: 200 nm) made of aluminum on the organic EL layer. This counter electrode layer was a layer formed in a pattern of bands having a width of 280 μm on the organic EL layer. A dummy counter electrode layer was formed on the upper surface of the partitions also.

By the above-mentioned method, an organic EL element was yielded. The organic EL element was sealed up to yield an organic EL display device.

### Example 9

In the same way as in Example 8, a black matrix and a colored layer were formed on a transparent substrate.

(Formation of an Adhesive Property Improving Layer)

Ag fine particles were dispersed into n-butyl acetate to give a concentration of 1%, thereby preparing a conductive metal layer forming dispersion liquid. This conductive metal layer forming dispersion liquid was coated onto the formed colored layer by spin coating and dried. Next, the resultant was fired at 250° C. in the atmosphere for 10 minutes to form an Ag film, as a conductive metal film, with a thickness of 5 nm. This conductive metal film was a transparent and homogeneous film.

Furthermore, a photosensitive resist was coated onto the conductive metal film, and then the resultant was subjected to mask-exposure, development and etching so as to form an adhesive property improving layer in the form of a pattern (width: 100 μm, and space width: 20 μm).

(Formation of a Transparent Electrode Layer)

An ITO film having a thickness of 150 nm was formed on the formed adhesive property improving layer by sputtering. Furthermore, a photosensitive resist was coated onto the ITO film, and the resultant was subjected to mask-exposure, development and etching to form a transparent electrode layer in the form of a pattern (width: 100 μm, and space width: 20 μm).

(Production of an Organic EL Element)

Next, an insulating layer, partitions, an organic EL layer and a counter electrode layer were formed in the same way as in Example 8, so as to yield an organic EL element. The organic EL element was sealed up to yield an organic EL display device.

### Example 10

In the same way as in Example 8, a black matrix, a colored layer, a conductive layer, and an ITO film were formed on a transparent substrates

(Formation of a Secondary Transparent Electrode Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed ITO film by spin coating, and then the resultant was fired at 250° C. in the atmosphere of oxygen gas (oxygen gas concentration: 100% by volume) having an atmospheric pressure for 10 minutes to form a conductive film with a thickness of 150 nm. This conductive film was a transparent and homogeneous film. It was ascertained that defects (pinholes) generated when the ITO film was formed were covered with the conductive film so as to repair the defects.

(Patterning of the Adhesive Property Improving Layer, the Transparent Electrode Layer and the Secondary Transparent Electrode Layer)

A photosensitive resist was coated onto the conductive film, and conductive film and the ITO film, and the resultant was subjected to mask-exposure and development. The conductive film, and the ITO film and the conductive layers were etched to form a patterned adhesive property improving layer, transparent electrode layer and secondary transparent electrode layer (pattern width: 100 μm, and space width: 20 μm).

(Production of an Organic EL Element)

Next, an insulating layer, partitions, an organic EL layer and a counter electrode layer were formed in the same way as in Example 8, so as to yield an organic EL element. The organic EL element was sealed up to yield an organic EL display device.

### Example 11

In the same way as in Example 8, a black matrix and a colored layer were formed on a transparent substrate.

(Formation of a Color Converting Layer)

A blue color converting layer (dummy layer) forming coating solution (transparent photosensitive resin composition, trade name: “Color Mosaic CB-701”, manufactured by FUJIFILM ELECTRONIC MATERIALS CO., LTD.) was coated onto the formed black matrix and colored layer by spin coating, and the resultant was pre-baked at 100° C. for 5 minutes, patterned by photolithography, and then post-baked at 200° C. for 60 minutes. In this way, a blue color converting layer (dummy layer) in the form of bands (width: 85 μm, and thickness: 10 μm) was formed on the blue colored layer.

Next, an alkali-soluble negative photosensitive resist in which a green color converting fluorescent substance (coumalin 6, manufactured by SIGMA-ALDRICH Corp.) was dispersed was used as a green color converting layer forming coating solution to form a green color converting layer in the form of bands (width: 85 μm, and thickness: 10 μm) on the green colored layer in the same way as described above.

Next, an alkali-soluble negative photosensitive resist in which a red color converting fluorescent substance (rhodamine 6G, manufactured by SIGMA-ALDRICH Corp.) was dispersed was used as a red color converting layer forming coating solution to form a red color converting layer in the form of bands (width: 85 μm, and thickness: 10 μm) on the red colored layer in the same way as described above.

(Formation of a Hard Coat Layer)

Next, a hard coat layer forming coating solution in which an acrylic thermosetting resin (trade name: “V-259PA/PH5”, manufactured by Nippon Steel Chemical Co., Ltd.) was diluted with propylene glycol monomethyl ether acetate was coated onto the formed color converting layers by spin coating, and the resultant was pre-baked at 120° C. for 5 minutes. The whole surface thereof was exposed to ultraviolet rays to set the quantity of the radiated rays into 300 mJ. After the exposure, the resultant was post-baked at 200° C. for 60 minutes, thereby forming a transparent hard coat layer having a thickness of 5 μm to cover the whole of the color converting layers.

(Formation of an Organic EL Element)

Next, an adhesive property improving layer, a transparent electrode layer, a secondary transparent electrode layer, an insulating layer, partitions, and an organic EL layer and a counter electrode layer were formed on the formed hard coat layer in the same way as in Example 10, so as to yield an organic EL element. The organic EL element was sealed up to yield an organic EL display device.

### Comparative Example 4

An organic EL element was produced in the same way as in Example 8 except that the adhesive property improving layer in Example 8 was not formed.

### Comparative Example 5

An organic EL element was produced in the same way as in Example 8 except that instead of the adhesive property improving layer in Example 8, a SiO₂ thin film having a thickness of 20 nm was formed over the entire face of the transparent substrate on which the colored layer and so on were formed.

[Evaluation]

In Examples 8 to 11 and Comparative Example 5, film-peeling was not observed when the transparent electrode layer thereof was formed. However, in Comparative Example 4, film-peeling was generated when the transparent electrode layer thereof was formed.

A DC voltage of 8.5V was applied to the transparent electrode layer and the counter electrode layer of each of the organic EL display devices of Examples 8 to 11 and Comparative Example 5 at a constant current density of 10 mA/cm² to drive the display device continuously, thereby emitting light from the blue light emitting layer at desired sites where the pattern pieces of the transparent electrode layer and the counter electrode layer crossed. The luminous area of the organic EL display device was an area 6 mm square. The organic EL display devices were subjected to a storage test at a temperature of 85° C. and a relative humidity of 60%. After 500 hours from the start of the test, defects in the organic EL element were observed with an optical microscope (magnifications: 50) to evaluate the organic EL element.

As a result, dark spots were generated in the organic EL display device of Comparative Example 5. It appears that this was based on the following reason: irregularities in the colored layer surface were not permitted to be made smooth by the SiO₂ film; therefore, degas components flowed out from the irregular portions so that dark spots were generated. On the other hand, in the organic EL display devices of Examples 8 to 11, dark spots were not generated so that display characteristics having excellent durability were exhibited.

### Example 12

(Formation of a Black Matrix)

As a transparent substrate, prepared was a 370 mm×470 mm×0.7 mm (thickness) sodium glass substrate (a Sn face polished product, manufactured by CENTRAL GLASS CO., LTD). This transparent substrate was washed by an ordinary method, and then a thin film (thickness: 0.2 μm) made of chromium nitride complex was formed on the whole of one surface of the transparent substrate. A photosensitive resist was coated onto this thin film, and the resultant was subjected to mask-exposure and development. The thin film was then etched, thereby yielding a black matrix in which openings each having a 84 μm×284 μm rectangular shape were arranged at a pitch of 100 μm in a matrix form.

(Formation of a Colored Layer)

Prepared were photosensitive coating compositions for forming colored layers in three colors of red, green and blue. As a red coloring agent, a green coloring agent and a blue coloring agent, the following were used, a condensed azo dye (Chromophthal Red BRN, manufactured by Ciba-Geigy Japan Limited), a phthalocyanine based green pigment (Lionol Green 2Y-301, manufactured by TOYO INK MFG. CO., LTD.), and an anthraquinone based pigment (Chromophthal BlueA3R, manufactured by Ciba-Geigy Japan Limited), respectively. As a binder resin, a 10% aqueous solution of polyvinyl alcohol was used. One part of each of the coloring agents was incorporated into 10 parts of the aqueous solution of polyvinyl alcohol (the “part(s)” being part(s) by mass). The resultant was stirred to disperse the coloring agent sufficiently in the solution. One part of ammonium dichromate was added as a crosslinking agent to 100 parts of the resultant solution to yield a photosensitive coating composition for forming each of the colored layers.

The resultant colored-layer-forming photosensitive coating compositions were successively used to form colored layers in the respective colors. Specifically, the red-colored-layer-forming photosensitive coating composition was coated onto the transparent substrate, on which the black matrix was formed, by spin coating, and the resultant was pre-baked at 100° C. for 5 minutes. Thereafter, the resultant was exposed to light through a photomask, and then developed with a developer (0.05% KOH solution). Next, the resultant was post-baked at 200° C. for 60 minutes to form a pattern of bands (width: 85 μm, and thickness: 1.5 μm) of the red colored layer so as to make the opening consistent with the pattern of the black matrix and further direct the width direction thereof to the short side direction of the openings in the black matrix. Thereafter, the green-colored-layer-forming photosensitive coating composition and the blue-colored-layer-forming photosensitive coating composition were successively used to form green and blue colored layers. In this way, a unified colored layer in which the patterned colored layers in the three colors were repeatedly arranged in the width direction was formed.

(Formation of a Color Converting Layer)

A blue color converting layer (dummy layer) forming coating solution (transparent photosensitive resin composition, trade name: “Color Mosaic CB-701”, manufactured by FUJIFILM ELECTRONIC MATERIALS CO., LTD.) was coated onto the formed black matrix and colored layer by spin coating, and the resultant was pre-baked at 100° C. for 5 minutes, patterned by photolithography, and then post-baked at 200° C. for 60 minutes. In this way, a blue color converting layer (dummy layer) in the form of bands (width: 85 μm, and thickness: 10 μm) was formed on the blue colored layer.

Next, an alkali-soluble negative photosensitive resist in which a green color converting fluorescent substance (coumalin 6, manufactured by SIGMA-ALDRICH Corp.) was dispersed was used as a green color converting layer forming coating solution to form a green color converting layer in the form of bands (width: 85 par and thickness: 10 μm) on the green colored layer in the same way as described above.

Next, an alkali-soluble negative photosensitive resist in which a red color converting fluorescent substance (rhodamine 6G, manufactured by SIGMA-ALDRICH Corp.) was dispersed was used as a red color converting layer forming coating solution to form a red color converting layer in the form of bands (width: 85 μm, and thickness: 10 μm) on the red colored layer in the same way as described above.

(Formation of an Overcoat Layer)

Next, an overcoat layer forming coating solution in which an acrylic thermosetting resin (trade name: “V-259PA/PH5”, manufactured by Nippon Steel Chemical Co., Ltd.) was diluted with propylene glycol monomethyl ether acetate was coated onto the formed color converting layers by spin coating, and the resultant was pre-baked at 120° C. for 5 minutes. The whole surface thereof was exposed to ultraviolet rays to set the quantity of the radiated rays into 300 mJ. After the exposure, the resultant was post-baked at 200° C. for 60 minutes, thereby forming a transparent overcoat layer having a thickness of 5 μm to cover the whole of the color converting layers.

(Formation of an Adhesive Property Improving Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed overcoat layer by spin coating, and then the resultant was fired at 250° C. in the atmosphere of oxygen gas (oxygen gas concentration: 100% by volume) having an atmospheric pressure for 10 minutes to form a conductive film having a thickness of 150 nm. This conductive film was a transparent and homogeneous film.

(Formation of a Transparent Electrode Layer)

An ITO film having a thickness of 150 nm was formed on the formed adhesive property improving layer by sputtering.

(Patterning of the Adhesive Property Improving Layer and Transparent Electrode Layer)

A photosensitive resin was coated onto the conductive film and the ITO film, and the resultant was subjected to mask-exposure and development. The conductive film and the ITO film were then etched, thereby forming patterned the adhesive property improving layer and transparent electrode layer (pattern width; 100 μm, and space width: 20 μm)

(Formation of an Insulating Layer and Partitions)

An insulating layer forming coating solution, in which a norbornene based resin (ARTON, manufactured by JSR Corporation.) having an average molecular weight of about 100,000 was diluted with toluene, was coated onto the transparent electrode layer by spin coating, so as to cover the adhesive property improving layer and transparent electrode layer. The resultant was then baked at 100° C. for 30 minutes to form an insulating film (thickness: 1 μm). Next, a photosensitive resist was coated onto this insulating film, and the resultant was subjected to mask-exposure and development. The insulating film was then etched to form an insulating layer. This insulating layer had a pattern in the form of stripes (width: 20 μm) crossing the transparent electrode layer at right angles, and positioned on the black matrix.

Next, a partition forming coat (Photoresist ZPN 1100, manufactured by ZEON CORPORATION) was coated onto the insulating layer by spin coating, so as to cover the entire face of the insulating layer. The resultant was pre-baked at 70° C. for 30 minute, exposed to light through a predetermined partition forming photomask, developed with a developer (ZTMA-100, manufactured by ZEON CORPORATION), and post-baked at 100° C. for 30 minutes. In this way, partitions were formed on the insulating layer. The partitions were in the following form: a height of 10 μm, a lower part (insulating layer side) width of 15 μm, and upper part width of 26 μm.

(Formation of an Organic EL Layer)

An organic EL layer consisting of a positive hole injection layer, a blue light emitting layer, and an electron injection layer was formed by vacuum evaporation using the partitions as a mask.

Specifically, 4,4′,4″-tris[N-(3-methylphenyl)-N-phenylamino]triphenylamine was first vapor-deposited into a thickness of 200 nm through a photomask having an opening corresponding to an image display area, so as to form a film. Thereafter, 4,4′-bis[N-(1-naphthyl)-N-phenylamino]biphenyl was vapor-deposited into a thickness of 20 nm to form a film, whereby the partitions functioned as a mask pattern so as to pass the positive hole injection layer materials only through spaces between the respective partitions. In this way, a positive hole injection layer was formed on the transparent electrode layer. In the same way, 4,4′-bis(2,2-diphenylvinyl)biphenyl was vapor-deposited into a thickness of 50 nm to form a film as a blue light emitting layer. Thereafter, tris(8-quinolinol)aluminum was vapor-deposited into a thickness of 20 nm to form a film as an electron injection layer. The thus obtained organic EL layer was a layer in which patterned bands having a width of 280 μm were present between the respective partitions. A dummy organic EL layer having the same layer structure was formed on the upper surface of the partitions also.

(Formation of a Counter Electrode Layer)

Next, aluminum was vapor-deposited on the area where the partitions were formed, through a photomask having a predetermined opening larger than the image display area, by vacuum evaporation (vapor deposition rate of aluminum=1.3 to 1.4 nm/second). In this way, the partitions functioned as a mask to form a counter electrode layer (back electrode layer, thickness: 200 nm) made of aluminum on the organic EL layer. This counter electrode layer was a layer formed in a pattern of bands having a width of 280 μm on the organic EL layer. A dummy counter electrode layer was formed on the upper surface of the partitions also.

By the above-mentioned method, an organic EL element was yielded. The organic EL element was sealed up to yield an organic EL display device.

### Example 13

In the same way as in Example 12, a black matrix, a colored layer, a color converting layer and an overcoat layer were formed on a transparent substrate.

(Formation of an Adhesive Property Improving Layer)

Ag fine particles were dispersed into n-butyl acetate to give a concentration of 1%, thereby preparing a conductive metal layer forming dispersion liquid. This conductive metal layer forming dispersion liquid was coated onto the formed overcoat layer by spin coating and dried. Next, the resultant was fired at 250° C. in the atmosphere for 10 minutes to form an Ag film, as a conductive metal film with a thickness of 5 nm. This conductive metal film was a transparent and homogeneous film.

Furthermore, a photosensitive resist was coated onto the conductive metal film, and then the resultant was subjected to mask-exposure, development and etching so as to form an adhesive property improving layer in the form of a pattern (width: 100 μm, and space width: 20 μm).

(Formation of a Transparent Electrode Layer)

An ITO film having a thickness of 150 nm was formed on the formed adhesive property improving layer by sputtering. Furthermore, a photosensitive resist was coated onto the ITO film, and the resultant was subjected to mask-exposure, development and etching to form a transparent electrode layer in the form of a pattern (width: 100 μm, and space width: 20 μm).

(Production of an Organic EL Element)

Next, an insulating layer, partitions, an organic EL layer and a counter electrode layer were formed in the same way as in Example 12, so as to yield an organic EL element. The organic EL element was sealed up to yield an organic EL display device.

### Example 14

In the same way as in Example 12, a black matrix, a colored layer, an overcoat layer, a conductive layer and ITO film were formed on a transparent substrate.

(Formation of a Secondary Transparent Electrode Layer)

Indium alloy fine particles containing 5% of Sn were dispersed into n-butyl acetate to give a concentration of 5% by weight, thereby preparing a conductive layer forming dispersion liquid. This conductive layer forming dispersion liquid was coated onto the formed ITO film by spin coating, and then the resultant was fired at 250° C. in the atmosphere of oxygen gas (oxygen gas concentration: 100% by volume) having an atmospheric pressure for 10 minutes to form a conductive film with a thickness of 150 nm. This conductive film was a transparent and homogeneous film. It was ascertained that defects (pinholes) generated when the ITO film was formed were covered with the conductive film so as to repair the defects.

(Patterning of the Adhesive Property Improving Layer, the Transparent Electrode Layer and the Secondary Transparent Electrode Layer)

A photosensitive resist was coated onto the conductive film, and the ITO film and the conductive film, and the resultant was subjected to mask-exposure and development. The ITO film and the conductive layers were etched to form a patterned adhesive property improving layer, transparent electrode layer and secondary transparent electrode layer (pattern width: 100 μm, and space width: 20 μm).

(Production of an Organic EL Element)

Next, an insulating layer, partitions, an organic EL layer and a counter electrode layer were formed in the same way as in Example 12, so as to yield an organic EL element. The organic EL element was sealed up to yield an organic EL display device.

### Comparative Example 6

An organic EL element was produced in the same way as in Example 12 except that the adhesive property improving layer in Example 12 was not formed.

### Comparative Example 7

An organic EL element was produced in the same way as in Example 12 except that instead of the adhesive property improving layer in Example 12, a SiO₂ thin film having a thickness of 20 nm was formed over the entire face of the transparent substrate.

[Evaluation]

In Examples 12 to 14 and Comparative Example 7, film-peeling was not observed when the transparent electrode layer thereof was formed. However, in Comparative Example 6, film-peeling was generated when the transparent electrode layer thereof was formed.

A DC voltage of 8.5V was applied to the transparent electrode layer and the counter electrode layer of each of the organic EL display devices of Examples 12 to 14 and Comparative Example 7 at a constant current density of 10 mA/Cm² to drive the display device continuously, thereby emitting light from the blue light emitting layer at desired sites where the pattern pieces of the transparent electrode layer and the counter electrode layer crossed. The luminous area of the organic EL display device was an area 6 mm square. The organic EL display devices were subjected to a storage test at a temperature of 85° C. and a relative humidity of 60%. After 500 hours from the start of the test, defects in the organic EL element were observed with an optical microscope (magnifications: 50) to evaluate the organic EL element.

As a result, dark spots were generated in the organic EL display device of Comparative Example 7. It appears that this was based on the following reason: irregularities in the overcoat layer surface were not permitted to be made smooth by the SiO₂ film; therefore, degas components flowed out from the irregular portions so that dark spots were generated. On the other hand, in the organic EL display devices of Examples 12 to 14, dark spots were not generated so that display characteristics having excellent durability were exhibited.

What is claimed is:

1. A color filter substrate for an organic electroluminescent element comprising a substrate, a colored layer formed in a pattern form on/over the substrate, and a transparent electrode layer and a conductive layer laminated, many order, on/over the colored layer, wherein the conductive layer is a coated film.

2. The color filter substrate for an organic electroluminescent element according to claim 1, wherein the transparent electrode layer is formed on/over the colored layer and the conductive layer having a barrier property is formed on/over the transparent electrode layer.

3. The color filter substrate for an organic electroluminescent element according to claim 2, wherein the conductive layer contains a plurality of fine particles having an average particle size of 1 to 10 nm.

4. The color filter substrate for an organic electroluminescent element according to claim 3, wherein the fine particles are fine particles made of indium tin oxide (ITO).

5. The color filter substrate for an organic electroluminescent element according to claim 3, wherein the fine particles are fine particles made of at least one kind selected from a group consisting of Au, Au, Cu, Pt, Sn, Zn, In, Pb and Al, and oxides thereof.

6. The color filter substrate for an organic electroluminescent element according to claim 2, wherein an average surface roughness (Ra) of the conductive layer is from 10 to 100 Å.

7. The color filter substrate for an organic electroluminescent element according to claim 2, wherein an inorganic layer having the barrier property is formed between the colored layer and the transparent electrode layer.

8. The color filter substrate for an organic electroluminescent element according to claim 7, wherein the inorganic layer has a conductivity.

9. The color filter substrate for an organic electroluminescent element according to claim 7, wherein the inorganic layer contains a plurality of fine particles having an average particle size of 1 to 10 nm.

10. The color filter substrate for an organic electroluminescent element according to claim 9, wherein the fine particles are fine particles made of indium tin oxide (ITO).

11. The color filter substrate for an organic electroluminescent element according to claim 9, wherein the fine particles are fine particles made of at least one kind selected from a group consisting of Au, Ag, Cu, Pt, Sn, Zn, In, Pb and Al, and oxides thereof.

12. The color filter substrate for an organic electroluminescent element according to claim 2, wherein at least one of the transparent electrode layer and/or the conductive layer is formed to cover an entire surface of the colored layer formed in the pattern form.

13. The color filter substrate for an organic electroluminescent element according to claim 7, wherein at least one of the transparent electrode layer, the conductive layer and/or the inorganic layer is formed to cover an entire surface of the colored layer formed in the pattern form.

14. The color filter substrate for an organic electroluminescent element according to claim 2, wherein an overcoat layer is formed between the colored layer and the transparent electrode layer.

15. The color filter substrate for an organic electroluminescent element according to claim 14, wherein the overcoat layer is formed over an entire face of the substrate on/over which the colored layer is formed.

16. The color filter substrate for an organic electroluminescent element according to claim 14, wherein the overcoat layer is formed in the pattern form to cover at least a surface of the colored layer, and at least one of the transparent electrode layer and/or the conductive layer is formed to cover an entire face of the overcoat layer formed in the pattern form, or cover an entire face of the colored layer and the overcoat layer formed in the pattern form.

17. The color filter substrate for an organic electroluminescent element according to claim 14, wherein an inorganic layer having the barrier property is formed between the overcoat layer and the transparent electrode layer.

18. The color filter substrate for an organic electroluminescent element according to claim 14, wherein an inorganic layer having the barrier property is formed between the overcoat layer and the transparent electrode layer, the overcoat layer is formed in the pattern form to cover at least a surface of the colored layer, and at least one of the transparent electrode layer, the conductive layer and/or the inorganic layer is formed to cover an entire face of the overcoat layer formed in the pattern form, or cover an entire face of the colored layer and the overcoat layer formed in the pattern form.

19. The color filter substrate for an organic electroluminescent element according to claim 17, wherein the inorganic layer is a coated film, and has a conductivity.

20. The color filter substrate for an organic electroluminescent element according to claim 17, wherein the inorganic layer contains a plurality of fine particles having an average particle size of 1 to 10 nm.

21. The color filter substrate for an organic electroluminescent element according to claim 20, wherein the fine particles are fine particles made of indium tin oxide (ITO).

22. The color filter substrate for an organic electroluminescent element according to claim 20, wherein the fine particles are fine particles made of at least one kind selected from a group consisting of Au, Ag, Cu, Pt, Sn, Zn, In, Pb and Al, and oxides thereof.

23. The color filter substrate for an organic electroluminescent element according to claim 1, wherein the conductive layer is formed in the pattern form on/over the colored layer, and the transparent electrode layer is formed on/over the conductive layer.

24. The color filter substrate for an organic electroluminescent element according to claim 23, wherein the conductive layer contains a plurality of fine particles having an average particle size of 1 to 10 nm.

25. The color filter substrate for an organic electroluminescent element according to claim 24, wherein the fine particles are fine particles made of indium tin oxide (ITO).

26. The color filter substrate for an organic electroluminescent element according to claim 24, wherein the fine particles are fine particles made of at least one kind selected from a group consisting of Au, Ag, Cu, Pt, Sn, Zn, In, Pb and Al, and oxides thereof.

27. The color filter substrate for an organic electroluminescent element according to claim 23, wherein an average surface roughness (Ra) of the transparent electrode layer is from 10 to 100 Å.

28. The color filter substrate for an organic electroluminescent element according to claim 23, wherein the conductive layer is formed to leave an area of a predetermined width from an edge of the colored layer formed in the pattern form.

29. The color filter substrate for an organic electroluminescent element according to claim 23, wherein the conductive layer is formed to cover an entire face of the colored layer formed in the pattern form.

30. The color filter substrate for an organic electroluminescent element according to claim 23, wherein a barrier layer is formed between the colored layer and the conductive layer.

31. The color filter substrate for an organic electroluminescent element according to claim 23, wherein an overcoat layer is formed between the colored layer and the conductive layer.

32. The color filter substrate for an organic electroluminescent element according to claim 31, wherein the overcoat layer is formed over an entire face of the substrate on/over which the colored layer is formed, and the conductive layer is formed to leave an area of a predetermined width from an edge of the colored layer formed in the pattern form.

33. The color filter substrate for an organic electroluminescent element according to claim 31, wherein the overcoat layer is formed in the pattern form to cover at least a surface of the colored layer, and the conductive layer is formed to leave an area of a predetermined width from an edge of the colored layer formed in the pattern form.

34. The color filter substrate for an organic electroluminescent element according to claim 31, wherein the overcoat layer is formed in the pattern form to cover at least a surface of the colored layer, and the conductive layer is formed to cover an entire face of the overcoat layer formed in the pattern form, or cover an entire face of the colored layer and the overcoat layer formed in the pattern form.

35. The color filter substrate for an organic electroluminescent element according to claim 31, wherein a barrier layer is formed between the overcoat layer and the conductive layer.

36. The color filter substrate for an organic electroluminescent element according to claim 1, wherein a light shielding part is formed on/over the substrate and between a plurality of the colored layer.

37. The color filter substrate for an organic electroluminescent element according to claim 36, wherein the light shielding part has an insulation property.

38. The color filter substrate for an organic electroluminescent element according to claim 1, wherein a color converting layer is formed on/over the colored layer and between the colored layer and the transparent electrode layer or the conductive layer.

39. A color filter substrate for an organic electroluminescent element, comprising a substrate, a colored layer formed in a pattern form on/over the substrate, a transparent electrode layer formed on/over the colored layer, and a conductive layer formed on/over the transparent electrode layer, wherein a pinhole presents in the transparent electrode layer is blocked with the conductive layer.

40. The color filter substrate for an organic electroluminescent element according to claim 39, wherein an overcoat layer is formed between the colored layer and the transparent electrode layer.

41. An organic electroluminescent display device, comprising the color filter substrate for an organic electroluminescent element according to claim 1, an organic electroluminescent layer formed on/over the color filter substrate for an organic electroluminescent element and containing at least a light emitting layer, and a counter electrode layer formed on/over the organic electroluminescent layer.
